(19) United States
(12) Patent Application Publication
(10) Pub. No.: US 2026/0304792 A1
(43) Pub. Date: Oct. 1, 2026

(54) SEMICONDUCTOR DEVICE INCLUDING LASER BEAM ABSORPTION ENHANCEMENT STRUCTURES AND METHODS FOR FORMING THE SAME

(71) Applicant: Sandisk Technologies, Inc., Milpitas, CA (US)

(72) Inventors: Kento ISERI, Yokkaichi (JP); Atsushi SHIMIZU, Yokkaichi (JP); Yuya SANADA, Yokkaichi (JP)

(21) Appl. No.: 19/685,314

(22) Filed: May 22, 2026

Related U.S. Application Data
(63) Continuation-in-part of application No. 18/768,833, filed on Jul. 10, 2024.
(60) Provisional application No. 63/648,997, filed on May 17, 2024.

(51) Int. Cl. H10B 80/00; H10B 43/10; H10B 43/27; H10B 43/30; H10B 43/40; H10B 43/50; H10D 30/01; H10D 30/69; H10D 62/17; H10D 62/83; H10D 62/832; H10D 80/30; H10W 72/90; H10W 80/00; H10W 90/00

(52) U.S. Cl. CPC H10B 80/00; H10B 43/10; H10B 43/27; H10B 43/30; H10B 43/40; H10B 43/50; H10D 30/0413; H10D 30/693; H10D 62/83; H10D 62/832; H10D 80/30; H10W 80/312; H10W 80/338; H10W 90/792; H10D 62/292; H10W 72/952

(57) ABSTRACT

A textured nanopattern is formed over a semiconductor structure. A laser anneal process can be performed by irradiating a laser beam on the textured nanopattern. The textured nanopattern may include semiconductor nanoparticles, such as silicon core and germanium-containing shell nanoparticles. The textured nanopattern enhances an absorption efficiency of the laser beam through at least one optical effect.

### FIELD

The present disclosure relates generally to the field of semiconductor devices, and particularly to laser beam absorption enhancement structures for a semiconductor material in a semiconductor device and methods for forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device comprises an alternating stack of insulating layers and electrically conductive layers that alternate along a vertical direction; memory openings vertically extending through the alternating stack; memory opening fill structures located in the memory openings and comprising a respective vertical stack of memory elements and a respective vertical semiconductor channel; a dielectric material portion located adjacent to the alternating stack; a semiconductor source layer comprising a polycrystalline doped semiconductor material, underlying a bottommost surface of the alternating stack, and contacting a bottom end of the vertical semiconductor channels; and a textured nanopattern including gaps having a respective gap width in a range from 5 nm to 500 nm.

According to another aspect of the present disclosure, a method of forming a three-dimensional memory device comprises forming an alternating stack of insulating layers and spacer material layers over a carrier substrate, wherein the spacer material layers are formed as, or are subsequently replaced with, electrically conductive layers; forming a dielectric material portion adjacent to the alternating stack; forming memory openings through the alternating stack; forming memory opening fill structures in the memory openings, wherein each of the memory opening fill structures comprises a respective vertical stack of memory elements and a respective vertical semiconductor channel; removing the carrier substrate; forming an unactivated semiconductor layer underneath the bottommost surface of the alternating stack and on bottom surfaces of the vertical semiconductor channels; forming a textured nanopattern including gaps having a respective gap width after forming the unactivated semiconductor layer; and irradiating a laser beam having a peak wavelength greater than the gap width on the unactivated semiconductor layer to convert the unactivated semiconductor into a semiconductor source layer, wherein the textured nanopattern enhances an absorption efficiency of the laser beam through at least one optical effect.

### BRIEF DESCRIPTION OF THE DRAWINGS

FIG. 1 is a vertical cross-sectional view of a first exemplary structure after formation of a first-tier alternating stack and a first-tier stepped dielectric material portion according to a first embodiment of the present disclosure.

FIG. 2A is a vertical cross-sectional view of the first exemplary structure after formation of first-tier memory openings and first-tier support openings according to the first embodiment of the present disclosure.

FIG. 2B is a top-down view of the first exemplary structure of FIG. 2A. The hinged vertical plane A-A′ is the cut plane of the vertical cross-sectional view of FIG. 2A.

FIG. 3 is a vertical cross-sectional view of the first exemplary structure after formation of first sacrificial opening fill structures according to the first embodiment of the present disclosure.

FIG. 4 is a vertical cross-sectional view of the first exemplary structure after formation of a second-tier alternating stack, a second-tier stepped dielectric material portion, second-tier memory openings, second-tier support openings, and second sacrificial opening fill structures according to the first embodiment of the present disclosure.

FIG. 5 is a vertical cross-sectional view of the first exemplary structure after formation of support pillar structures according to the first embodiment of the present disclosure.

FIG. 6 is a vertical cross-sectional view of the first exemplary structure after formation of inter-tier memory openings according to the first embodiment of the present disclosure.

FIGS. 7A-7E are sequential vertical cross-sectional views of a memory opening during formation of a memory opening fill structure according to the first embodiments of the present disclosure.

FIG. 8A is a schematic vertical cross-sectional view of the first exemplary structure after formation of memory opening fill structures according to the first embodiment of the present disclosure.

FIG. 8B is a top-down view of the first exemplary structure of FIG. 8A. The vertical plane A-A is the cut plane of the vertical cross-sectional view of FIG. 8A.

FIG. 9A is a vertical cross-sectional view of the first exemplary structure after formation of lateral isolation trenches according to the first embodiment of the present disclosure.

FIG. 9B is a top-down view of the first exemplary structure of FIG. 9A. The vertical plane A-A is the cut plane of the vertical cross-sectional view of FIG. 9A.

FIG. 10 is a vertical cross-sectional view of the first exemplary structure after formation of laterally-extending cavities according to the first embodiment of the present disclosure.

FIG. 11A is a schematic vertical cross-sectional view of the first exemplary structure after formation of electrically conductive layers according to the first embodiment of the present disclosure.

FIG. 11B is a magnified view of a region around a memory opening fill structure of FIG. 11A.

FIG. 12A is a vertical cross-sectional view of the first exemplary structure after formation of lateral isolation trench fill structures, layer contact via structures, and drain contact via structures according to the first embodiment of the present disclosure.

FIG. 12B is a top-down view of the first exemplary structure of FIG. 12A. The vertical plane A-A is the cut plane of the vertical cross-sectional view of FIG. 12A.

FIG. 13 is a vertical cross-sectional view of the first exemplary structure after formation of a memory die according to the first embodiment of the present disclosure.

FIG. 14 is a vertical cross-sectional view of the first exemplary structure after attaching a logic die to the memory die according to the first embodiment of the present disclosure.

FIG. 15A is a vertical cross-sectional view of the first exemplary structure after removal of the carrier substrate according to the first embodiment of the present disclosure.

FIG. 15B is a magnified view of a region around a memory opening fill structure of the first exemplary structure of FIG. 15A.

FIG. 16A is a vertical cross-sectional view of the first exemplary structure after removal of end portions of the memory films according to the first embodiment of the present disclosure.

FIG. 16B is a magnified view of a region around a memory opening fill structure of the first exemplary structure of FIG. 16A.

FIG. 17 is a vertical cross-sectional view of the first exemplary structure after deposition of an unactivated semiconductor layer according to the first embodiment of the present disclosure.

FIG. 18 is a vertical cross-sectional view of the first exemplary structure after formation of a patterned photoresist layer according to the first embodiment of the present disclosure.

FIGS. 19A, 19D and 19E are vertical cross-sectional views of alternative configurations of the first exemplary structure after patterning the unactivated semiconductor layer according to the first embodiment of the present disclosure.

FIG. 19B is a bottom-up view of a first configuration of an amorphous semiconductor textured-pattern structure in the first exemplary structure of FIG. 20A.

FIG. 19C is a bottom-up view of a second configuration of an amorphous semiconductor textured-pattern structure in the first exemplary structure of FIG. 20A.

FIG. 20 is a vertical cross-sectional view of the first exemplary structure after crystallizing the unactivated semiconductor layer into an activated semiconductor layer according to the first embodiment of the present disclosure.

FIG. 21 is a vertical cross-sectional view of the first exemplary structure after deposition of a backside metal layer according to the first embodiment of the present disclosure.

FIG. 22 is a vertical cross-sectional view of the first exemplary structure after formation of a semiconductor source layer according to the first embodiment of the present disclosure.

FIG. 23 is a vertical cross-sectional view of a second exemplary structure after formation of a matrix material layer according to a second embodiment of the present disclosure.

FIG. 24 is a vertical cross-sectional view of the second exemplary structure after formation of a dielectric textured-pattern structure according to the second embodiment of the present disclosure.

FIG. 25A is a vertical cross-sectional view of the second exemplary structure after removal of a photoresist layer according to the second embodiment of the present disclosure.

FIG. 25B is a bottom-up view of a first configuration of the dielectric textured-pattern structure in the second exemplary structure of FIG. 25A.

FIG. 25C is a bottom-up view of a second configuration of the dielectric textured-pattern structure in the second exemplary structure of FIG. 25A.

FIG. 26 is a vertical cross-sectional view of the second exemplary structure after deposition of an unactivated semiconductor layer according to the second embodiment of the present disclosure.

FIG. 27 is a vertical cross-sectional view of the second exemplary structure after crystallizing the unactivated semiconductor layer into an activated semiconductor layer according to the second embodiment of the present disclosure.

FIG. 28 is a vertical cross-sectional view of the second exemplary structure after deposition of a backside metal layer according to the second embodiment of the present disclosure.

FIG. 29 is a vertical cross-sectional view of the second exemplary structure after formation of a semiconductor source layer according to the second embodiment of the present disclosure.

FIG. 30 is a vertical cross-sectional view of a third exemplary structure after deposition of an unactivated semiconductor layer according to a third embodiment of the present disclosure.

FIG. 31A is a vertical cross-sectional view of the third exemplary structure after depositing a carbon-based material layer over the unactivated semiconductor layer according to the third embodiment of the present disclosure.

FIG. 31B is a scanning electron micrograph of a carbon-based material layer including laterally-extending cracks therein.

FIG. 32 is a vertical cross-sectional view of the third exemplary structure after transferring the pattern of the laterally-extending cracks into the unactivated semiconductor layer according to the third embodiment of the present disclosure.

FIG. 33 is a vertical cross-sectional view of the third exemplary structure after removing the carbon-based material layer according to the third embodiment of the present disclosure.

FIG. 34 is a vertical cross-sectional view of the third exemplary structure after converting the unactivated semiconductor layer into an activated semiconductor material layer according to the third embodiment of the present disclosure.

FIG. 35 is a vertical cross-sectional view of the third exemplary structure after deposition of a backside metal layer according to the third embodiment of the present disclosure.

FIG. 36 is a vertical cross-sectional view of the third exemplary structure after formation of a semiconductor source layer according to the third embodiment of the present disclosure.

FIG. 37 is a vertical cross-sectional view of a fourth exemplary structure after formation of a matrix material layer according to a fourth embodiment of the present disclosure.

FIG. 38 is a vertical cross-sectional view of the fourth exemplary structure after depositing a carbon-based material layer over the matrix material layer according to the fourth embodiment of the present disclosure.

FIG. 39 is a vertical cross-sectional view of the fourth exemplary structure after formation of a textured-pattern structure according to the fourth embodiment of the present disclosure.

FIG. 40 is a vertical cross-sectional view of the fourth exemplary structure after removal of the carbon-based material layer according to the fourth embodiment of the present disclosure.

FIG. 41 is a vertical cross-sectional view of the fourth exemplary structure after activation of electrical dopants in the unactivated semiconductor layer according to the fourth embodiment of the present disclosure.

FIG. 42 is a vertical cross-sectional view of the fourth exemplary structure after removal of the textured-pattern structure according to the fourth embodiment of the present disclosure.

FIG. 43 is a vertical cross-sectional view of the fourth exemplary structure after deposition of a backside metal layer according to the fourth embodiment of the present disclosure.

FIG. 44 is a vertical cross-sectional view of the fourth exemplary structure after formation of a semiconductor source layer according to the fourth embodiment of the present disclosure.

FIG. 45 is a vertical cross-sectional view of a fifth exemplary structure after formation of gate stacks according to a fifth embodiment of the present disclosure.

FIG. 46 is a vertical cross-sectional view of the fifth exemplary structure after formation of source/drain regions according to the fifth embodiment of the present disclosure.

FIG. 47 is a vertical cross-sectional view of the fifth exemplary structure after deposition of a matrix material layer and a carbon-based material layer according to the fifth embodiment of the present disclosure.

FIG. 48 is a vertical cross-sectional view of the fifth exemplary structure after formation of a textured-pattern structure according to the fifth embodiment of the present disclosure.

FIG. 49 is a vertical cross-sectional view of the fifth exemplary structure after removal of the carbon-based material layer and activation of electrical dopants in the doped semiconductor region according to the fifth embodiment of the present disclosure.

FIG. 50 is a vertical cross-sectional view of an alternative configuration of the fifth exemplary structure after removal of the carbon-based material layer and activation of electrical dopants in the doped semiconductor region according to the fifth embodiment of the present disclosure.

FIG. 51 is a vertical cross-sectional view of the fifth exemplary structure after removal of the textured-pattern structure according to the fifth embodiment of the present disclosure.

FIG. 52 is a vertical cross-sectional view of the fifth exemplary structure after formation of a contact-level dielectric layer and contact via structures according to the fifth embodiment of the present disclosure.

FIG. 53 is a vertical cross-sectional view of a sixth exemplary structure after deposition of a matrix material layer and a carbon-based material layer according to a sixth embodiment of the present disclosure.

FIG. 54 is a vertical cross-sectional view of the sixth exemplary structure after formation of a textured-pattern structure according to the sixth embodiment of the present disclosure.

FIG. 55 is a vertical cross-sectional view of the sixth exemplary structure after removal of the carbon-based material layer and activation of electrical dopants in the doped semiconductor region according to the sixth embodiment of the present disclosure.

FIG. 56 is a vertical cross-sectional view of an alternative configuration of the sixth exemplary structure after removal of the carbon-based material layer and activation of electrical dopants in the doped semiconductor region according to the sixth embodiment of the present disclosure.

FIG. 57 is a vertical cross-sectional view of the sixth exemplary structure after removal of the textured-pattern structure according to the sixth embodiment of the present disclosure.

FIG. 58 is a vertical cross-sectional view of the sixth exemplary structure after formation of a contact-level dielectric layer and contact via structures according to the sixth embodiment of the present disclosure.

FIG. 59 is a vertical cross-sectional view of the seventh exemplary structure after deposition of an unactivated semiconductor layer and a nanoparticle textured-pattern structure according to the seventh embodiment of the present disclosure.

FIG. 60 is a vertical cross-sectional view of the seventh exemplary structure after crystallizing the unactivated semiconductor layer into an activated semiconductor layer according to the seventh embodiment of the present disclosure.

FIG. 61 is a vertical cross-sectional view of the seventh exemplary structure after deposition of a backside metal layer according to the seventh embodiment of the present disclosure.

FIG. 62 is a vertical cross-sectional view of the eighth exemplary structure after deposition of an unactivated semiconductor layer and a nanoparticle textured-pattern structure according to the eighth embodiment of the present disclosure.

FIG. 63 is a vertical cross-sectional view of the eighth exemplary structure after crystallizing the unactivated semiconductor layer into an activated semiconductor layer according to the eighth embodiment of the present disclosure.

FIG. 64 is a vertical cross-sectional view of the eighth exemplary structure after deposition of a backside metal layer according to the eighth embodiment of the present disclosure.

FIGS. 65A, 65B and 65C are vertical cross-sectional views of steps of making nanoparticles according to the seventh and eighth embodiments of the present disclosure.

### DETAILED DESCRIPTION

As discussed above, the embodiments of the present disclosure are directed to laser beam absorption enhancement structures for a semiconductor material in a semiconductor device and methods for forming the same, the various aspects of which are described below. Embodiments of the disclosure can be employed to form various structures including a multilevel memory structure, non-limiting examples of which include field effect transistors and three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

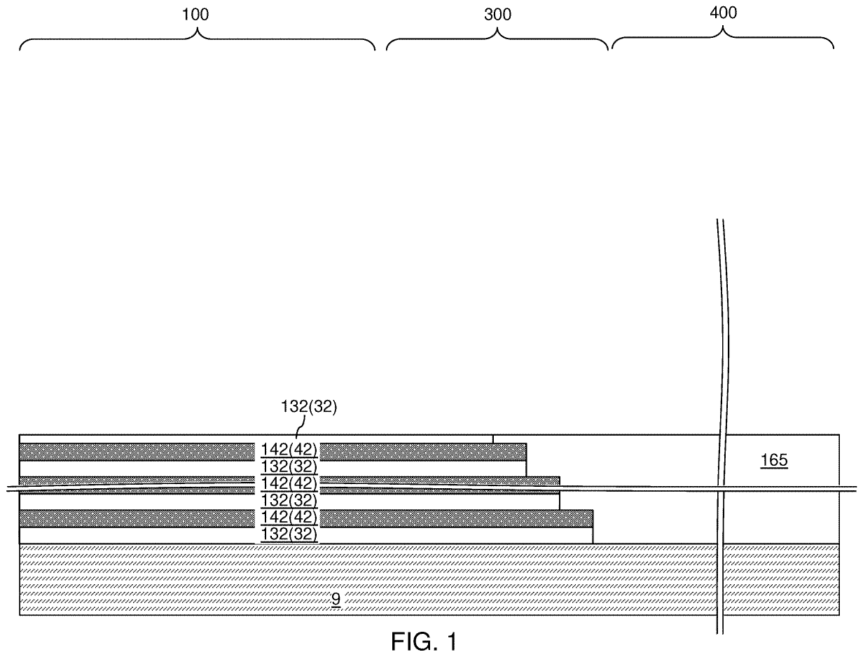

Referring to FIG. 1, a first exemplary structure according to a first embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective to the materials of insulating layers 32 and dielectric material portions to be subsequently formed.

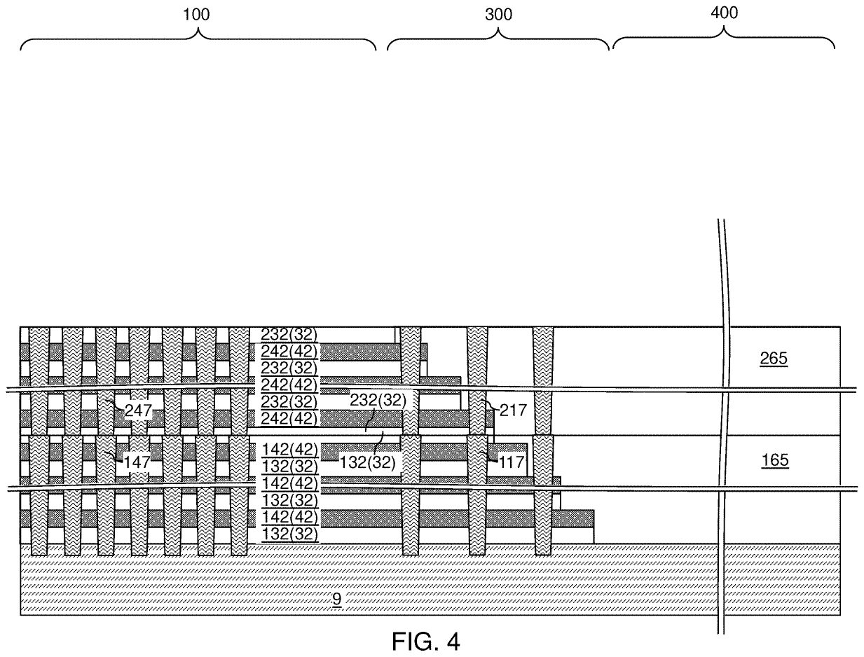

A first alternating stack of insulating layers 32 and spacer material layers can be formed over the carrier substrate 9. The spacer material layers may be formed as sacrificial material layers 42. In case a second alternating stack of additional insulating layers and additional spacer material layers is subsequently formed over the first alternating stack to form a multi-tier structure, as shown in FIG. 4 and as described below, the first alternating stack is referred to as a first-tier alternating stack, and the second alternating stack is referred to as a second-tier alternating stack. In this case, the insulating layers 32 within the first-tier alternating stack are herein referred to as first insulating layers 132, and spacer material layers (such as the sacrificial material layers 42) within the first-tier alternating stack are herein referred to as first spacer material layers (such as first sacrificial material layers 142).

The first insulating layers 132 comprise an insulating material such as undoped silicate glass or a doped silicate glass, and the first sacrificial material layers 142 comprise a sacrificial material such as silicon nitride or a silicon-germanium alloy. In one embodiment, the first insulating layers 132 may comprise silicon oxide layers, and the first sacrificial material layers 142 may comprise silicon nitride layers. The first-tier alternating stack (132, 142) may comprise multiple repetitions of a unit layer stack including a first insulating layer 132 and a first sacrificial material layer 142. The total number of repetitions of the unit layer stack within the first-tier alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed. The first exemplary structure comprises a memory array region 100 in which a three-dimensional array of memory elements is to be subsequently formed, and a contact region 300 in which layer contact via structures contacting word lines are to be subsequently formed.

While an embodiment is described in which the first spacer material layers are formed as first sacrificial material layers 142, the first spacer material layers may be formed as first electrically conductive layers in an alternative embodiment. In this case, processing steps performed to replace the first sacrificial material layers 142 with first electrically conductive layers may be omitted. Generally, spacer material layers may be formed as or may be subsequently replaced with electrically conductive layers.

Optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first-tier alternating stack (132, 142) are removed through formation of the stepped surfaces. A “stepped cavity” refers to a cavity having stepped surfaces.

The first stepped cavity can have various stepped surfaces such that the horizontal cross-sectional shape of the first stepped cavity changes in steps as a function of the vertical distance from the top surface of the carrier substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the alternating stack (132, 142) laterally extends farther than any overlying first sacrificial material layer 142 within the first-tier alternating stack (132, 142) in the terrace region. The stepped surfaces of the first-tier alternating stack (132, 142) continuously extend from a bottommost layer within the first-tier alternating stack (132, 142) to a topmost layer within the first-tier alternating stack (132, 142).

A first stepped dielectric material portion 165 (i.e., an insulating fill material portion) can be formed in the first stepped cavity by deposition of a dielectric material therein. For example, a dielectric material such as silicon oxide can be deposited in the stepped cavity. Excess portions of the deposited dielectric material can be removed from above the top surface of the topmost layer of the first-tier alternating stack (132, 142), for example, by chemical mechanical planarization (CMP). The remaining portion of the deposited dielectric material filling the first stepped cavity constitutes the first stepped dielectric material portion 165. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F.

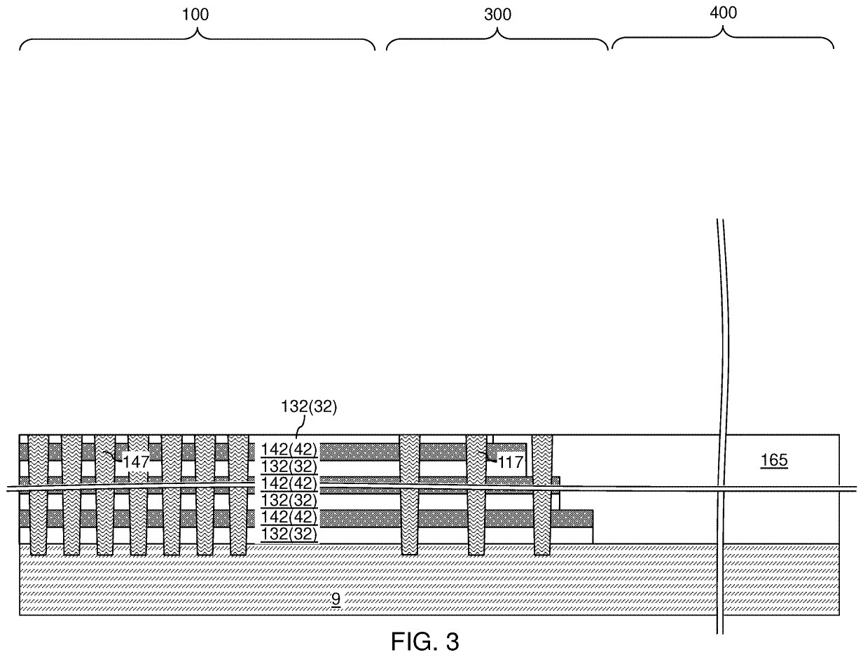

Referring to FIG. 3, a first etch mask layer (such as a photoresist layer) can be formed over the first-tier alternating stack (132, 142), and can be lithographically patterned to form openings therein. A first anisotropic etch process can be performed to transfer the pattern of the openings in the first etch mask layer through the first stepped dielectric material portion 165, and the first-tier alternating stack (132, 142), and optionally into an upper portion of the carrier substrate 9. First-tier memory openings 149 can be formed through the first-tier alternating stack (132, 142) in the memory array region 100, and first-tier support openings 119 can be formed through the first stepped dielectric material portion 165 and the first-tier alternating stack (132, 142) in the contact region 300. Each of the first-tier memory openings 149 and the first-tier support openings 119 can vertically extend into the carrier substrate 9. In one embodiment, bottom surfaces of the first-tier memory openings 149 and the first-tier support openings 119 may be formed at or below the top surface of the carrier substrate 9. The first-tier memory openings 149 and the first-tier support openings 119 may have a diameter in a range from 40 nm to 400 nm, such as from 80 nm to 200 nm, although lesser and greater thicknesses may be employed. The first etch mask layer can be removed, for example, by ashing after the first anisotropic etch process.

The first-tier memory openings 149 may be formed as clusters of first-tier memory openings 149. Each cluster of first-tier memory openings 149 may comprise an area of a memory block containing a plurality of rows of memory openings 49. Each row of first-tier memory openings 149 may comprise a plurality of first-tier memory openings 149 that are arranged along the first horizontal direction (e.g., word line direction) hd1 with a uniform pitch. The rows of first-tier memory openings 149 may be laterally spaced from each other along the second horizontal direction (e.g., bit line direction) hd2, which may be perpendicular to the first horizontal direction hd1. In one embodiment, each cluster of first-tier memory openings 149 may be formed as a two-dimensional periodic array of first-tier memory openings 149.

Referring to FIG. 3, a first sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the first-tier memory openings 149 and in the first-tier support openings 119 by a conformal deposition process. Excess portions of the first sacrificial fill material can be removed from above the top surface of the first-tier alternating stack (132, 142), for example, by a recess etch process. Each remaining portion of the first sacrificial fill material that fills a respective first-tier memory opening 149 constitutes a first sacrificial memory opening fill structure 147. Each remaining portion of the first sacrificial fill material that fills a respective first-tier support opening 119 constitutes a first sacrificial support opening fill structure 117.

Referring to FIG. 4, a second-tier alternating stack (232, 242) of second insulating layers 232 and second spacer material layers may be formed above the first-tier alternating stack (132, 142) and the first stepped dielectric material portion 165. The second insulating layers 232 can be additional insulating layers 32 having a same material composition and a same thickness range as the first insulating layers 132. The second spacer material layers can be additional spacer material layers having a same material composition and a same thickness range as the first spacer material layers in the first-tier alternating stack (132, 142). In one embodiment, the second spacer material layers may comprise second sacrificial material layers 242. In this case, the second sacrificial material layers 242 can be additional sacrificial material layers 42 having a same material composition and a same thickness range as the first sacrificial material layers 142.

The second-tier alternating stack (232, 242) may comprise multiple repetitions of a unit layer stack including a second insulating layer 232 and a second sacrificial material layer 242. The total number of repetitions of the unit layer stack within the second-tier alternating stack (232, 242) may be, for example, in a range from 8 to 1,024, such as from 32 to 256, although lesser and greater number of repetitions may also be employed. Each of the second insulating layers 232 may have a thickness in a range from 20 nm to 100 nm, such as from 30 nm to 60 nm, although lesser and greater thicknesses may also be employed. Each of the second sacrificial material layers 242 may have a thickness in a range from 20 nm to 100 nm, such as from 30 nm to 60 nm, although lesser and greater thicknesses may also be employed.

The first-tier alternating stack (132, 142) and the second-tier alternating stack (232, 242) are collectively referred to as an alternating stack (32, 42) of insulating layers 32 and sacrificial material layers 42.

While an embodiment is described in which the second spacer material layers are formed as second sacrificial material layers 242, the second spacer material layers may be formed as second electrically conductive layers in an alternative embodiment. In this case, processing steps performed to replace the second sacrificial material layers 242 with second electrically conductive layers may be omitted.

Optional stepped surfaces are formed in the contact region 300 by patterning the second-tier alternating stack (232, 242). The stepped surfaces of the second-tier alternating stack (232, 242) may be laterally offset toward the memory array region 100 relative to the stepped surfaces of the first-tier alternating stack (132, 142) in a plan view. A second stepped cavity is formed within the volume from which portions of the second-tier alternating stack (232, 242) are removed through formation of the stepped surfaces. A “stepped cavity” refers to a cavity having stepped surfaces.

The second stepped cavity can have various stepped surfaces such that the horizontal cross-sectional shape of the second stepped cavity changes in steps as a function of the vertical distance from the top surface of the carrier substrate 9. In one embodiment, the second stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type.

Each second sacrificial material layer 242 other than a topmost second sacrificial material layer 242 within the alternating stack (232, 242) laterally extends farther than any overlying second sacrificial material layer 242 within the second-tier alternating stack (232, 242) in the terrace region. The stepped surfaces of the second-tier alternating stack (232, 242) continuously extend from a bottommost layer within the second-tier alternating stack (232, 242) to a topmost layer within the second-tier alternating stack (232, 242).

A second stepped dielectric material portion 265 (i.e., an insulating fill material portion) can be formed in the second stepped cavity by deposition of a dielectric material therein. For example, a dielectric material such as silicon oxide can be deposited in the stepped cavity. Excess portions of the deposited dielectric material can be removed from above the top surface of the topmost layer of the second-tier alternating stack (232, 242), for example, by chemical mechanical planarization (CMP). The remaining portion of the deposited dielectric material filling the second stepped cavity constitutes the second stepped dielectric material portion 265. If silicon oxide is employed for the second stepped dielectric material portion 265, the silicon oxide of the second stepped dielectric material portion 265 may, or may not, be doped with dopants such as B, P, and/or F. The combination of the first stepped dielectric material portion 165 and the second stepped dielectric material portion 265 may be collectively referred to as stepped dielectric material portions (165, 265).

A second etch mask layer (such as a photoresist layer) can be formed over the second-tier alternating stack (232, 242), and can be lithographically patterned to form openings therein. A second anisotropic etch process can be performed to transfer the pattern of the openings in the second etch mask layer through the second stepped dielectric material portion 265 and the second-tier alternating stack (232, 242). Second-tier memory openings can be formed through the second-tier alternating stack (232, 242) directly on a top surface of a respective first sacrificial memory opening fill structure 147 in the memory array region 100. Second-tier support openings 119 can be formed through the second stepped dielectric material portion 165 and the second-tier alternating stack (232, 242) directly on a top surface of a respective first sacrificial support opening fill structure 117 in the contact region 300. Each of the second-tier memory openings and the second-tier support openings may have about the same diameter as the diameter of a respective underlying first sacrificial opening fill structure (147, 117). The second etch mask layer can be removed, for example, by ashing after the second anisotropic etch process.

A second sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the second-tier memory openings and in the second-tier support openings by a conformal deposition process. Excess portions of the second sacrificial fill material can be removed from above the top surface of the second-tier alternating stack (232, 242), for example, by a recess etch process. Each remaining portion of the second sacrificial fill material that fills a respective second-tier memory opening constitutes a second sacrificial memory opening fill structure 247. Each remaining portion of the second sacrificial fill material that fills a respective second-tier support opening constitutes a second sacrificial support opening fill structure 217.

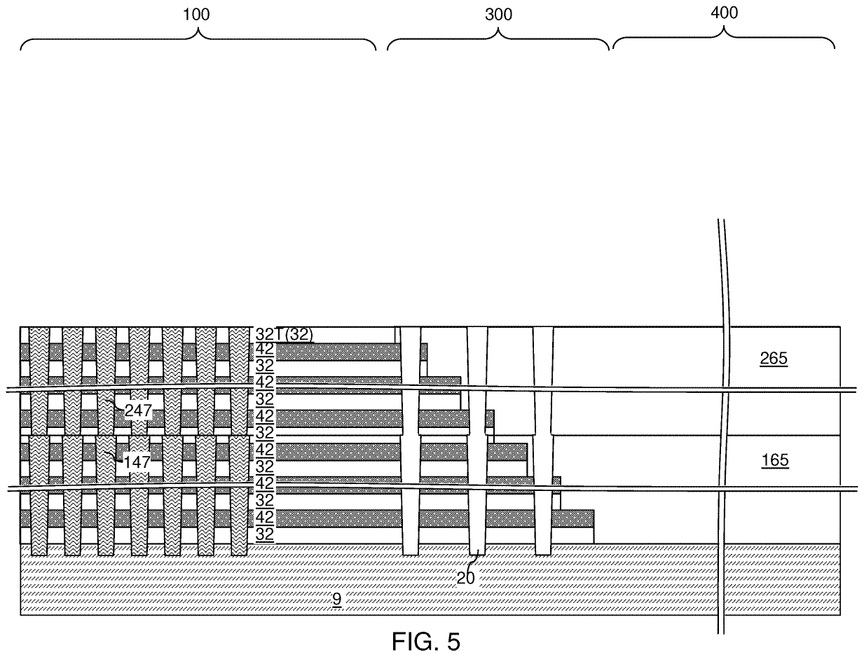

Referring to FIG. 5, a sacrificial mask layer (not shown) is formed over the memory array region 100. The exposed first and second sacrificial support opening fill structures (117, 217) in the contact region 300 are removed by selective etching or ashing to reopen the first-tier and second-tier support openings. A dielectric material, such as silicon oxide, is deposited in the first-tier and second-tier support openings to form support pillar structures 20. The sacrificial mask layer is then removed by selective etching or ashing.

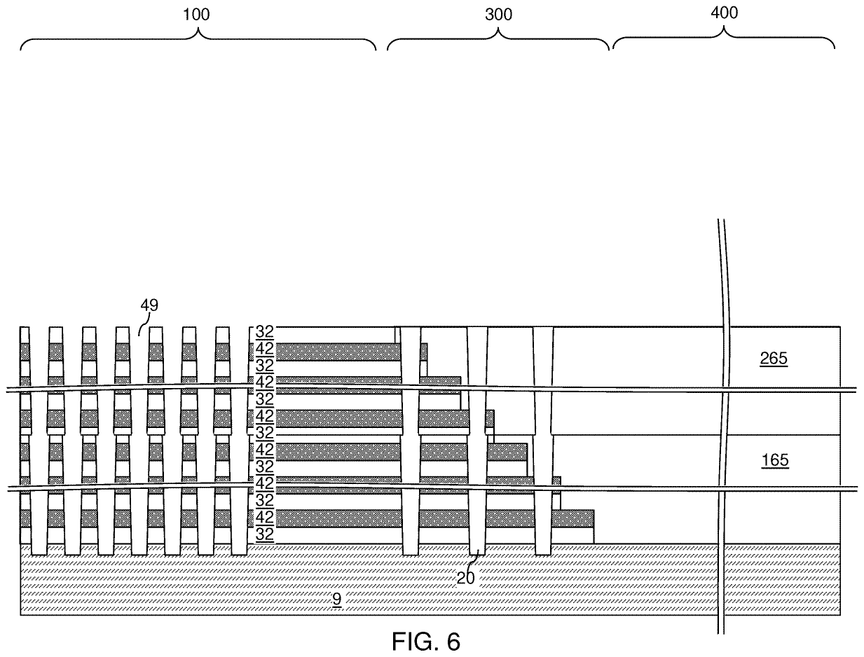

Referring to FIG. 6, the sacrificial memory opening fill structures (147, 247) in the memory array region 100 can be removed selective to the materials of the stepped dielectric material portions (165, 265), the support pillar structures 20, and the alternating stack (32, 42). For example, an selective etch process or an ashing process may be employed to remove the sacrificial memory opening fill structures and portions of the optional etch stop liner in the memory array region 100. Voids are formed in the volumes of the memory openings 49.

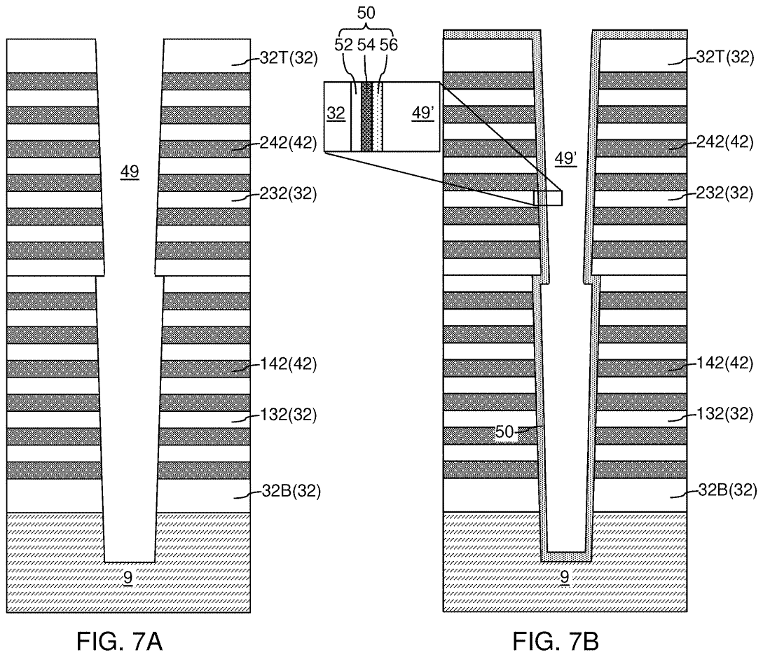

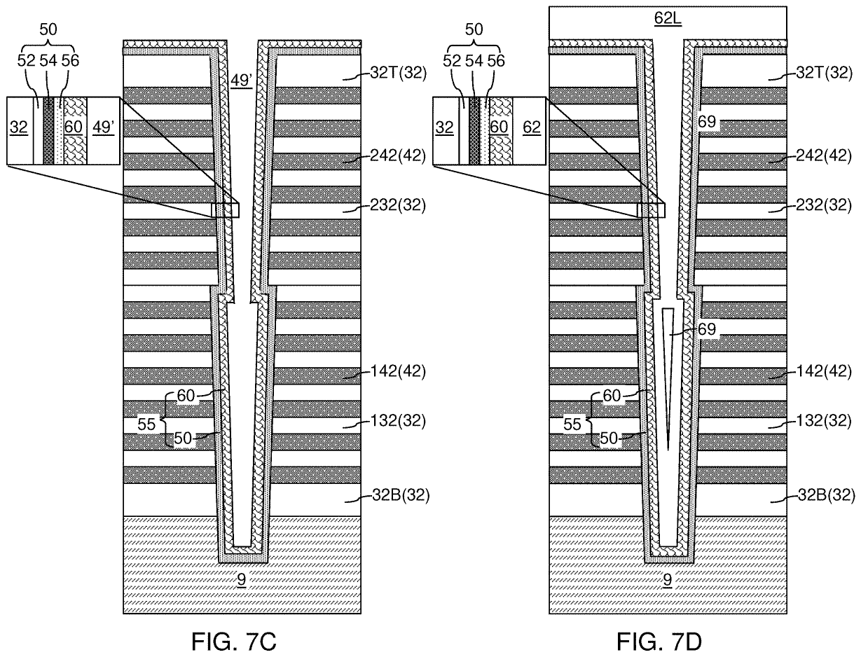

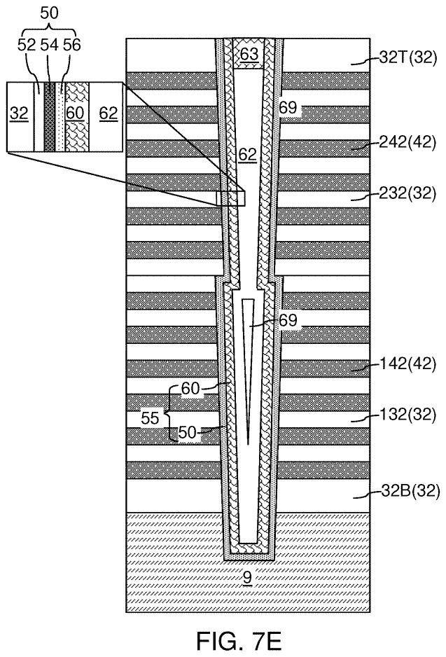

FIG. 7A-7E are sequential vertical cross-sectional views of a memory opening 49 during formation of a memory opening fill structure 58.

Referring to FIG. 7A, a memory opening 49 is illustrated after the processing steps of FIG. 6. Each memory opening 49 vertically extends through each layer within the alternating stack (32, 42). The bottommost layer of the alternating stack (32, 42) may be a bottommost insulating layer 32B, and the topmost layer of the alternating stack (32, 42) may be a topmost insulating layer 32T.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer. A memory cavity 49′ is present in an unfilled volume of the memory opening 49.

Referring to FIG. 7C, a semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62. A doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extends predominantly along long a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

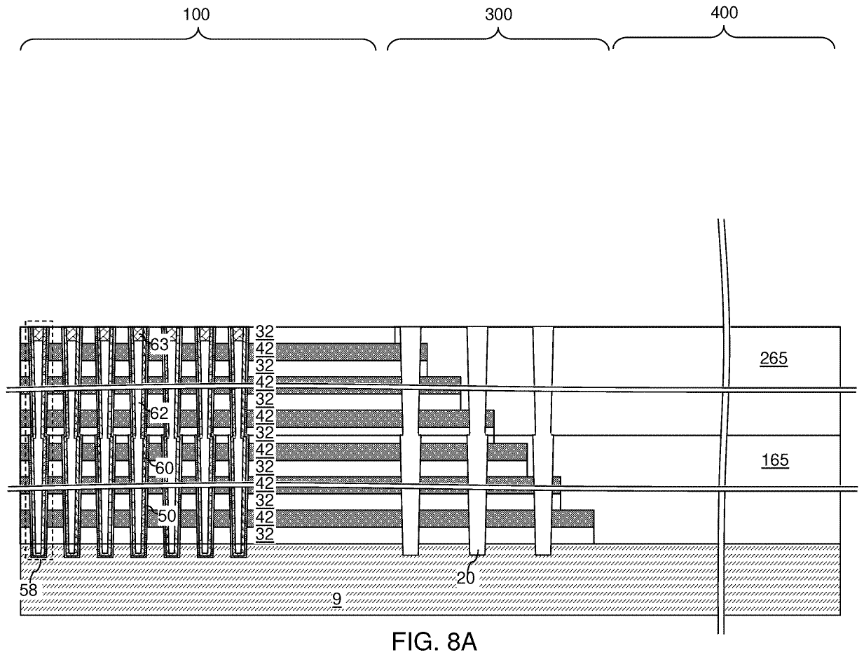

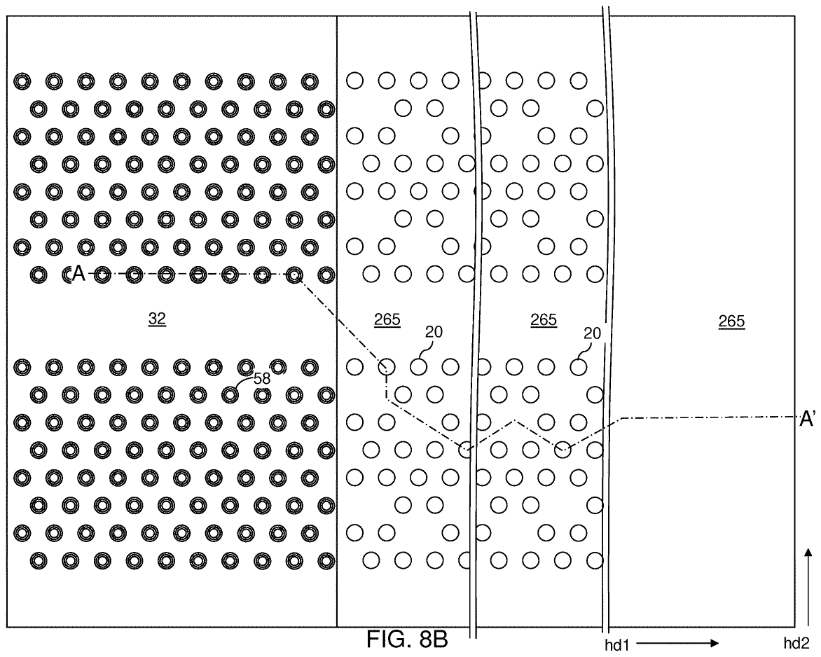

Referring to FIGS. 8A and 8B, the exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

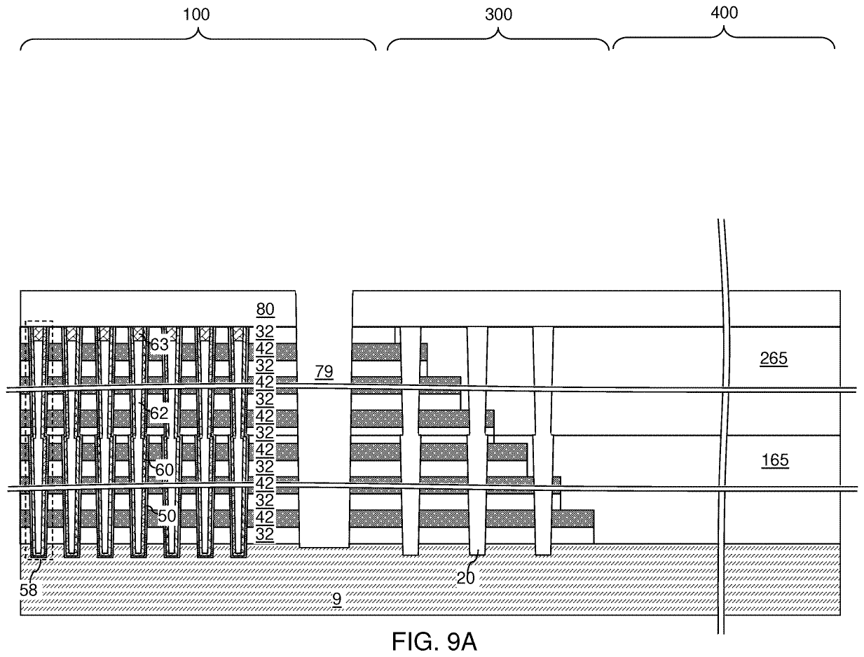

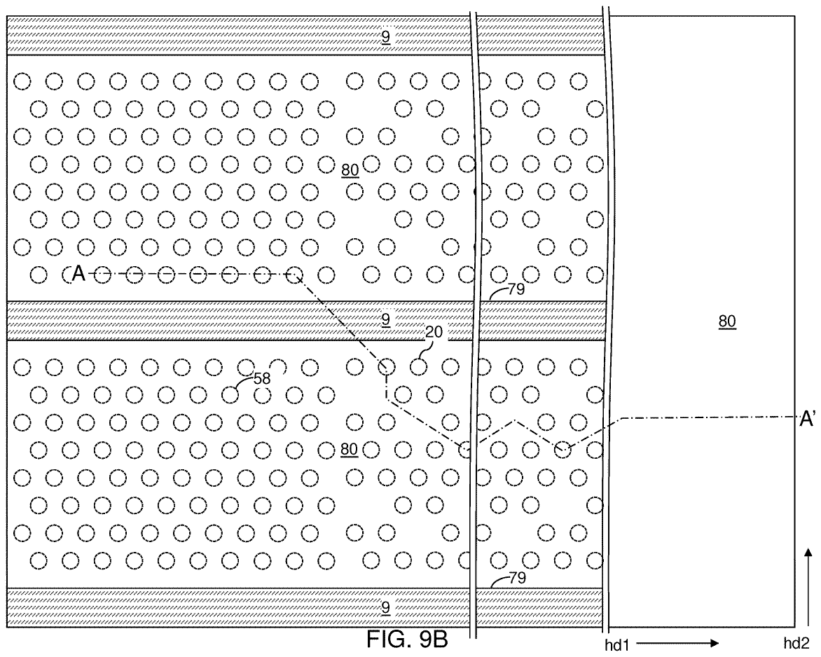

Referring to FIGS. 9A and 9B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portions (165, 265), and to a top surface of the carrier substrate 9. Lateral isolation trenches 79 laterally extending along the first horizontal direction hd1 can be formed through the alternating stack (32, 42), the stepped dielectric material portions (165, 265), and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

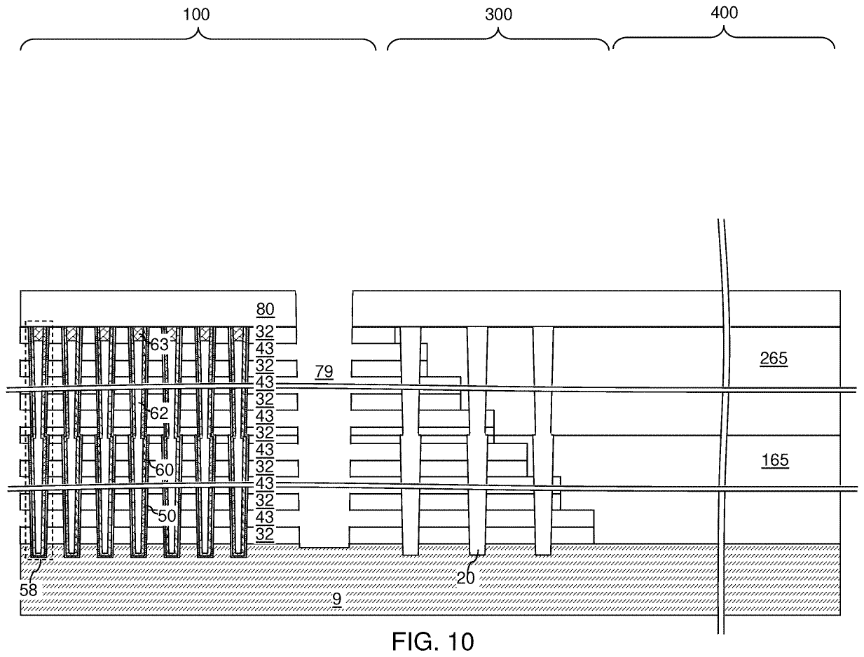

Referring to FIG. 10, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portions (165, 265), and the material of the outermost layer of the memory films 50. In one embodiment, the sacrificial material layers 42 can include silicon nitride, and the materials of the insulating layers 32 and the stepped dielectric material portions (165, 265) can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The support pillar structure 20, the stepped dielectric material portions (165, 265), and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

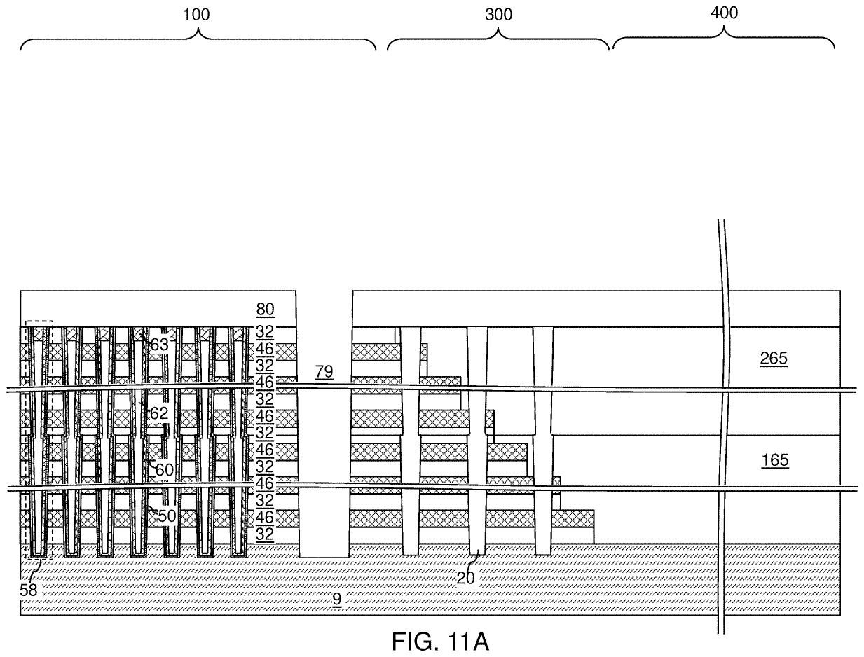

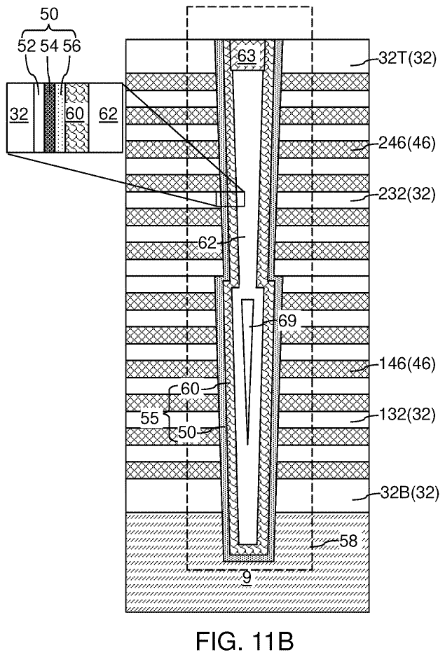

Referring to FIGS. 11A and 11B, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

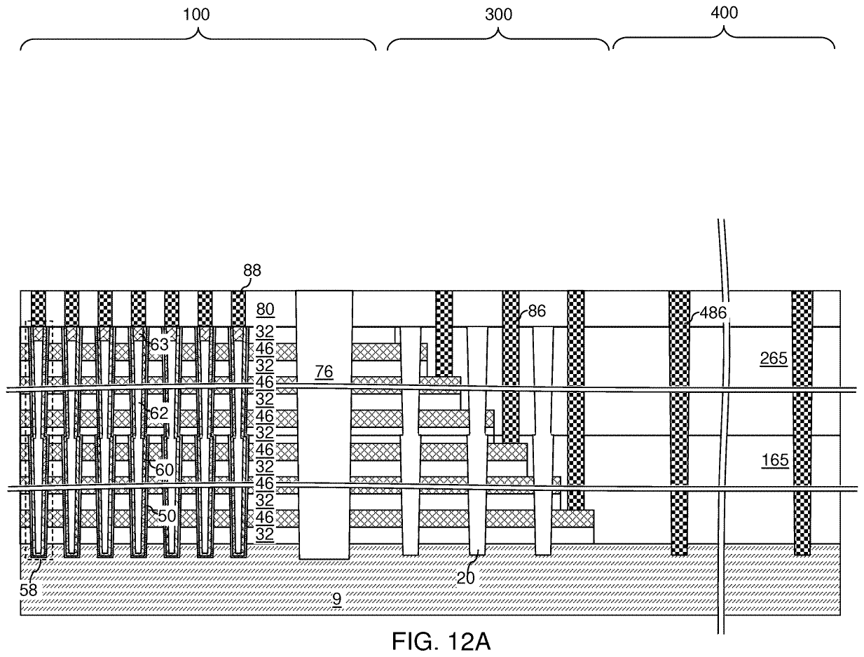

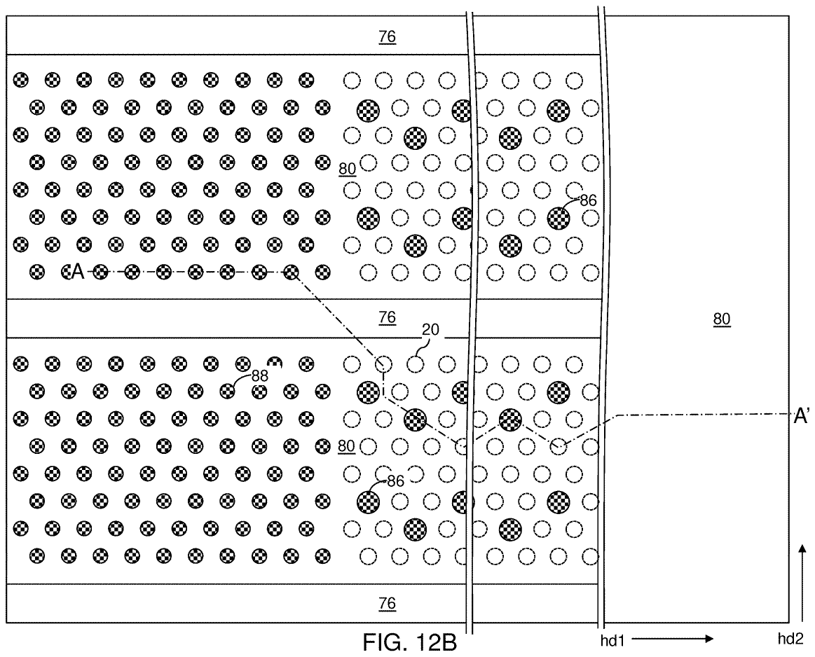

Referring to FIGS. 12A and 12B, a dielectric fill material, such as silicon oxide, can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

Contact via structures (88, 86) can be formed through the contact-level dielectric layer 80, and optionally through the stepped dielectric material portions (165, 265). For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portions (165, 265). In addition, connection via structures 486 can be formed through the contact-level dielectric layer 80 and the stepped dielectric material portions (165, 265) in the peripheral region 400. In one embodiment, the connection via structures 486 may extend into an upper portion of the carrier substrate 9.

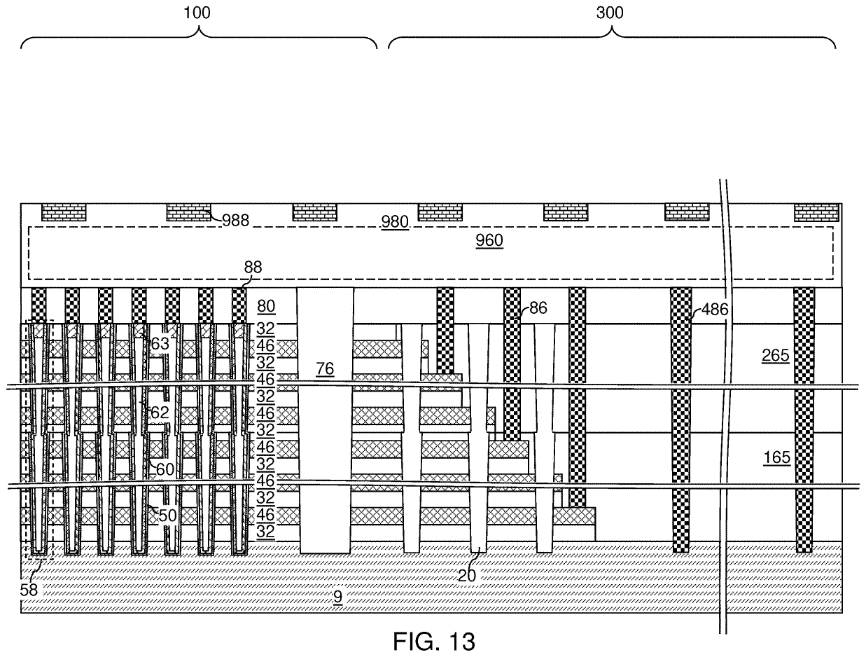

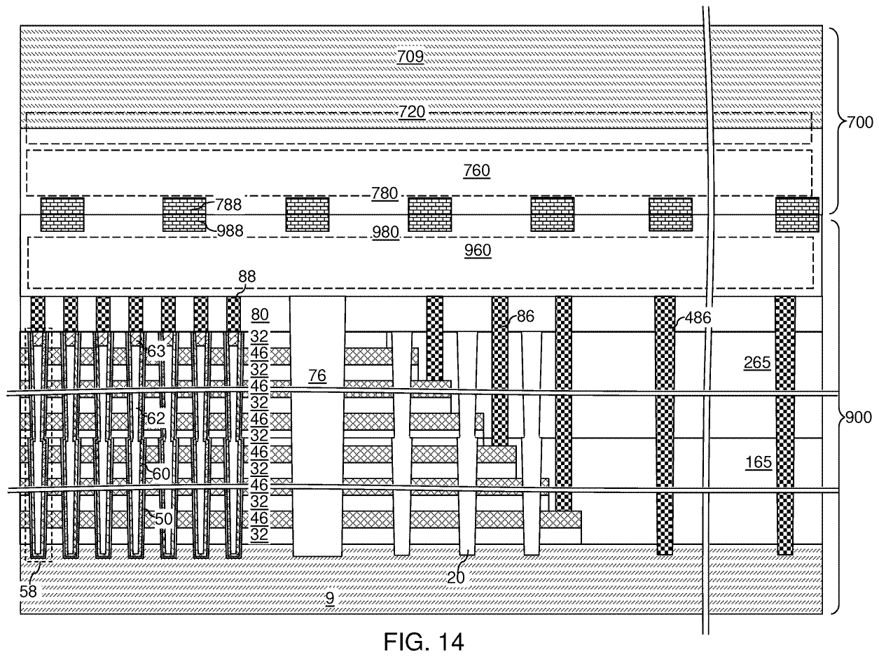

Referring to FIG. 13, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

Referring to FIG. 14, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

The logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

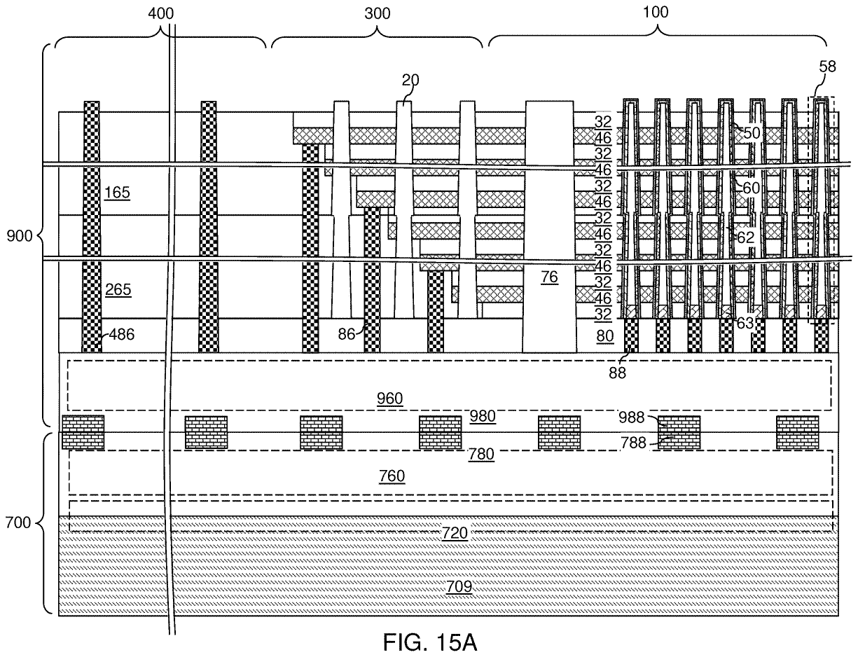

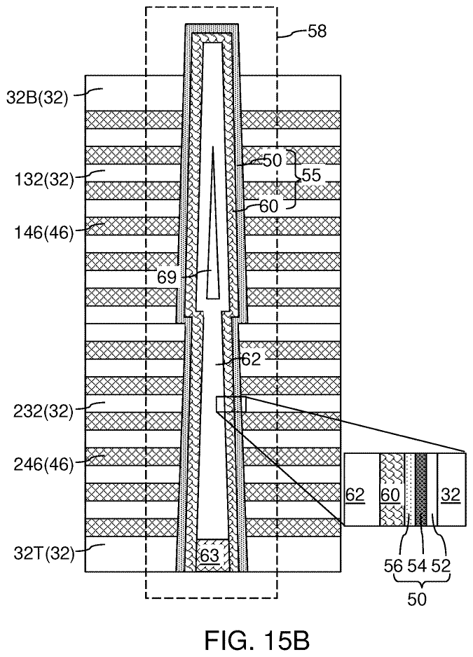

Referring to FIGS. 15A and 15B, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

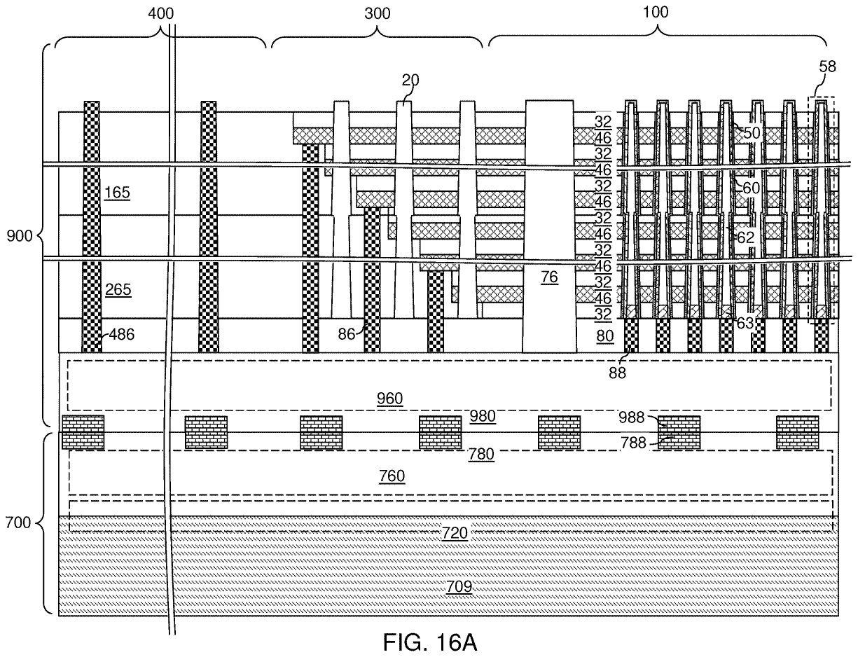

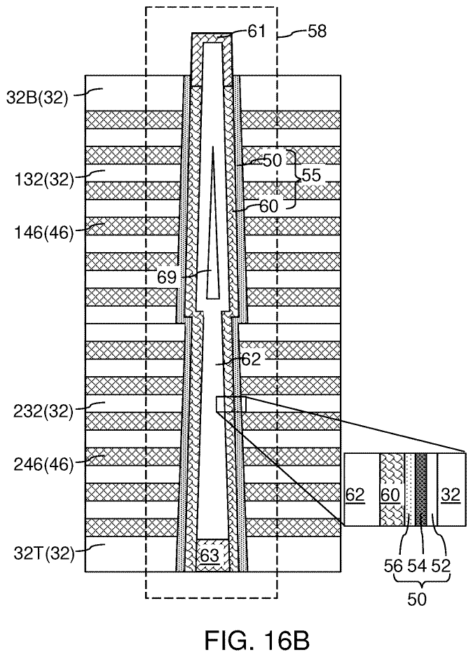

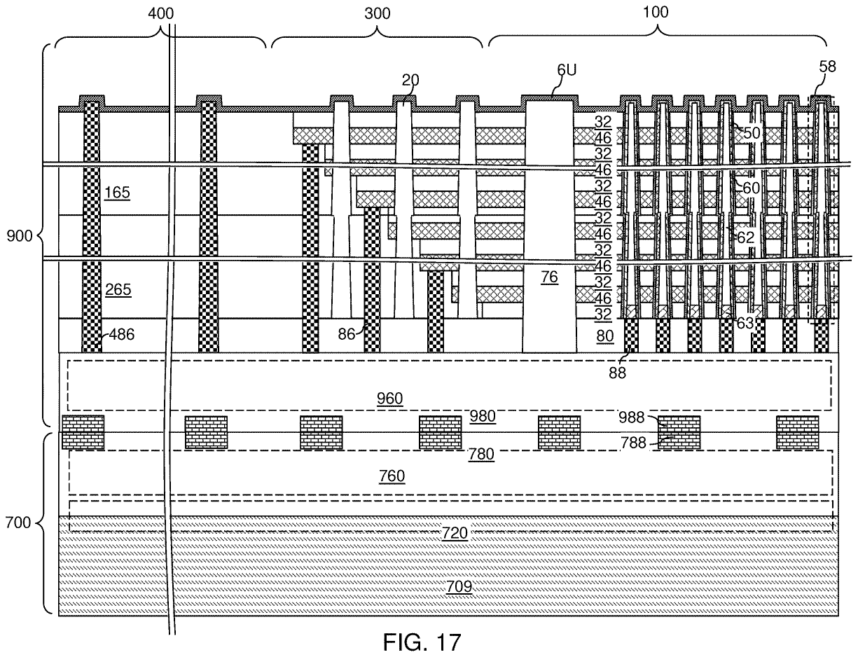

In one embodiment, at least a terminal step of at least one removal process that is employed to remove the carrier substrate 9 may comprise a selective wet etch process that etches the material of the carrier substrate 9 (such as a semiconductor material of the carrier substrate 9) selective to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Backside end surfaces of the support pillar structures 20 can be physically exposed upon removal of the carrier substrate 9. The optional outer blocking dielectric layers 44 are illustrated in FIG. 16B, each of which embeds a respective electrically conductive layer 46. Alternatively, the optional outer blocking dielectric layers 44 may be omitted.

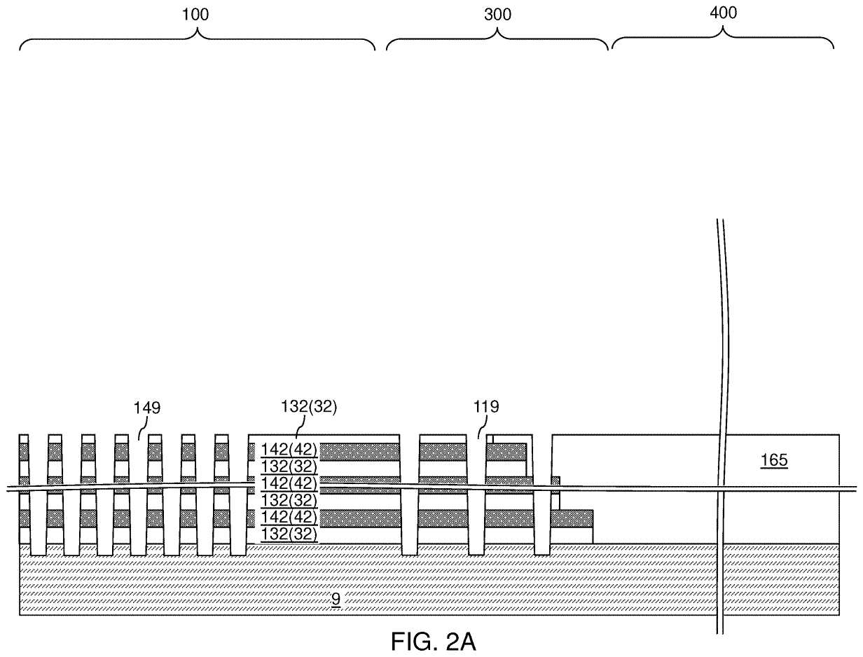

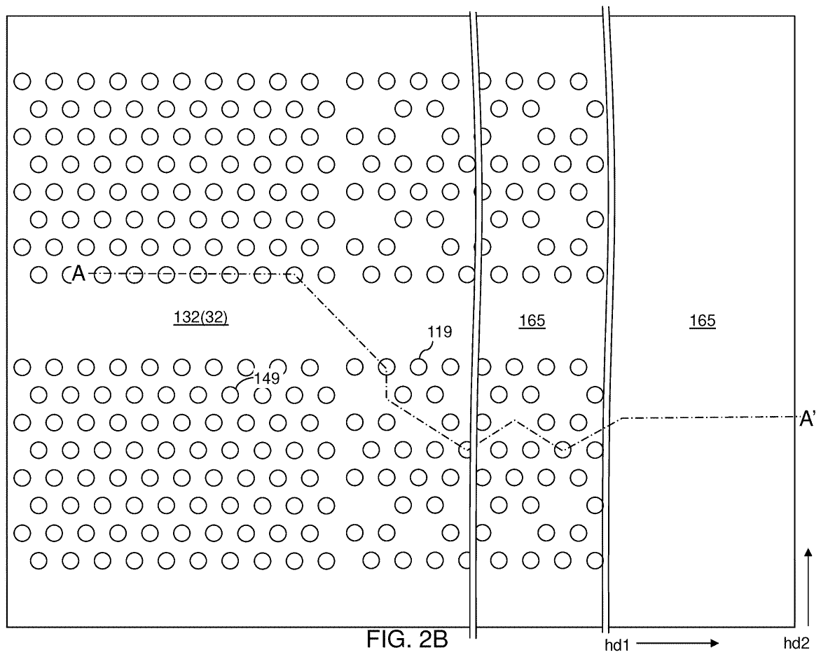

Referring collectively to FIGS. 1-15B and according to an embodiment of the present disclosure, a device structure can be formed by forming an alternating stack (32, 42) of insulating layers 32 and spacer material layers (such as sacrificial material layer 42) over a carrier substrate 9 such that the spacer material layers are formed as, or are subsequently replaced with, electrically conductive layers 46; forming a dielectric material portion (such as the stepped dielectric material portions (165, 265)) adjacent to the alternating stack (32, 42); forming memory openings 49 through the alternating stack (32, 46); forming memory opening fill structures 58 in the memory openings 49, wherein each of the memory opening fill structures 58 comprises a respective vertical stack of memory elements (e.g., portions of the memory film 50) and a respective vertical semiconductor channel 60; and removing the carrier substrate 9.

Referring to FIGS. 16A and 16B, a sequence of wet etch steps can be performed to sequentially remove portions of the memory film 50 that are exposed on the backside of the alternating stack (32, 46). For example, the blocking dielectric layer 52, the memory material layer 54, and the optional dielectric liner 56 (which may be, for example, a tunneling dielectric layer) of each memory film 50 can be removed from a region that is more distal from the bonding interface between the memory die 900 and the logic die 700 than a physically exposed planar surface of the bottommost insulating layer 32B is from the bonding interface. For the purpose of convenience, geometrical features of the first exemplary structure and other exemplary structures in the present disclosure may be described in an orientation in which the logic die 700 overlies the memory die 900. Viewed in this orientation, the blocking dielectric layer 52, the memory material layer 54, and the optional dielectric liner 56 (which may be, for example, a tunneling dielectric layer) of each memory film 50 can be removed from below the horizontal plane including the bottom surface of the bottommost insulating layer 32B. Dopants of the second conductivity type (such as n-type dopants, for example phosphorus dopants) may be implanted into the exposed bottom portion of the vertical semiconductor channel to form a doped source region 61, as shown in FIG. 16B.

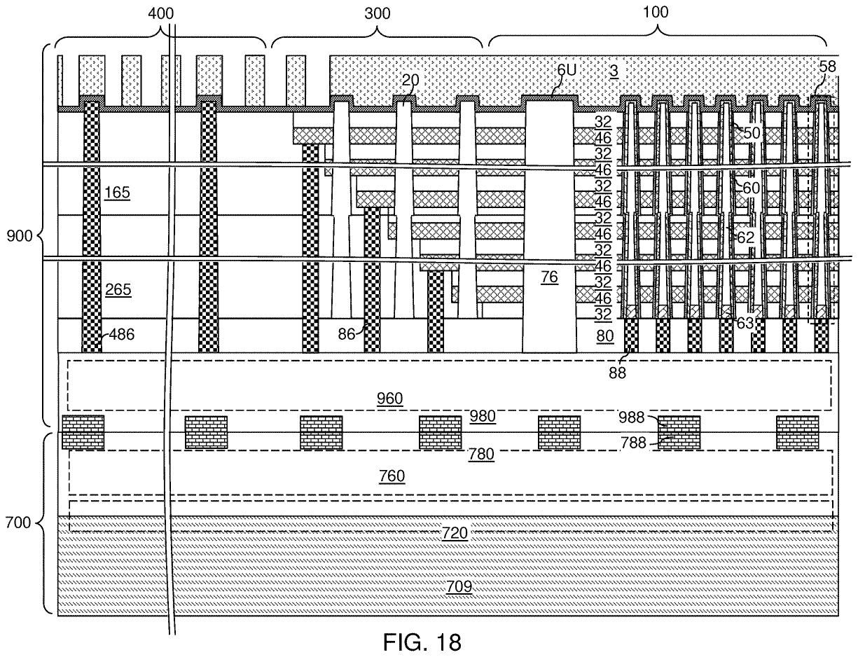

Referring to FIG. 17, a doped semiconductor material layer can be formed by deposition of a semiconductor material on the backside surface of the bottommost insulating layer 32B. In one embodiment, the doped semiconductor material layer can be deposited by a plasma-enhanced chemical vapor deposition at a temperature of 400 degrees Celsius or less. The doped semiconductor material layer may be deposited with in-situ doping with dopants of the second conductivity type, or may be deposited without electrical dopants, and may be subsequently doped with dopants of the second conductivity type by ion implantation or by plasma doping. In one embodiment, the doped semiconductor material layer may comprise silicon, such as polysilicon or amorphous silicon. In another embodiment, the doped semiconductor material layer may comprise amorphous or polycrystalline silicon-germanium containing germanium at an atomic percentage of 25% or less. The thickness of the doped semiconductor material layer may be in a range from 10 nm to 200 nm, such as from 20 nm to 100 nm, although lesser and greater thicknesses may also be employed.

In one embodiment, the electrical dopants of the second conductivity type in the doped semiconductor material layer are not electrically activated due to the low temperature of the deposition process employed to form the doped semiconductor material layer. The doped semiconductor material layer in a state in which the electrical dopants therein are not electrically activated is herein referred to as an unactivated semiconductor layer 6U. Thus, the unactivated semiconductor layer 6U is formed underneath the bottommost surface of the alternating stack (32, 46) and the stepped dielectric material portions (165, 265), and on bottom surfaces of the doped source regions 61 of the vertical semiconductor channels 60.

According to an embodiment of the present disclosure, the unactivated semiconductor layer 6U comprises a silicon-based semiconductor material containing silicon at an atomic percentage greater than 75%, and/or greater than 90%, and/or greater than 95%, and an anneal process is used to active the dopants to increase the electrical conductivity of the semiconductor layer. The atomic concentration of electrical dopants in the unactivated semiconductor layer 6U may be in a range from 5.0×10¹⁸/cm³ to 2.0×10²¹/cm³, although lesser and greater atomic concentrations may also be employed.

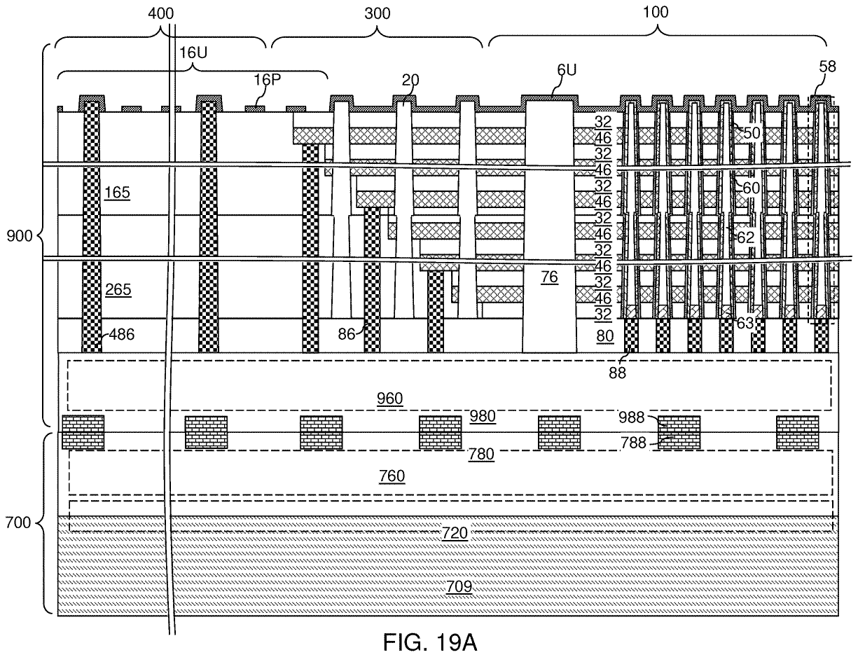

Referring to FIG. 18, a photoresist layer can be applied on the unactivated semiconductor layer 6U, and can be lithographically patterned to form a patterned photoresist layer 3 containing at least one opening in areas that overlie the peripheral region 400, i.e., a region in which connection via structures 486 are present. The pattern of the at least one opening may comprise a two-dimensional array of discrete openings with photoresist material portions between the openings. Alternatively, the pattern of the at least one opening may comprise an interconnected continuous opening that laterally surrounds a two-dimensional array of discrete photoresist material portions that are patterned portions of the photoresist layer. The lateral dimension (e.g., width or diameter) the photoresist material portions in the patterned photoresist layer 3 may be in a range from 5 nm to 500 nm, such as from 100 nm to 300 nm. Preferably, the lateral dimension is smaller than a peak wavelength of a laser beam that will be used for dopant activation in the subsequent step described below. An end surface of each connection via structure 488 may be entirely covered by a respective portion of the patterned photoresist layer 3, or may be only partially covered by the patterned photoresist layer 3. For example, if the pattern of the at least one opening in the patterned photoresist layer 3 comprises a two-dimensional array of discrete openings, the maximum lateral dimension (such as a diameter) of the discrete openings may be in a range from 5 nm to 500 nm. If the pattern of the at least one opening in the patterned photoresist layer 3 comprises an interconnected continuous opening that laterally surrounds a two-dimensional array of discrete photoresist material portions, the maximum dimension of the gaps between neighboring pairs of discrete photoresist material portions may be in range from 5 nm to 500 nm. Preferably, the maximum dimension of any gap in the patterned photoresist layer 3 is less than the wavelength of a laser beam to be subsequently employed for a laser anneal process, which may be about 500 nm.

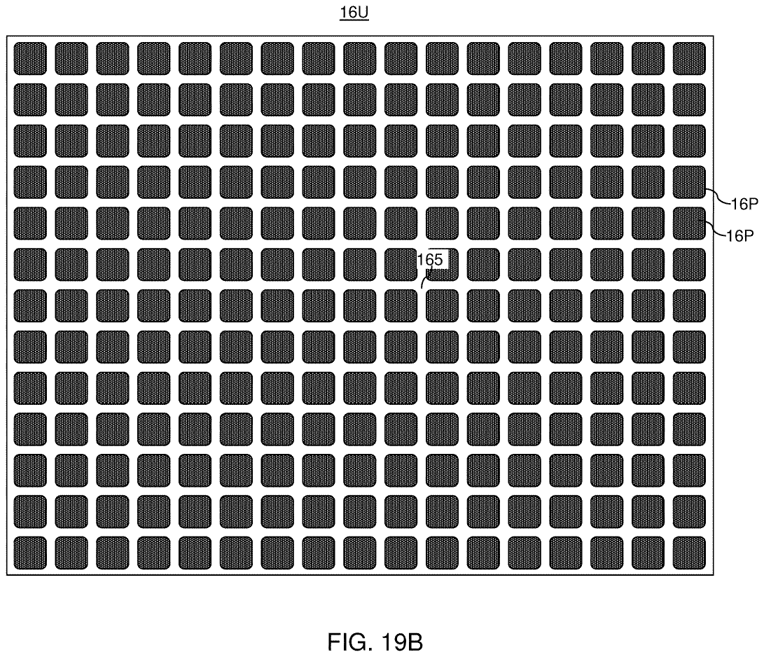

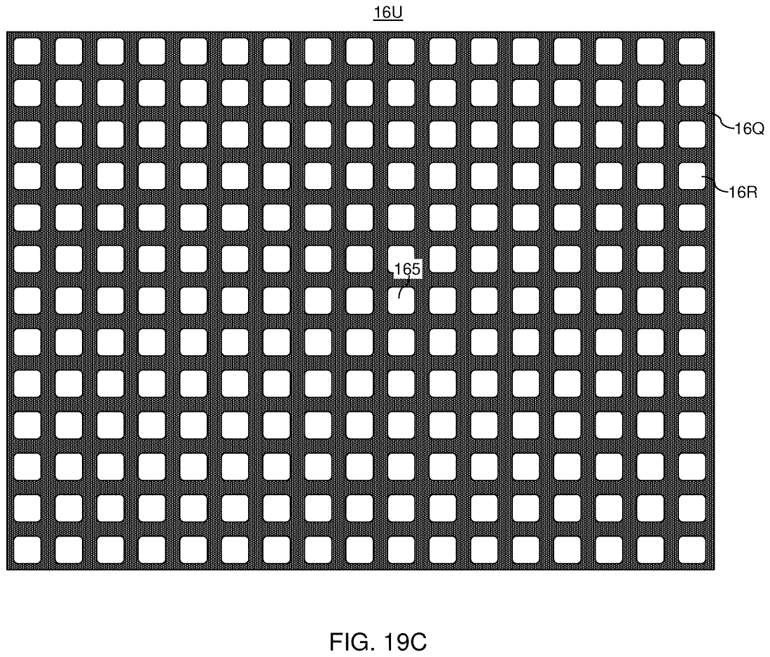

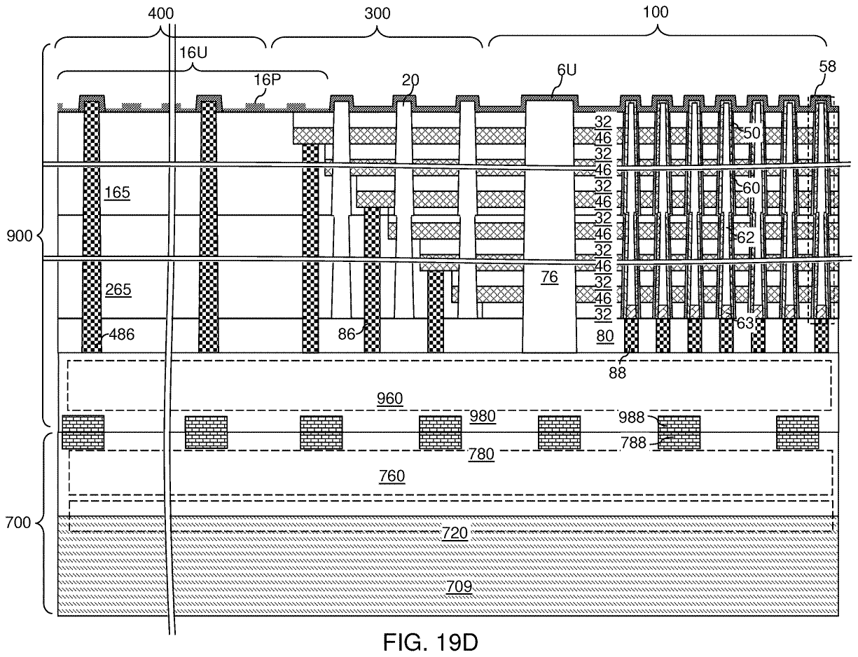

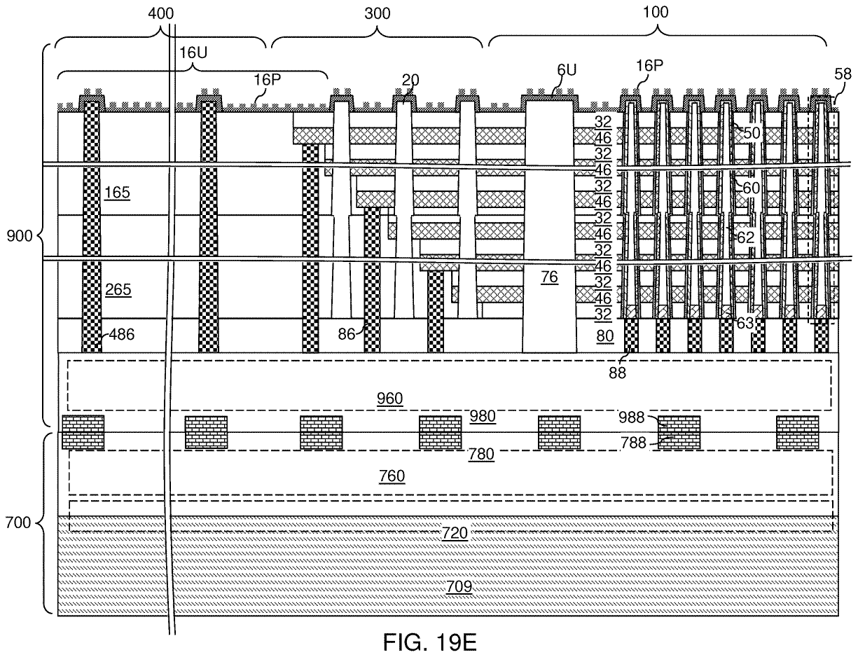

Referring to FIGS. 19A-19C, the unactivated semiconductor layer 6U can be patterned by performing an anisotropic etch process that transfers a pattern in the patterned photoresist layer 3 at least partially through the unactivated semiconductor layer 6U. In the embodiment shown in FIG. 19A, the anisotropic etch process transfers the pattern in the patterned photoresist layer 3 completely through the unactivated semiconductor layer 6U. A portion of the unactivated semiconductor layer 6U that replicates the pattern of the at least one opening in the patterned photoresist layer 3 is herein referred to as a semiconductor textured-pattern structure 16U. Thus, the textured pattern in the unactivated semiconductor layer 6U comprises a replica of a pattern in the patterned photoresist layer 3.

The semiconductor textured-pattern structure 16U includes a nanoscale pattern having geometrical features having lateral dimensions less than the peak wavelength of a laser beam to be subsequently employed for a laser anneal process, which may be about 500 nm. As used herein, a “textured pattern” refers to a pattern that includes gaps between material portions such that the gaps are capable of inducing optical diffraction for light having a wavelength range from 500 nm to 1,000 nm. The gaps of the textured pattern may have lateral dimensions in a range from 5 nm to 500 nm. The semiconductor textured-pattern structure 16U comprises a textured pattern that is formed within a portion of the unactivated semiconductor layer 6U located at least in the peripheral region 400. The semiconductor textured-pattern structure 16U is formed underneath a dielectric material portion (such as the stepped dielectric material portions (165, 265)). The semiconductor textured-pattern structure 16U includes gaps between neighboring pairs of semiconductor material portions of the unactivated semiconductor layer 6U with a respective gap width in a range from 5 nm to 500 nm.

Generally, the semiconductor textured-pattern structure 16U includes at least one semiconductor material portion. In one embodiment, the at least one semiconductor material portion comprises an array of discrete semiconductor pillar structures 16P in which discrete semiconductor pillar structures 16P are arranged to provide a textured pattern as illustrated in FIG. 19B. In this case, the array of discrete semiconductor pillar structures 16P may comprise a two-dimensional periodic array of discrete semiconductor pillar structures 16P (i.e., nanopillars) each having a diameter in a range from 100 nm to 400 nm.

In another embodiment, the at least one semiconductor material portion comprises a semiconductor material plate 16Q, and the textured pattern comprises an array of discrete openings 16R in the semiconductor material plate 16Q as illustrated in FIG. 19C. In this embodiment, the pitch of the openings 16R is less than peak wavelength of the laser beam, such as less than 500 nm. Thus, an array of nanoholes 16R is formed in the semiconductor material layer 16Q.

In the alternative embodiments shown in FIGS. 19D and 19E, the anisotropic etch process transfers the pattern in the patterned photoresist layer 3 partially through the unactivated semiconductor layer 6U. In this embodiment, the nanopillars 16P protrude from the top surface of the unactivated semiconductor layer 6U. Thus, only the top surface of the unactivated semiconductor layer 6U is textured to form nanofeatures, such as nanopillars 16P. The entire top surface of the unactivated semiconductor layer 6U may be textured, as shown in FIG. 19E, or only the portion of the top surface of the unactivated semiconductor layer 6U located in the peripheral region may be textured, as shown in FIG. 19D.

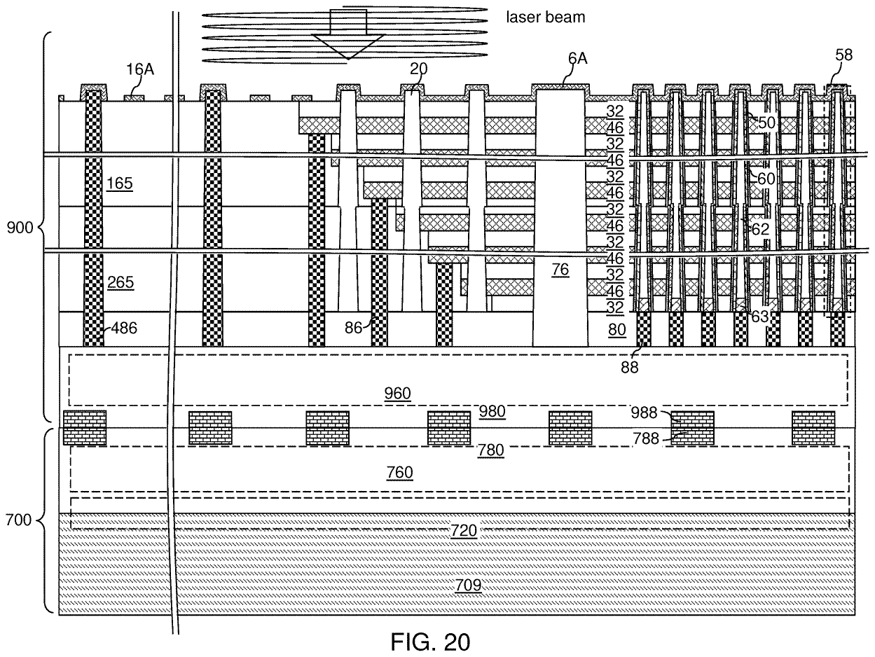

Referring to FIG. 20, a laser anneal process can be performed by irradiating a laser beam on the unactivated semiconductor layer 6U. The peak wavelength of the laser beam may be in a range from 400 nm to 1,000 nm, such as about 500 nm. As discussed above, in one embodiment, the lateral dimension of gaps between neighboring pairs of semiconductor material portions 16P or 16Q in the semiconductor textured-pattern structure 16U is less than the peak wavelength of the laser beam. The laser anneal process converts the unactivated semiconductor layer 6U into a semiconductor source layer 6A comprising an activated doped semiconductor material. The laser anneal process converts the semiconductor textured-pattern structure 16U into an activated semiconductor textured-pattern structure 16A which also comprises the activated doped semiconductor material. In other words, the nanopillars 16P or the semiconductor plate 16Q comprises an activated doped semiconductor (e.g., polysilicon or polycrystalline silicon-germanium) material. If the unactivated semiconductor layer 6U comprised an amorphous material (e.g., amorphous silicon), then it may be crystallized into a polycrystalline (e.g., polysilicon) material during the laser anneal. In the alternative embodiments in which the structures of FIG. 19D or FIG. 19E is laser annealed, the activated semiconductor textured-pattern structure 16A may be formed on a part of or on the entire semiconductor source layer 6A, respectively.

Without wishing to be bound by a particular theory, it is believed the textured pattern (e.g., pattern of nanoscale features) in the semiconductor textured-pattern structure 16U enhances the laser beam absorption efficiency through at least one optical effect, and thus, reduces the intensity of the laser beam that enters the dielectric material portions (165, 265). In is believed that the nanoscale openings in the semiconductor textured-pattern structure 16U have a net effect of scattering the laser beam so that the intensity of the laser beam that is transmitted into the dielectric material portions (165, 265) is reduced. Therefore, the laser beam either does not reach the low melting point copper bonding pads (788, 988) located on the opposite side of the dielectric material portions (165, 265) in the peripheral region 400, or the laser beam intensity is significantly attenuated by the textured-pattern structure 16U, and the copper bonding pads are not melted by the laser beam. Thus, a laser beam blocking structure may be omitted in the peripheral region 400, which reduces process complexity.

Without wishing to be bound by a particular theory, it is believed that enhancement of laser absorption by a textured pattern containing nanofeatures (e.g., nanopillars and/or nanoholes) involves increasing the surface area that interacts with the laser beam, as well as inducing localized electromagnetic field enhancements. Without wishing to be bound by a particular theory, it is believed that when a laser beam encounters a textured nanopattern having a pitch less than the wavelength of the laser beam, the irregularities of the texture lead to multiple optical phenomena: diffraction, scattering, and interference. These effects collectively increase the probability of light absorption in the textured nanopattern. Thus, increased absorption of the laser beam photons by the semiconductor textured-pattern structure 16U either blocks the laser beam or reduces the intensity of the laser beam that impinges into the stepped dielectric material portions (165, 265), and protects bonding pads from melting.

In one embodiment, the lateral dimensions of the textured pattern, and specifically the pitch and/or the spacing between structural elements of the textured pattern, should be less than the peak wavelength of the incident laser radiation. Without wishing to be bound by a particular theory, it is believed that this generates near-field radiation effects, where the electromagnetic fields are enhanced in the vicinity of the textured surface. These near-field effects lead to more efficient absorption of the laser beam in the adjacent semiconductor or dielectric material.

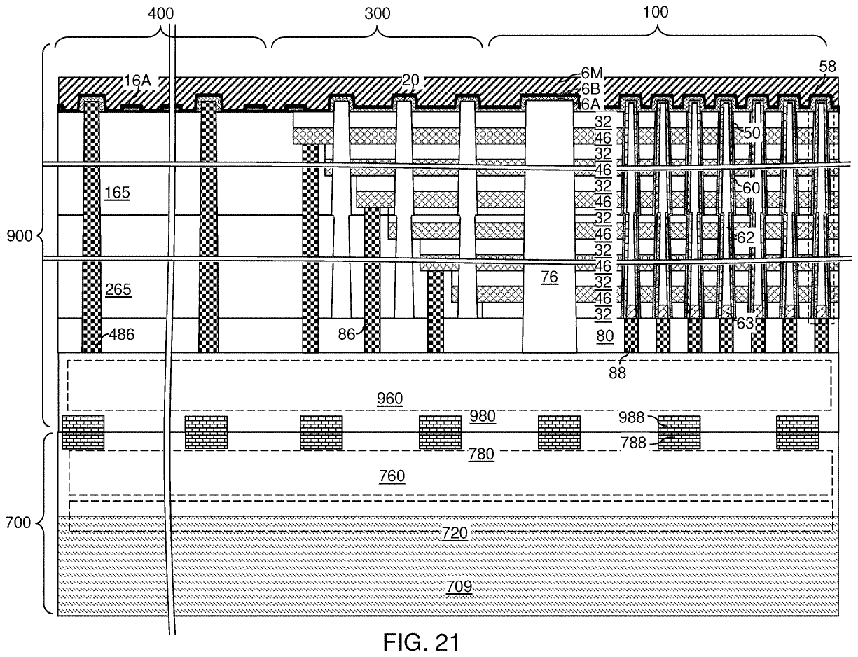

Referring to FIG. 21, a metallic source layer (6B, 6M) can be formed on the backside of the semiconductor source layer 6A and the activated semiconductor textured-pattern structure 16A. The metallic source layer (6B, 6M) may include a metallic barrier liner 6B comprising a conductive metallic nitride material (such as TiN, TaN, WN, and/or MoN), and a metal layer 6M located on the metallic barrier liner 6B and comprising a metal (such as W, Al, Cu, Co, Mo, Ru, etc.) having a higher electrical conductivity than the conductive metallic nitride material.

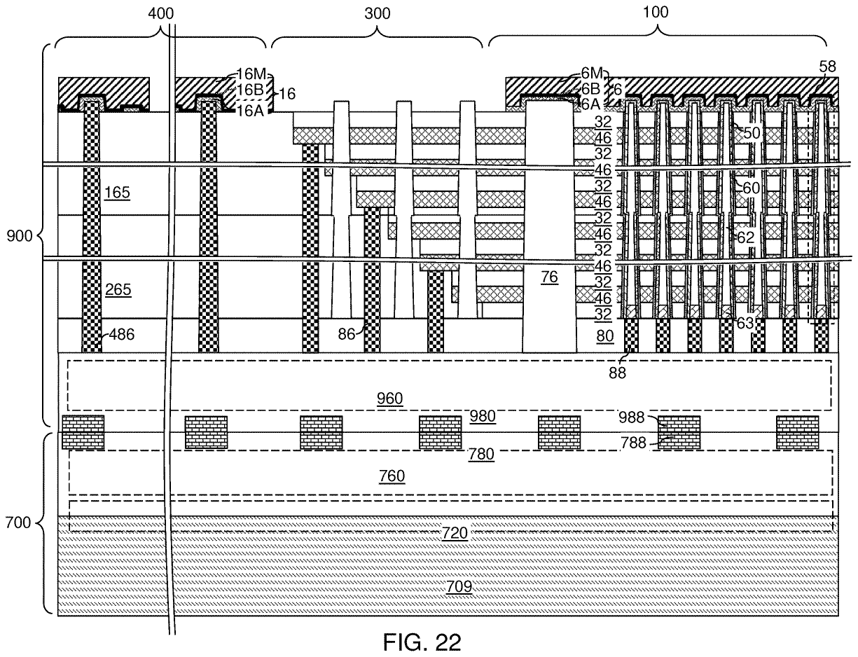

Referring to FIG. 22, a photoresist layer (not shown) can be applied over the metallic source layer (6B, 6M), and can be lithographically patterned into discrete photoresist material portions that over a respective area of the memory array region 100 or a respective one of the connection via structures 488. The metallic source layer (6B, 6M), the semiconductor source layer 6A, and the activated semiconductor textured-pattern structure 16A can be patterned by performing an anisotropic etch process, which transfers the pattern in the photoresist layer through the metallic source layer (6B, 6M), the semiconductor source layer 6A, and the activated semiconductor textured-pattern structure 16A.

Each patterned portion of the metallic source layer (6B, 6M) and the semiconductor source layer 6A comprises a source layer 6 that contacts end portions of a respective group of vertical semiconductor channels 60 (e.g., the doped source regions 61 in the end portions of the vertical semiconductor channels 60). Patterned portions of the metallic source layer (6B, 6M) and the activated semiconductor textured-pattern structure 16A comprise conductive pad structures 16 that contact an end surface of a respective one of the connection via structures 488. Each conductive pad structure 16 may comprise a stack of an activated semiconductor textured-pattern structure 16A, a textured metallic barrier liner 16B extending into the gaps within the activated semiconductor textured-pattern structure 16A, and a metal plate 16M.

The first exemplary structure may include three-dimensional memory device comprising: an alternating stack (32, 46) of insulating layers 32 and electrically conductive layers 46 that alternate along a vertical direction; memory openings 49 vertically extending through the alternating stack (32, 46); memory opening fill structures 58 located in the memory openings 49 and comprising a respective vertical stack of memory elements and a respective vertical semiconductor channel 60; a dielectric material portion (such as the stepped dielectric material portions (165, 265)) located adjacent to the alternating stack (32, 46); a semiconductor source layer 6A comprising a polycrystalline doped semiconductor material, underlying a bottommost surface of the alternating stack (32, 46), and contacting a bottom end of the vertical semiconductor channels 60; and at least one semiconductor material portion (as embodied as an activated semiconductor textured-pattern structure 16A) underlying the dielectric material portion (such as the stepped dielectric material portions (165, 265)), having a same material composition as the semiconductor source layer 6A, and having a textured pattern including gaps having a respective gap width in a range from 5 nm to 500 nm. In one embodiment, the polycrystalline doped semiconductor material is absent within the areas of the gaps. In one embodiment, the gaps may be at least partly filled with a textured metallic barrier liner 16B.

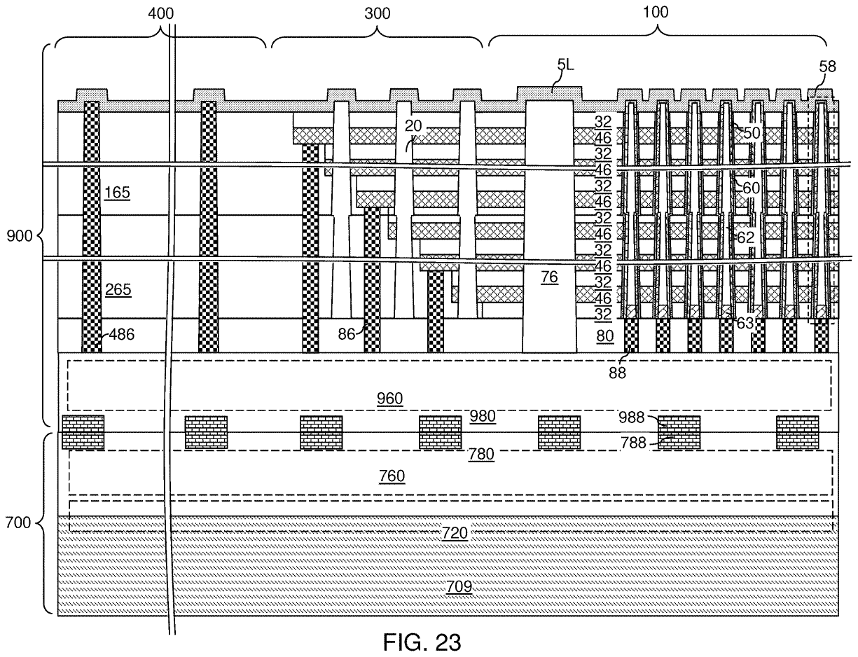

Referring to FIG. 23, a second exemplary structure according to a second embodiment of the present disclosure may be derived from the first exemplary structure illustrated in FIGS. 16A and 16B by forming a matrix material layer 5L on the backside surface of the bottommost insulating layer 32 and on the physically exposed surfaces of the vertical semiconductor channels 60. The matrix material layer 5L comprises a sacrificial dielectric material that can be subsequently removed selective to the materials of the bottommost insulating layer 32 and the vertical semiconductor channels 60. In one embodiment, the matrix material layer 5L may comprise silicon nitride, silicon oxynitride, borosilicate glass, borophosphosilicate glass, or organosilicate glass. The thickness of the matrix material layer 5L may be in a range from 100% to 1,000% of an unactivated semiconductor layer to be subsequently formed. For example, the thickness of the matrix material layer 5L may be in a range from 100 nm to 1,000 nm, such as from 200 nm to 400 nm, although lesser and greater thicknesses may also be employed.

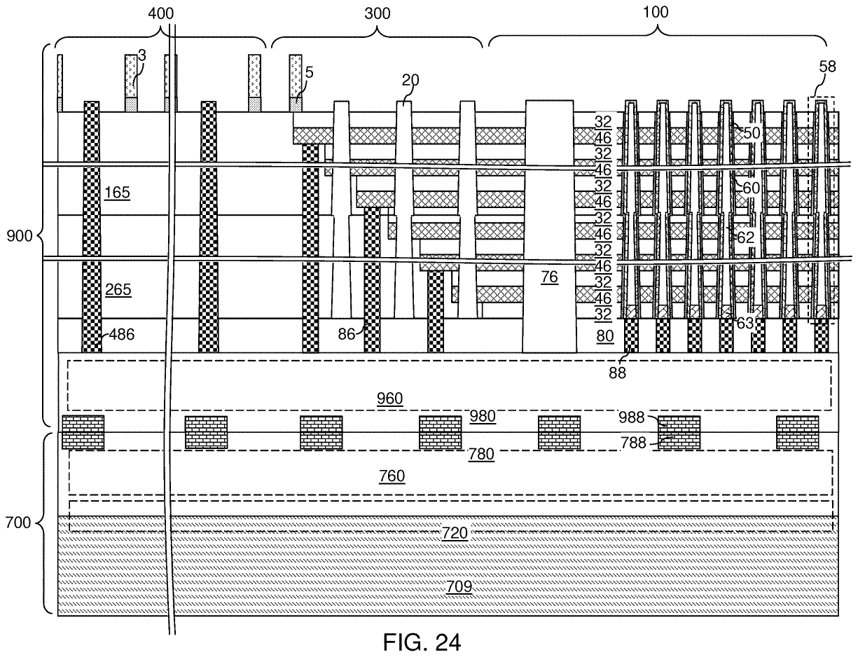

Referring to FIG. 24, a patterned photoresist layer 3 can be formed over the matrix material layer 5L. In one embodiment, the patterned photoresist layer 3 does not cover the memory array region 100 or the contact region 300, and includes at least one opening in the peripheral region 400. The pattern of the at least one opening may comprise a two-dimensional array of discrete openings, or may comprise an interconnected continuous opening that laterally surrounds a two-dimensional array of discrete photoresist material portions that are patterned portions of the photoresist layer, as described above with respect to the first embodiment. In an alternative embodiment, the patterned photoresist layer 3 covers parts of the memory array region 100 and the contact region 300, and includes at least one opening over these regions. The lateral dimensions of features of the at least one opening in the patterned photoresist layer 3 may be in a range from 5 nm to 500 nm, such as from 100 nm to 300 nm. An end surface of each connection via structure 488 may be entirely covered by a respective portion of the patterned photoresist layer 3, or may be only partially covered by the patterned photoresist layer 3, or may be not covered by the patterned photoresist layer 3. For example, if the pattern of the at least one opening in the patterned photoresist layer 3 comprises a two-dimensional array of discrete openings, the maximum lateral dimension (such as a diameter) of the discrete openings may be in a range from 5 nm to 500 nm. If the pattern of the at least one opening in the patterned photoresist layer 3 comprises an interconnected continuous opening that laterally surrounds a two-dimensional array of discrete photoresist material portions, the maximum dimension of the gaps between neighboring pairs of discrete photoresist material portions may be in range from 5 nm to 500 nm. Preferably, the maximum dimension of any gap in the patterned photoresist layer 3 is less than the peak wavelength of a laser beam to be subsequently employed for a laser anneal process, which may be about 500 nm.

An anisotropic etch process can be performed to etch unmasked portions of the matrix material layer 5L. The anisotropic etch process can etch the material of the matrix material layer 5L selective to the semiconductor material of the vertical semiconductor channels 60, and preferably selective to the material of the bottommost insulating layer 32B. Remaining portions of the matrix material layer 5L comprise a dielectric textured-pattern structure 5. In one embodiment, the dielectric textured-pattern structure 5 may be located only in the peripheral region. In an alternative embodiment, the dielectric textured-pattern structure 5 may also be located in the contact region 300 and in the memory array region 100, similar to the pattern shown in FIG. 19E.

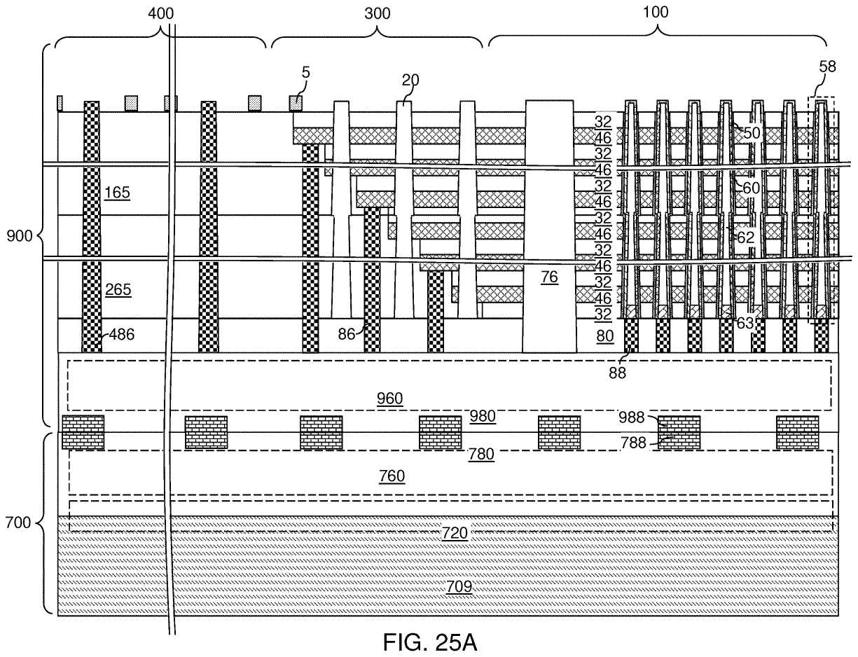

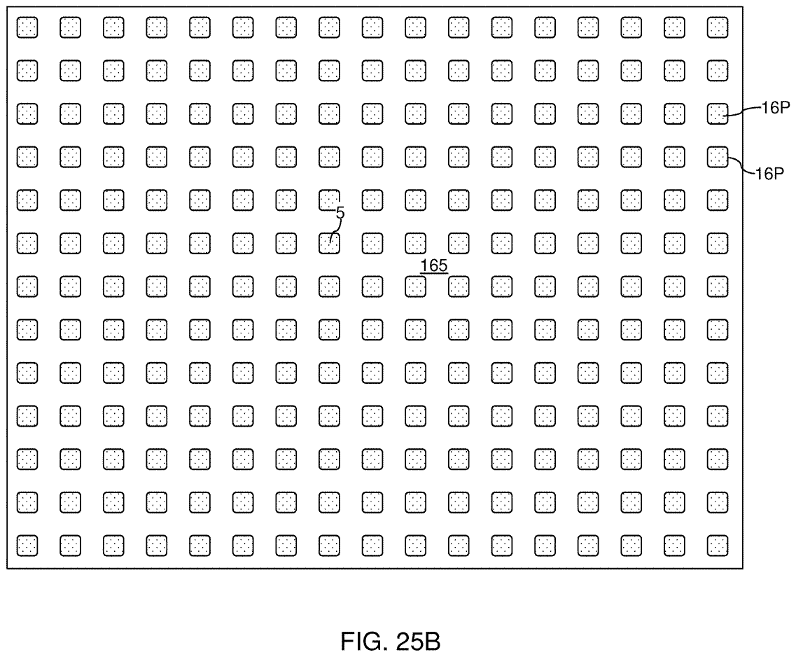

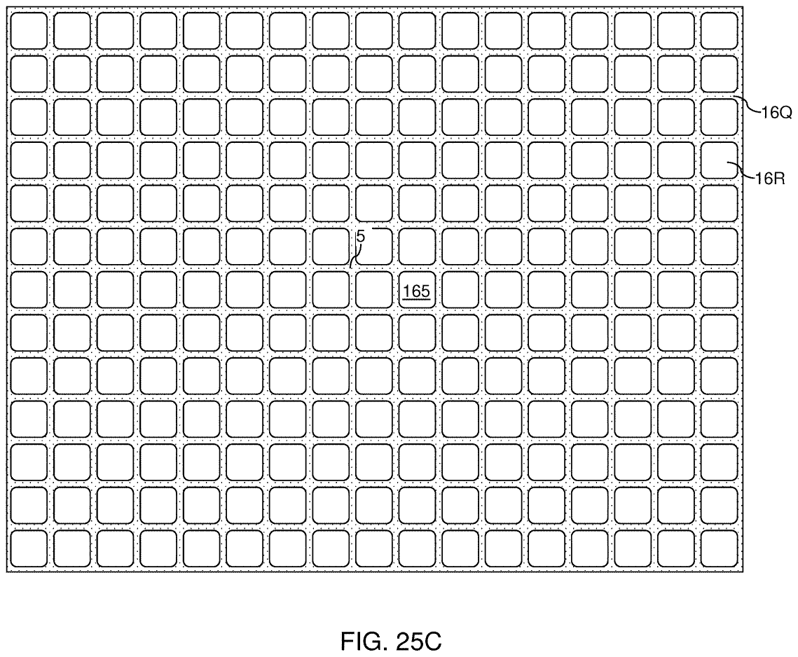

Referring to FIGS. 25A-25C, the patterned photoresist layer 3 can be removed selective to the dielectric textured-pattern structure 5, the vertical semiconductor channels 60, and the bottommost insulating layer 32B.

The dielectric textured-pattern structure 5 includes a nanoscale pattern having geometrical features having lateral dimensions less than the peak wavelength of a laser beam to be subsequently employed for a laser anneal process, which may be about 500 nm. The gaps of the textured pattern may have lateral dimensions in a range from 5 nm to 500 nm, and the pitch of the textured pattern may also be in a range from 5 nm to 500 nm. The dielectric textured-pattern structure 5 comprises a textured pattern that is formed at least within the peripheral region 400, and optionally within the contact region 300 and the memory array region 100. The dielectric textured-pattern structure 5 is formed underneath a dielectric material portion (such as the stepped dielectric material portions (165, 265)). The dielectric textured-pattern structure 5 includes nanoscale gaps between neighboring pairs of dielectric material portions with a respective nanoscale gap width in a range from 5 nm to 500 nm.

The dielectric textured-pattern structure 5 includes at least one dielectric material portion. In one embodiment, the at least one dielectric material portion comprises an array of discrete dielectric pillar structures 5P in which discrete dielectric pillar structures 5P are arranged to provide a textured pattern as illustrated in FIG. 25B. In this case, the array of discrete dielectric pillar structures 5P may comprise a two-dimensional periodic array of discrete dielectric pillar structures 5P each having a width (e.g., diameter for cylindrical pillar structures) in a range from 100 nm to 400 nm. In another embodiment, the at least one dielectric material portion comprises a dielectric material plate 5Q, and the textured pattern comprises an array of discrete openings 5R in the dielectric material plate as illustrated in FIG. 25C. In one embodiment, the dielectric textured-pattern structure 5 protrudes away from the stepped dielectric material portion 165. In one embodiment, the dielectric textured-pattern structure 5 comprises a two-dimensional periodic array of patterned dielectric material portions each having a lateral dimension in a range from 20 nm to 300 nm.

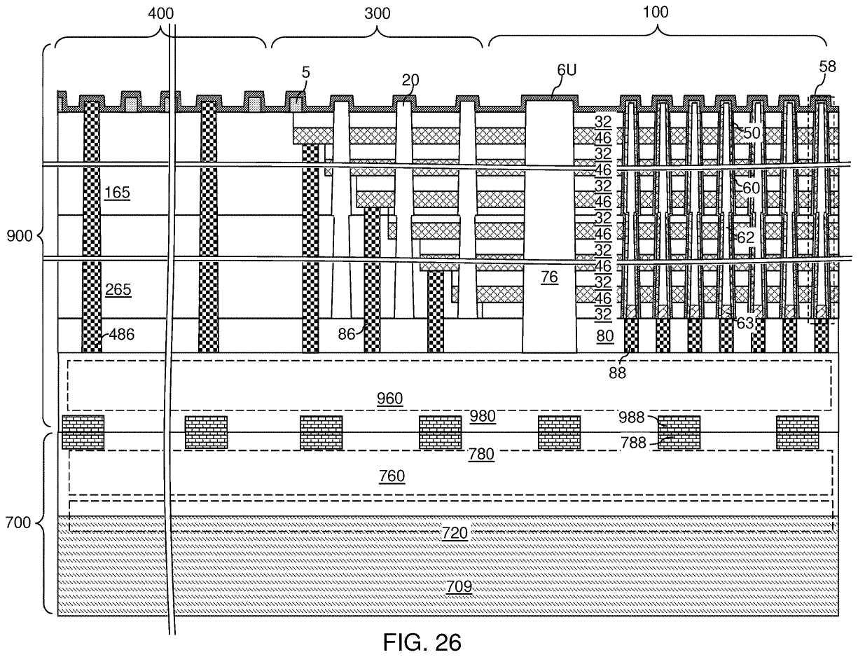

Referring to FIG. 26, the processing steps described with reference to FIG. 17 can be performed to form an unactivated semiconductor layer 6U. The unactivated semiconductor layer 6U can be formed underneath the bottommost surface of the alternating stack (32, 46) and on bottom surfaces of the vertical semiconductor channels 60 and on the dielectric textured-pattern structure 5. The portion of the unactivated semiconductor layer 6U at least in the peripheral region 400 is formed on the dielectric textured-pattern structure 5. The textured pattern in the dielectric textured-pattern structure 5 is replicated in the overlying portion of the unactivated semiconductor layer 6U at least in the peripheral region 400 and optionally also in the contact region 300 and in the memory array region 100. As such, a portion of the unactivated semiconductor layer 6U located on the dielectric textured-pattern structure 5 has a textured pattern. Generally, the textured pattern in the portion of the unactivated semiconductor layer 6U located on the dielectric textured-pattern structure 5 may include gaps between neighboring pairs of vertically-extending portions with a respective gap width in a range from 5 nm to 500 nm.

In one embodiment, the dielectric textured-pattern structure 5 has a thickness in a range from 100% to 1,000% of a portion of the unactivated semiconductor layer 6U that contacts the bottommost surface of the alternating stack (32, 46). In one embodiment, the unactivated semiconductor layer 6U continuously extends underneath an entirety of the bottom surface of the dielectric material portion (such as the stepped dielectric material portion (165) without an opening therethrough. Gaps are present between neighboring pairs of downward-protruding portions of the unactivated semiconductor layer 6U that underlie the dielectric textured-pattern structure 5.

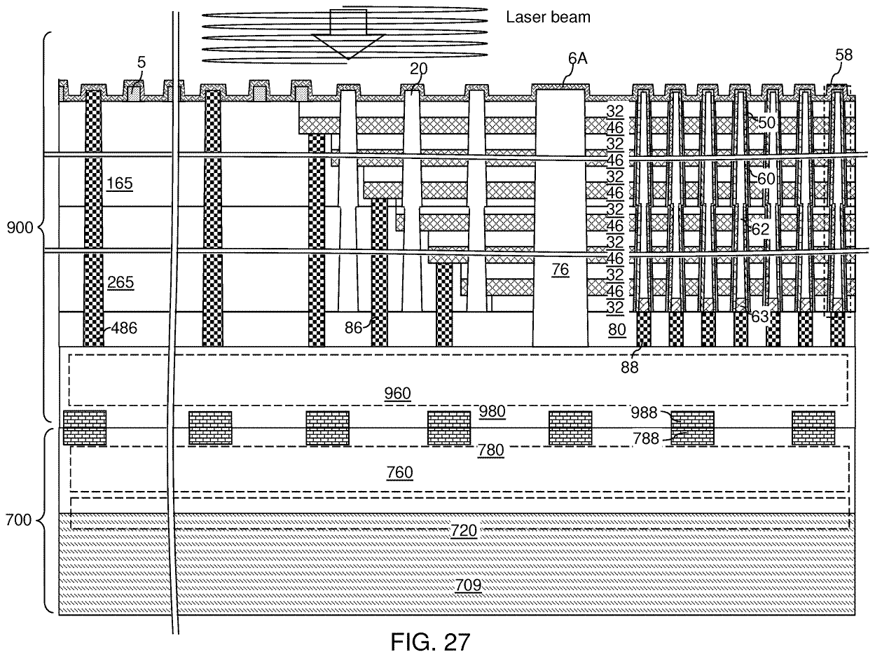

Referring to FIG. 27, a laser anneal process can be performed by irradiating a laser beam on the unactivated semiconductor layer 6U. The peak wavelength of the laser beam may be in a range from 400 nm to 1,000 nm, such as about 500 nm. The lateral dimension of gaps between neighboring pairs of semiconductor material portions in the unactivated semiconductor layer 6U is less than the peak wavelength of the laser beam. The laser anneal process converts the unactivated semiconductor layer 6U into a semiconductor source layer 6A including a layer of an activated doped semiconductor material.

According to as aspect of the present disclosure, the textured pattern in the unactivated semiconductor layer 6U enhances the absorption efficiency of the unactivated semiconductor layer 6U through optical effects, and thus, reduces the intensity of the laser beam that enters the dielectric material portions (165, 265). As discussed above, the nanoscale openings in the unactivated semiconductor layer 6U have a net effect of scattering the laser beam so that the intensity of the laser beam that is irradiated into the dielectric material portions (165, 265) is reduced, and melting of the bonding pads is prevented.

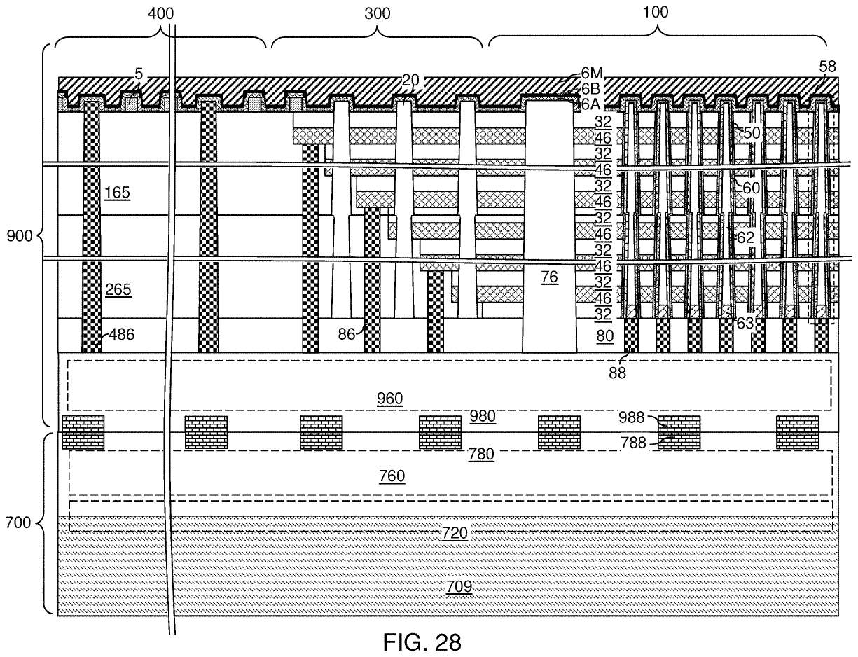

Referring to FIG. 28, a metallic source layer (6B, 6M) can be formed on the backside of the semiconductor source layer 6A. The metallic source layer (6B, 6M) may include a metallic barrier liner 6B comprising a conductive metallic nitride material (such as TiN, TaN, WN, and/or MoN), and a metal layer 6M located on the metallic barrier liner 6B and comprising a metal (such as W, Al, Cu, Co, Mo, Ru, etc.) having a higher electrical conductivity than the conductive metallic nitride material.

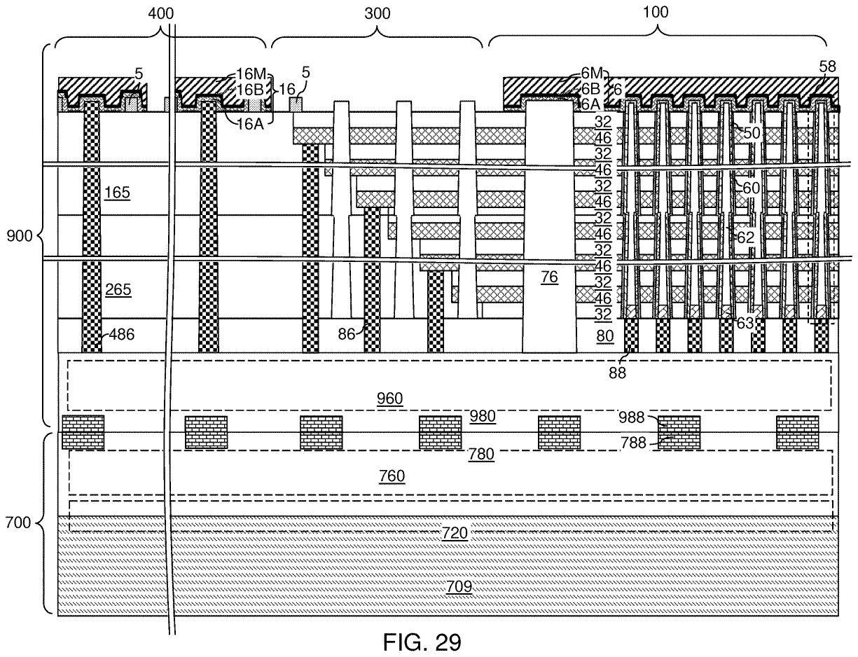

Referring to FIG. 29, a photoresist layer (not shown) can be applied over the metallic source layer (6B, 6M), and can be lithographically patterned into discrete photoresist material portions that over a respective area of the memory array region 100 or a respective one of the connection via structures 488. The metallic source layer (6B, 6M) and the semiconductor source layer 6A can be patterned by performing an anisotropic etch process, which transfers the pattern in the photoresist layer through the metallic source layer (6B, 6M) and the semiconductor source layer 6A.

Patterned portions of the metallic source layer (6B, 6M) and the semiconductor source layer 6A comprise a source layer 6 that contacts end portions of a respective group of vertical semiconductor channels 60 (e.g., that contacts the doped source regions 61). Additional patterned portions of the metallic source layer (6B, 6M) and the semiconductor source layer 6A comprise conductive pad structures 16 that contact an end surface of a respective one of the connection via structures 488. Each conductive pad structure 16 may comprise a stack of an activated semiconductor textured-pattern structure 16A, a textured metallic barrier liner 16B extending into the gaps within the activated semiconductor textured-pattern structure 16A, and a metal plate 16M. The dielectric textured-pattern structure 5 is present between the bottom surface of the stepped dielectric material portions (165, 265) and conductive pad structures 16.

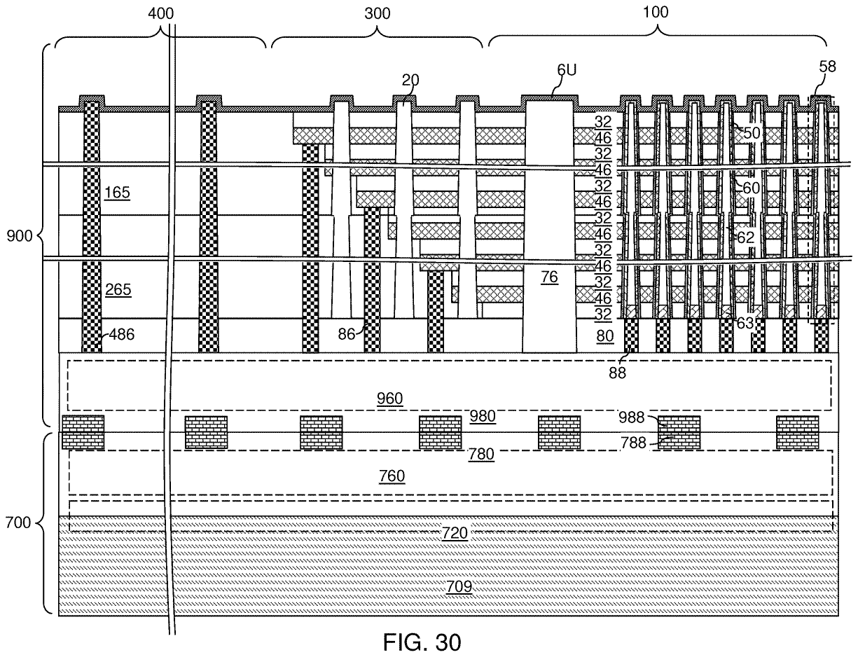

Referring to FIG. 30, a third exemplary structure according to a third embodiment of the present disclosure is illustrated, which may be the same as the first exemplary structure illustrated in FIG. 17.

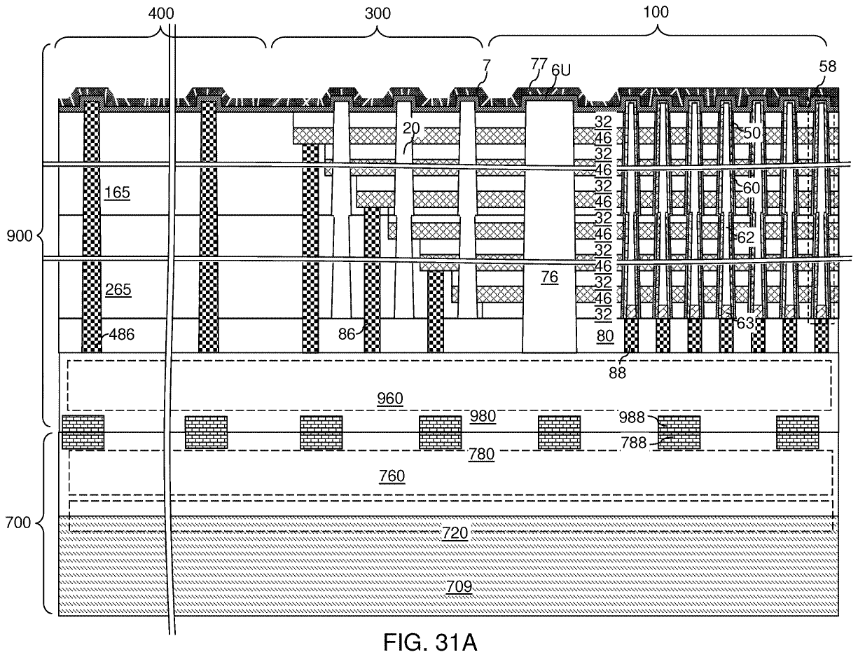

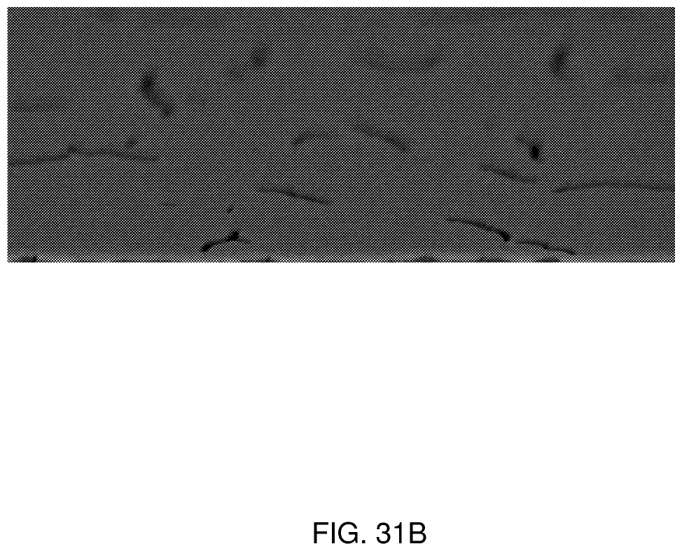

Referring to FIG. 31A a carbon-based material layer 7 can be formed over the unactivated semiconductor layer 6U. The carbon-based material layer 7 comprises carbon at an atomic percentage greater than 50%, and/or greater than 70%, and/or greater than 90%, and/or greater than 95%, such as 96 to 100%. The carbon-based-material layer 7 can be composite primarily of amorphous carbon, and additives can be added to the material composition of the carbon-based material layer 7 to increase the surface tension of the material of the carbon-based material layer 7. In one embodiment, the carbon-based material layer 7 may be composed primarily of amorphous carbon. In one embodiment, the carbon-based material layer 7 may comprise amorphous carbon at an atomic percentage greater than 50%, and/or greater than 70%, and/or greater than 90%, and/or greater than 95%, such as 96 to 100%.

In one embodiment, the carbon-based material layer 7 can be formed by chemical vapor deposition. In one embodiment, the carbon-based material comprises carbon atoms at an atomic percentage greater than 70%. The thickness of the carbon-based material layer 7 may be in a range from 100 nm to 600 nm, such as from 200 nm to 400 nm, although lesser and greater thicknesses may also be employed.

According to an aspect of the present disclosure, the carbon-based material layer 7 may be formed with a random pattern of laterally-extending cracks 77 during deposition. FIG. 31B is a scanning electron micrograph of a carbon-based material layer 7 including laterally-extending cracks 77 therein. In one embodiment, the random pattern of cracks is formed due to internal stress within the carbon-based material layer 7. In one embodiment, the random pattern of laterally-extending cracks 77 may have an average width that is less than a peak wavelength of the laser beam to be subsequently employed to activate electrical dopants in the unactivated semiconductor layer 6U located between the carbon-based material layer 7 and the alternating stack (32, 46). In one embodiment, the average crack width is in a range from 20 nm to 400 nm. In one embodiment, the random pattern of laterally-extending cracks 77 has an average length that is greater than the peak wavelength of the laser beam.

In some embodiments, at least one dopant can be added to the material composition of the carbon-based material layer 7 to increase the internal stress in the carbon-based material layer 7. The at least one dopant may comprise selected from B, P, N or F at a total atomic concentration less than 30%, such as 0.5 to 10%.

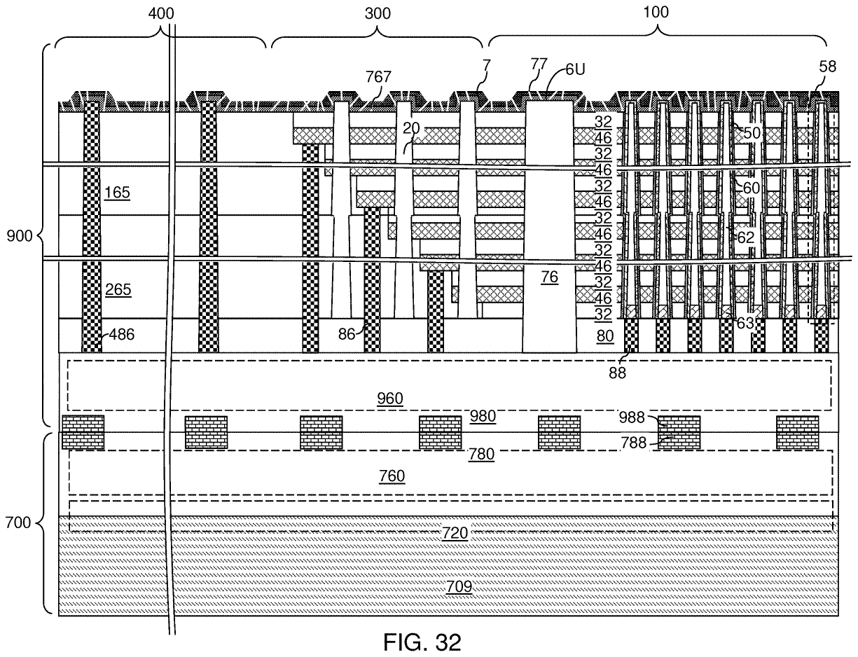

Referring to FIG. 32, the pattern of the laterally-extending cracks 77 in the carbon-based material layer 7 can be transferred through the unactivated semiconductor layer 6U by performing a selective etch process which etches the unactivated semiconductor layer 6U selective to the carbon-based material layer 7. The pattern of the laterally-extending cracks 77 in the carbon-based material layer 7 is replicated as random cracks 767 in the unactivated semiconductor layer 6U. The random cracks 767 extend partially or entirely through the thickness of the unactivated semiconductor layer 6U, depending on the duration of the etch.

A textured pattern comprising the random cracks 767 is formed within a portion of the unactivated semiconductor layer 6U located underneath the stepped dielectric material portion 165. As such, the unactivated semiconductor layer 6U comprises a semiconductor textured-pattern structure. In one embodiment, the textured pattern may be formed throughout the entirety of the unactivated semiconductor layer 6U. The textured pattern includes gaps (i.e., cracks 767) between neighboring pairs of portions of the unactivated semiconductor layer 6U with a respective gap width in a range from 5 nm to 500 nm. Specifically, the random cracks 767 may have a respective gap width in a range from 5 nm to 500 nm, and typically in a range from 20 nm to 200 nm.

The random cracks 767 may extend through the entire thickness of the unactivated semiconductor layer 6U, or may extend only thorough a distal portion of the unactivated semiconductor layer 6U (i.e., a portion that is distal from the bonding interface between the memory die 900 and the logic die 700). Generally, each of the random cracks 767 may have a respective vertical gap depth that is in a range from 30% to 100% of a thickness of a portion of the unactivated semiconductor layer 6U that underlies the bottommost surface of the alternating stack (32, 46). In one embodiment, at least 10% of all random cracks 767 are not connected to any of the other random cracks 767, i.e., are formed as isolated random cracks that do not form a network.

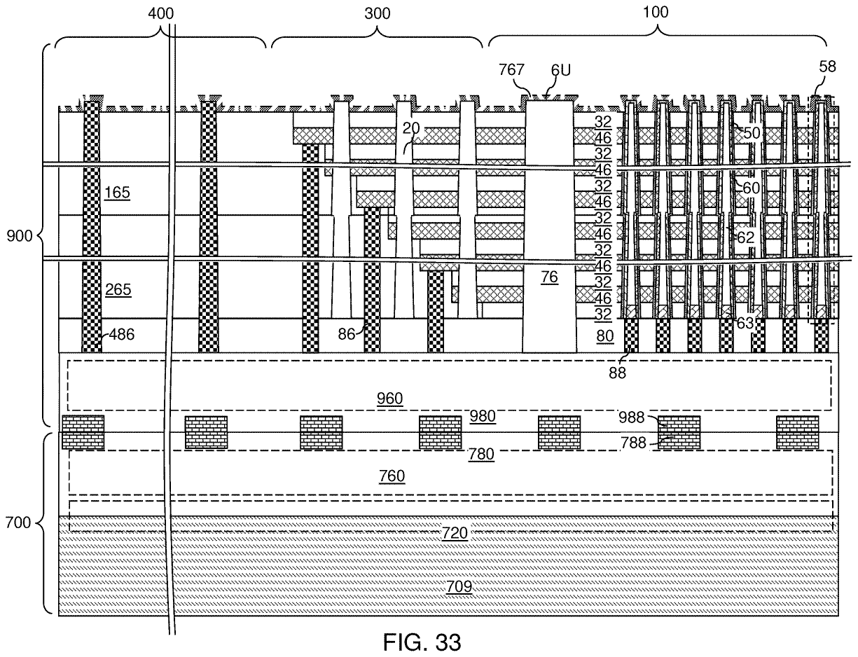

Referring to FIG. 33, the carbon-based material layer 7 may be removed selective to the unactivated semiconductor layer 6U, for example, by performing an ashing process.

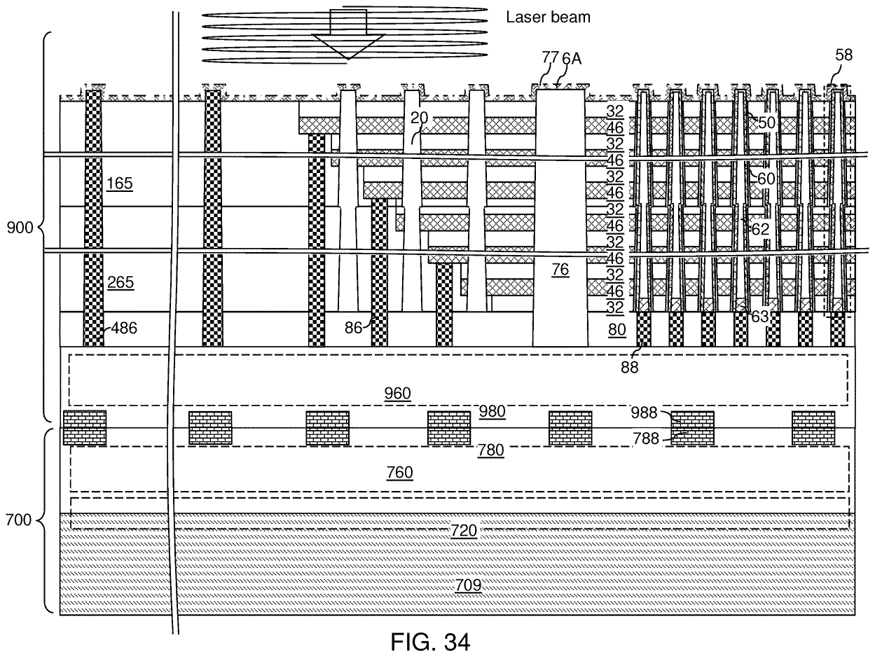

Referring to FIG. 34, a laser anneal process can be performed by irradiating a laser beam on the unactivated semiconductor layer 6U. The peak wavelength of the laser beam may be in a range from 400 nm to 1,000 nm, such as about 500 nm. In one embodiment, the lateral dimension of gaps, as defined by the widths of the random cracks 767, between neighboring pairs of semiconductor material portions in the unactivated semiconductor layer 6U is less than the peak wavelength of the laser beam. The laser anneal process converts the unactivated semiconductor layer 6U into a semiconductor source layer 6A including a layer of an activated doped semiconductor material.

As described above, the textured pattern in the unactivated semiconductor layer 6U may enhance the absorption efficiency of unactivated semiconductor layer 6U through optical effects, and thus, reduces the intensity of the laser beam that enters the dielectric material portions (165, 265). Thus, the melting of the bonding pads may be prevented.

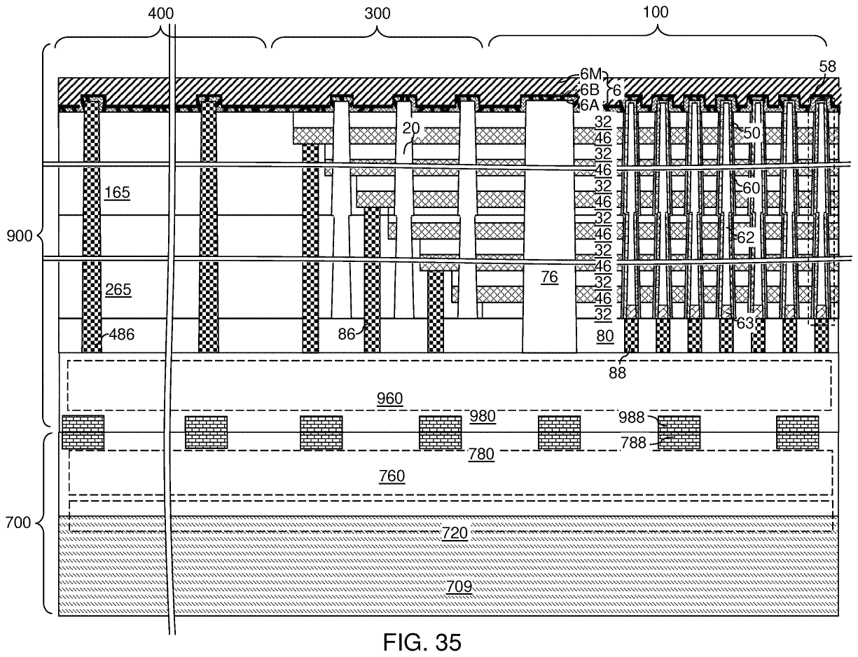

Referring to FIG. 35, a metallic source layer (6B, 6M) can be formed on the backside of the semiconductor source layer 6A. The metallic source layer (6B, 6M) may include a metallic barrier liner 6B comprising a conductive metallic nitride material (such as TiN, TaN, WN, and/or MoN), and a metal layer 6M located on the metallic barrier liner 6B and comprising a metal (such as W, Al, Cu, Co, Mo, Ru, etc.) having a higher electrical conductivity than the conductive metallic nitride material.

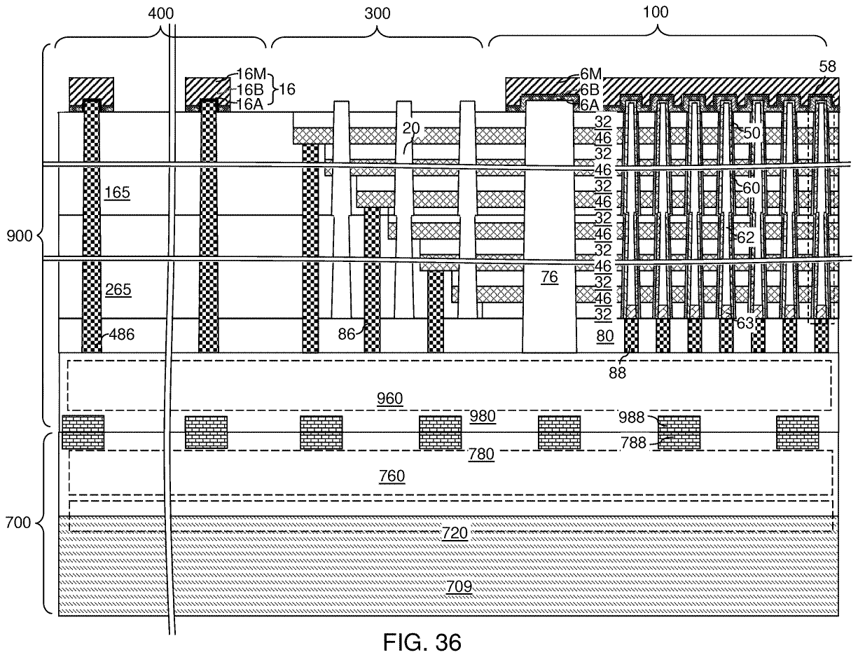

Referring to FIG. 36, a photoresist layer (not shown) can be applied over the metallic source layer (6B, 6M), and can be lithographically patterned into discrete photoresist material portions that over a respective area of the memory array region 100 or a respective one of the connection via structures 488. The metallic source layer (6B, 6M) and the semiconductor source layer 6A can be patterned by performing an anisotropic etch process, which transfers the pattern in the photoresist layer through the metallic source layer (6B, 6M) and the semiconductor source layer 6A.

Patterned portions of the metallic source layer (6B, 6M) and the semiconductor source layer 6A comprise a source layer 6 that contacts end portions of a respective group of vertical semiconductor channels 60 (e.g., the doped source regions 61). Additional patterned portions of the metallic source layer (6B, 6M) and the semiconductor source layer 6A comprise conductive pad structures 16 that contact an end surface of a respective one of the connection via structures 488. Each conductive pad structure 16 may comprise a stack of an activated semiconductor textured-pattern structure 16A, a textured metallic barrier liner 16B extending into the gaps within the activated semiconductor textured-pattern structure 16A, and a metal plate 16M. The random cracks 767 in the semiconductor source layer 6A can be at least partly filled with portions of the metallic barrier liner 6B. The random cracks 767 in the activated semiconductor textured-pattern structure 16A can be at least partly filled with portions of the textured metallic barrier liners 16B.

In the third exemplary structure, the textured pattern in the at least one semiconductor material portion (i.e., in the activated semiconductor textured-pattern structure 16A) comprises random cracks 767 extending through the at least one semiconductor material portion. In one embodiment, the random cracks 767 are filled with a conductive metallic nitride material. In one embodiment, at least 10% of all random cracks 767 are not connected to any other random cracks 767.

Referring collectively to FIGS. 1-36, various embodiments of the present disclosure provide a three-dimensional memory device comprising: an alternating stack (32, 46) of insulating layers 32 and electrically conductive layers 46 that alternate along a vertical direction; memory openings 49 vertically extending through the alternating stack (32, 46); memory opening fill structures 58 located in the memory openings 49 and comprising a respective vertical stack of memory elements (e.g., portions of the memory film 50) and a respective vertical semiconductor channel 60; a dielectric material portion (such as the stepped dielectric material portions (165, 265)) located adjacent to the alternating stack (32, 46); a semiconductor source layer 6A comprising a polycrystalline doped semiconductor material, underlying a bottommost surface of the alternating stack (32, 46), and contacting a bottom end of the vertical semiconductor channels 60; and at least one semiconductor material portion (as embodied as an activated semiconductor textured-pattern structure 16A) underlying the dielectric material portion (such as the stepped dielectric material portions (165, 265)), having a same material composition as the semiconductor source layer 6A, and having a textured pattern including gaps having a respective gap width in a range from 5 nm to 500 nm.

In one embodiment, the polycrystalline doped semiconductor material is absent within the areas of the gaps. In one embodiment, the semiconductor source layer 6 contacts doped source layers 61 located in the bottom ends of the vertical semiconductor channels 60.

In one embodiment, the at least one semiconductor material portion (e.g., the activated semiconductor textured-pattern structure 16A) comprises a semiconductor material plate 16Q, and the textured pattern comprises an array of discrete openings 16R in the semiconductor material plate. In another embodiment, the at least one semiconductor material portion comprises an array of discrete semiconductor pillar structures 16P arranged to provide the textured pattern. In one embodiment, the array of discrete semiconductor pillar structures 16P comprises a two-dimensional periodic array of discrete semiconductor pillar structures each having a diameter in a range from 100 nm to 400 nm. In one embodiment, the array of discrete semiconductor pillar structures 16P is also located on the semiconductor source layer 6A to provide the textured pattern on the semiconductor source layer 6A.

In one embodiment, the three-dimensional memory device comprises a textured-pattern structure 5 contacting a bottom surface of the dielectric material portion (such as the stepped dielectric material portions (165, 265)) and protruding downward from the bottom surface of the dielectric material portion (such as the stepped dielectric material portions (165, 265)), wherein the at least one semiconductor material portion (as embodied as an activated semiconductor textured-pattern structure 16A) comprises an array of downward-protruding polycrystalline semiconductor portions that laterally surrounds the textured-pattern structure 5. In one embodiment, the textured-pattern structure 5 has a thickness in a range from 100% to 1,000% of a thickness of the at least one semiconductor material portion (as embodied as an activated semiconductor textured-pattern structure 16A). In one embodiment, the gaps in the textured pattern comprise gaps between neighboring pairs of the downward-protruding polycrystalline semiconductor portions. In one embodiment, the textured-pattern structure 5 comprises a two-dimensional periodic array of patterned dielectric material portions each having a lateral dimension in a range from 20 nm to 300 nm.

In one embodiment, the textured pattern in the at least one semiconductor material portion (e.g., the activated semiconductor textured-pattern structure 16A) comprises random cracks 767 extending through the at least one semiconductor material portion (as embodied as an activated semiconductor textured-pattern structure 16A). In one embodiment, the random cracks 767 are filled with a conductive metallic nitride material 16B′. In one embodiment, at least 10% of all random cracks 767 are not connected to any other random cracks 767.

In one embodiment, additional random cracks 767 also extend through the semiconductor source layer 6A; and a metallic source layer (6B, 6M) is located on the semiconductor source layer 6A and fills the additional random cracks 767.

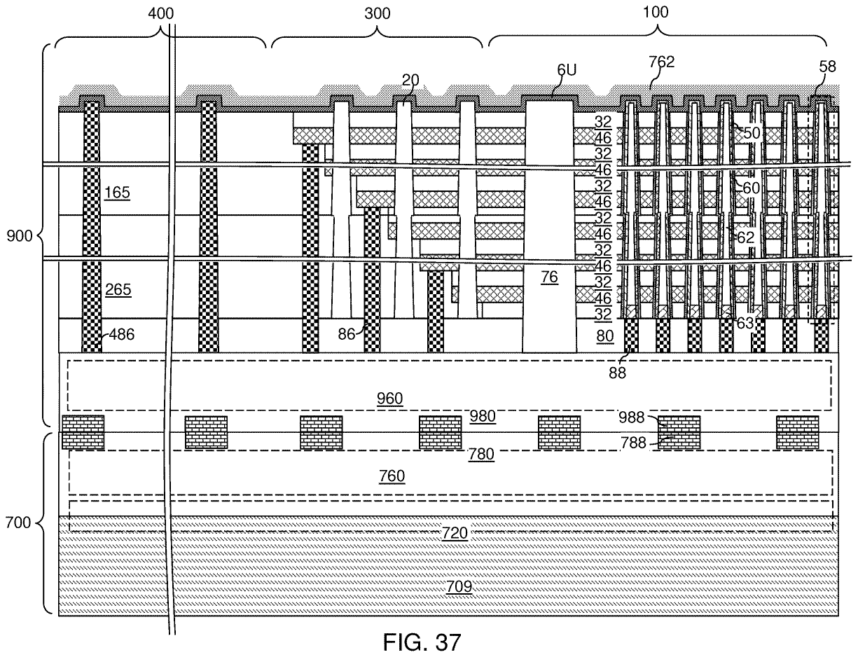

Referring to FIG. 37, a fourth exemplary structure according to a fourth embodiment of the present disclosure can be derived from the first exemplary structure illustrated in FIG. 17 by forming a matrix (e.g. heat sink) material layer 762 on the unactivated semiconductor layer 6U. Generally, the matrix material layer 762 can be formed over at least one semiconductor device including at least one doped semiconductor region including an unactivated semiconductor material. In other words, the at least one semiconductor device comprises at least one doped semiconductor region formed by implantation of electrical dopants therein.

In the fourth exemplary structure, the at least one semiconductor device is provided in a memory die 900 that comprises: an alternating stack (32, 46) of insulating layers 32 and electrically conductive layers 46 that alternate along a vertical direction; memory openings 49 vertically extending through the alternating stack (32, 46); memory opening fill structures 58 located in the memory openings 49 and comprising a respective vertical stack of memory elements (e.g., portions of the memory film 50) and a respective vertical semiconductor channel 60; a dielectric material portion (such as the stepped dielectric material portions (165, 265)) located adjacent to the alternating stack (32, 46); and an unactivated semiconductor layer 6U that contains the at least one doped semiconductor region and underlying the alternating stack (32, 46) and contacting end portions of the vertical semiconductor channels 60 (e.g., the doped source regions 61 in the end portions of the vertical semiconductor channels 60). The unactivated semiconductor layer 6U comprises a doped semiconductor material that is not electrically activated. A logic die 700 comprising a peripheral circuit configured to control operation of the vertical stacks of memory elements can be bonded to the memory die 900.

The matrix material layer 762 comprises a sacrificial material that can be subsequently removed selective to the at least one semiconductor device. In case the matrix material layer 762 is formed directly on the at least one doped semiconductor region including an unactivated semiconductor material, the matrix material layer 762 comprises a material that can be subsequently removed selective to the material of the at least one doped semiconductor region (such as the unactivated semiconductor layer 6U). In one embodiment, the matrix material layer 762 comprises a dielectric material. In one embodiment, the matrix material layer 762 comprises undoped silicate glass, a doped silicate glass, organosilicate glass, silicon oxynitride, or silicon nitride. The thickness of the matrix material layer 762 may be less than the peak wavelength of a laser beam to be subsequently employed to electrically activate the at least one doped semiconductor region (such as the unactivated semiconductor layer 6U). For example, if the peak wavelength of the laser beam to be subsequently employed in a laser anneal process is about 500 nm, the thickness of the matrix material layer 762 may be in a range from 50 nm to 500 nm, such as from 150 nm to 400 nm, although lesser and greater thicknesses may also be employed.

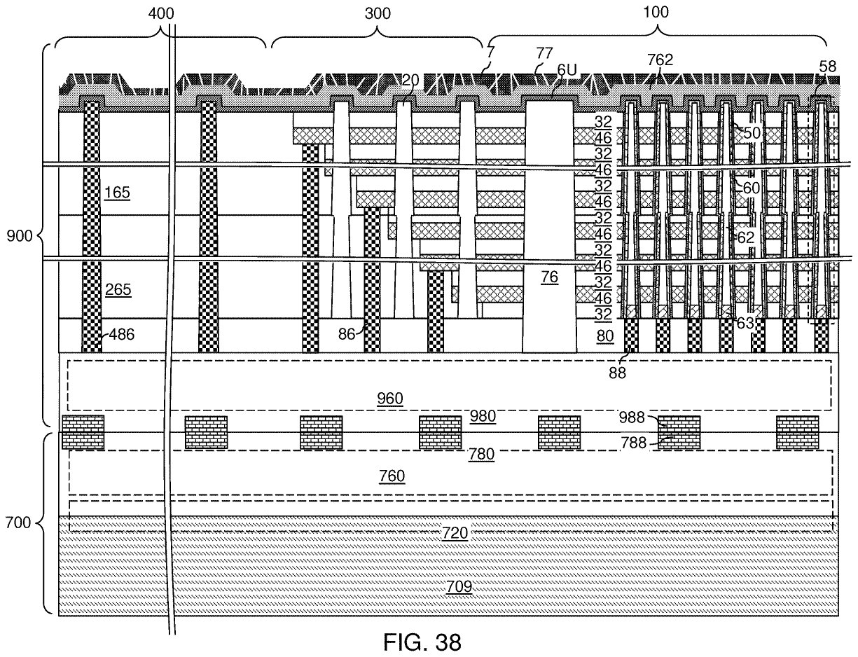

Referring to FIG. 38, the processing steps described with reference to FIG. 31 can be performed to form the above described carbon-based material layer 7 over the matrix material layer 762. As described above, the carbon-based material layer 7 may be formed with the random pattern of laterally-extending cracks 77 during deposition.

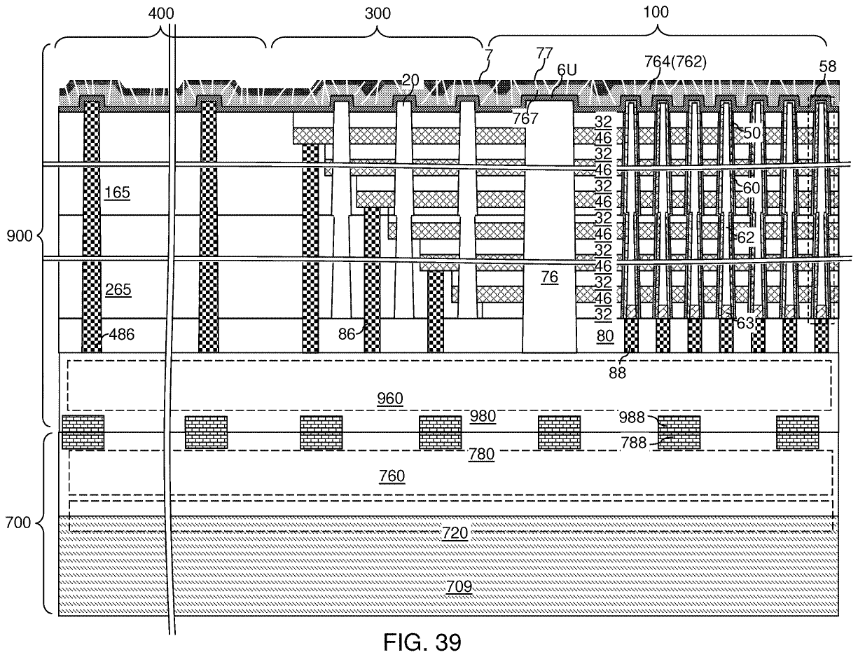

Referring to FIG. 39, the pattern of the laterally-extending cracks 77 in the carbon-based material layer 7 can be transferred through the matrix material layer 762 by performing a selective etch process that etches the matrix material layer 762 selective to the carbon-based material layer 7. The anisotropic etch process transfers a random pattern of laterally-extending cracks 77 in the carbon-based material layer 7 into the matrix material layer 762. Random cracks 767 extending partially or entirely though the thickness of the matrix material layer 762 from a top surface of the matrix material layer 762 toward the substrate are formed in the matrix material layer 762 such that the matrix material layer 762 comprises a textured pattern. The pattern of the laterally-extending cracks 77 in the carbon-based material layer 7 is replicated as random cracks 767 in the matrix material layer 762. The matrix material layer 762 including the pattern of the random cracks 767 constitutes a textured-pattern structure 764, i.e., a structure including a textured pattern. The random cracks 767 extend from a physically-exposed surface of the textured-pattern structure 764 toward the dielectric material portion (such as the stepped dielectric material portions (165, 265)).

In one embodiment, the anisotropic etch process may have an etch chemistry that amplifies the lateral dimensions of the random cracks 767 relative to the lateral dimensions of the laterally-extending cracks 77 in the carbon-based material layer 7. In one embodiment, the anisotropic etch process etches the material of the matrix material layer 762 at an etch rate that is at least twice an etch rate of the carbon-based material layer 7. In one embodiment, an average lateral dimension (such as an average width) of the random cracks 767 in the textured pattern of the a textured-pattern structure 764 may be greater than an average lateral dimension of the laterally-extending cracks 77 in the carbon-based material layer 7.

Thus, a textured pattern comprising the random cracks 767 is formed within the matrix material layer 762 to provide the textured-pattern structure 764. In one embodiment, the textured pattern may be formed throughout the entirety of the lateral dimension of the matrix material layer 762. The textured pattern includes gaps between neighboring pairs of portions of the matrix material layer 762 with a respective gap width in a range from 5 nm to 500 nm. Specifically, the random cracks 767 may have a respective gap width in a range from 5 nm to 500 nm, and typically in a range from 20 nm to 200 nm.

The random cracks 767 may extend through the entire thickness of the textured-pattern structure 764, or may extend thorough a distal portion of the textured-pattern structure 764 (i.e., a portion that is distal from the bonding interface between the memory die 900 and the logic die 700). Generally, each of the random cracks 767 may have a respective vertical gap depth that is in a range from 30% to 100% of a thickness of the textured-pattern structure 764. In one embodiment, at least 10% of all random cracks 767 are not connected to any other random cracks 767, i.e., are formed as isolated random cracks that do not form a network. In one embodiment, the etch process has an etch chemistry that etches a material of the matrix material layer 762 selective to underlying portions of the at least one semiconductor device. For example, the etch process has an etch chemistry that etches a material of the matrix material layer 762 selective to the unactivated semiconductor layer 6U.

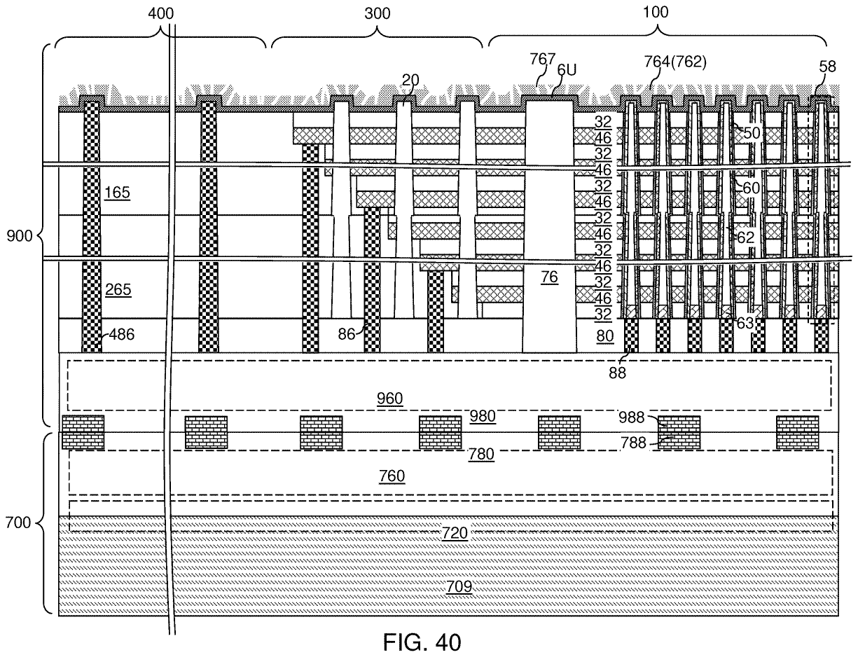

Referring to FIG. 40, the carbon-based material layer 7 may be removed, for example, by performing an ashing process. In some embodiment, the etch process described with reference to FIG. 39 may collaterally etch the entirety of the carbon-based material layer 7. In this case, the processing steps of FIG. 40 may be unnecessary.

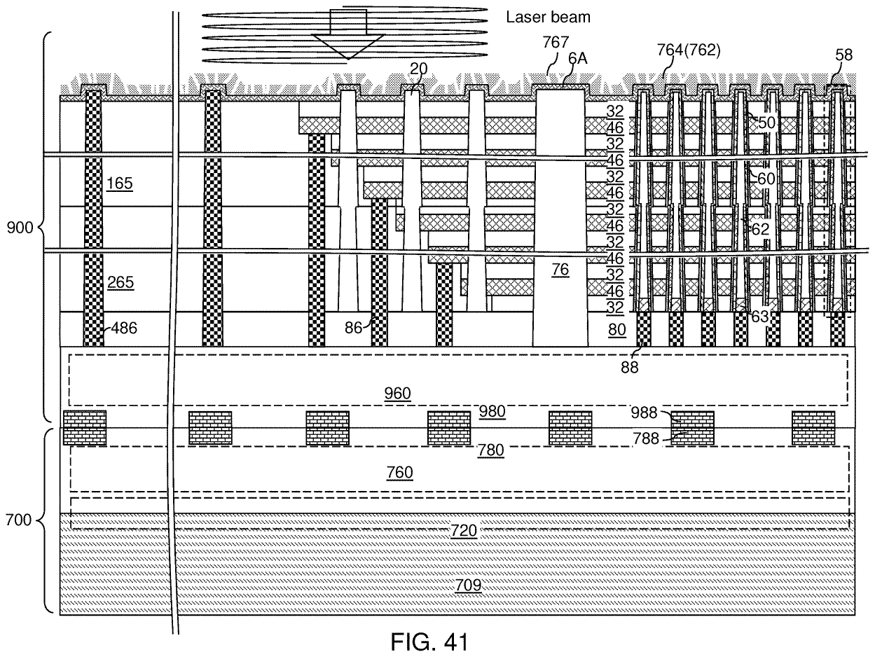

Referring to FIG. 41, a laser anneal process can be performed by irradiating a laser beam on the textured-pattern structure 764. The peak wavelength of the laser beam may be in a range from 400 nm to 1,000 nm, such as about 500 nm. In one embodiment, the lateral dimension of gaps, as defined by the widths of the random cracks 767, between neighboring pairs of material portions in the textured-pattern structure 764 is less than the wavelength of the laser beam. The unactivated semiconductor layer 6U can be heated indirectly from the heat absorbed by the textured-pattern structure (i.e., textured heat sink) 764 and directly from the heat absorbed by the unactivated semiconductor layer 6U. The laser anneal process converts the unactivated semiconductor layer 6U into a semiconductor source layer 6A including a layer of an activated doped semiconductor material.

As described above, the textured pattern in textured-pattern structure 764 enhances the absorption efficiency of textured-pattern structure 764 through optical effects, and thus, reduces the intensity of the laser beam that enters the dielectric material portions (165, 265). The thickness of the textured-pattern structure 764 may be in a range from 50 nm to 500 nm, such as from 150 nm to 400 nm, for enhancement of heat absorption. The nanoscale openings in textured-pattern structure 764 have a net effect of scattering the laser beam so that the intensity of the laser beam that is irradiated into the dielectric material portions (165, 265) is reduced, and the bonding pads are not melted.

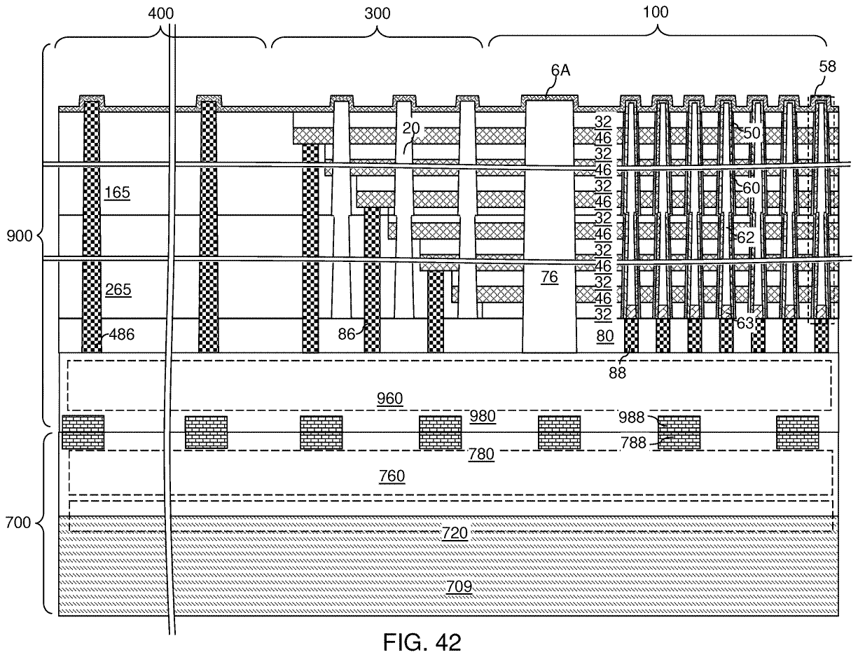

Referring to FIG. 42, the textured-pattern structure 764 can be removed selective to the material of the semiconductor source layer 6A by performing a selective etch process. For example, if the textured-pattern structure 764 comprises undoped silicate glass, doped silicate glass, or organosilicate glass, a wet etch process using dilute hydrofluoric acid can be performed to remove the textured-pattern structure 764.

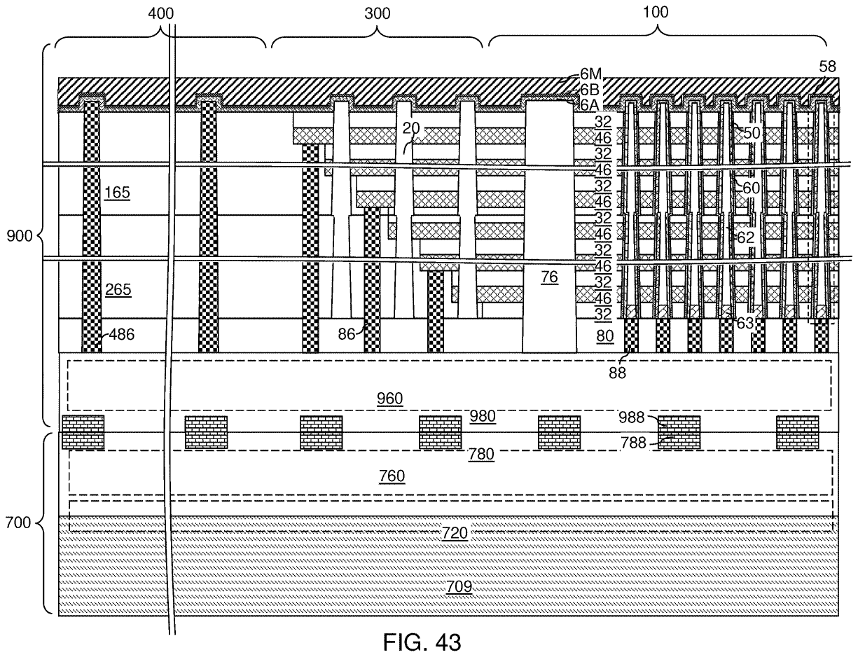

Referring to FIG. 43, a metallic source layer (6B, 6M) can be formed on the backside of the semiconductor source layer 6A. The metallic source layer (6B, 6M) may include a metallic barrier liner 6B comprising a conductive metallic nitride material (such as TiN, TaN, WN, and/or MoN), and a metal layer 6M located on the metallic barrier liner 6B and comprising a metal (such as W, Al, Cu, Co, Mo, Ru, etc.) having a higher electrical conductivity than the conductive metallic nitride material.

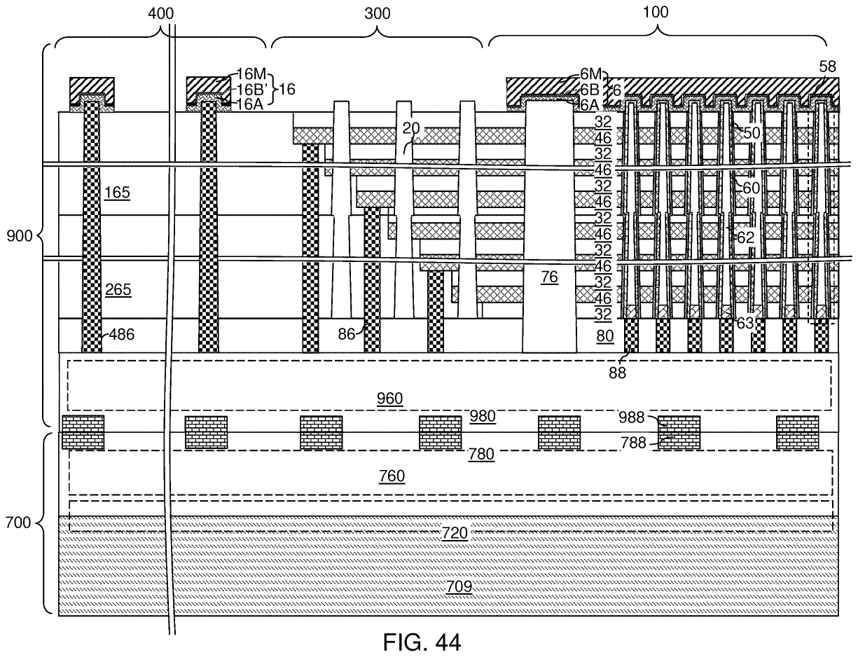

Referring to FIG. 44, a photoresist layer (not shown) can be applied over the metallic source layer (6B, 6M), and can be lithographically patterned into discrete photoresist material portions that over a respective area of the memory array region 100 or a respective one of the connection via structures 488. The metallic source layer (6B, 6M) and the semiconductor source layer 6A can be patterned by performing an anisotropic etch process, which transfers the pattern in the photoresist layer through the metallic source layer (6B, 6M) and the semiconductor source layer 6A.

Patterned portions of the metallic source layer (6B, 6M) and the semiconductor source layer 6A comprise a source layer 6 that contacts end portions of a respective group of vertical semiconductor channels 60. Additional patterned portions of the metallic source layer (6B, 6M) and the semiconductor source layer 6A comprise conductive pad structures 16 that contact an end surface of a respective one of the connection via structures 488. Each conductive pad structure 16 may comprise a stack of an activated semiconductor textured-pattern structure 16A, a metallic barrier liner 16B′, and a metal plate 16M.

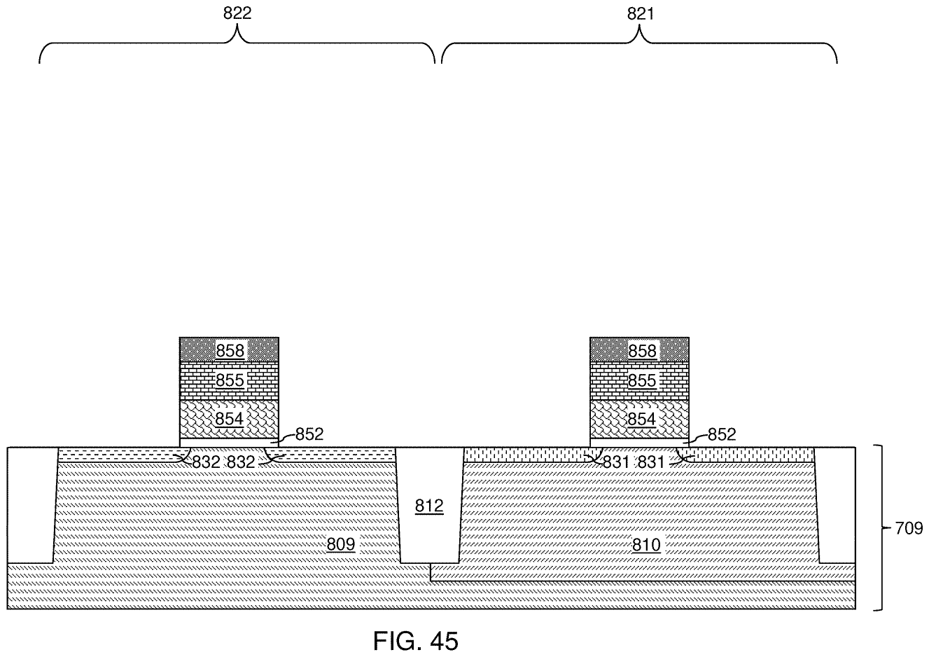

Referring to FIG. 45, a fifth exemplary structure according to a fifth embodiment of the present disclosure is illustrated. The fifth exemplary structure includes a semiconductor structure including at least one doped semiconductor region including unactivated electrical dopants. For example, the fifth exemplary structure may comprise field effect transistors (e.g., field effect transistors in a CMOS configuration) located on a single crystalline semiconductor substrate. The semiconductor substrate may comprise a single crystalline silicon substrate, such as a commercially available single crystalline silicon wafer. In one embodiment, the substrate may comprise the logic-side substrate 709 and the field effect transistors may comprise transistors of the logic circuit 720 described above. The semiconductor substrate 709 may comprise at least one single crystalline substrate semiconductor portion (e.g., doped well or surface region) such as a p-doped single crystalline semiconductor material portion 809 and an n-doped single crystalline semiconductor material portion 810. For example, the p-doped single crystalline semiconductor material portion 809 may comprise a surface region of p-doped semiconductor substrate 709, and the n-doped single crystalline semiconductor material portion 810 may be an n-type well located in the surface region of the substrate 709.

Shallow trench isolation structures 812 may be formed in an upper portion of the semiconductor substrate 709. A first device region 821 and a second device region 822 may be provided in the fifth exemplary structure. Each of the first device region 821 and the second device region 822 may be laterally surrounded by a respective one of the shallow trench isolation structures 812. Gate stack structures (852, 854, 855, 858) can be formed in the first device region 821 and the second device region 822. Each gate stack structure (852, 854, 855, 858) may comprise a gate dielectric 852, at least one gate electrode (854, 855) which includes at least one of a heavily doped semiconductor (e.g., heavily doped polysilicon) gate electrode portion 854 and/or a metallic (e.g., metal, metal nitride and/or silicide) gate electrode portion 855, and an optional dielectric (e.g., silicon nitride, etc.) gate gap 858.

Optional first ion implantation processes can be performed to form optional source/drain extension regions (e.g., shallow lightly doped drain and source regions) (831, 832). For example, the source/drain extension regions (831, 832) may comprise p-doped source/drain extension regions 831 that are formed in the first device region 821 in an upper portion of the n-doped single crystalline semiconductor material portion 810, and n-doped source/drain extension regions 832 that are formed in the second device region 822 in an upper portion of the p-doped single crystalline semiconductor material portion 809. The gate stack structures (852, 854, 855, 858) may be employed as implantation masks during the first ion implantation processes. Thus, the edges of the source/drain extension regions (831, 832) can be self-aligned to the sidewalls of the gate stack structures (852, 854, 855, 858). The electrical dopants in the source/drain extension regions (831, 832) as implanted are not electrically activated. In other words, the electrical dopants in the source/drain extension regions (831, 832) can be located predominantly at interstitial sites of the single crystalline structure of the source/drain extension regions (831, 832).

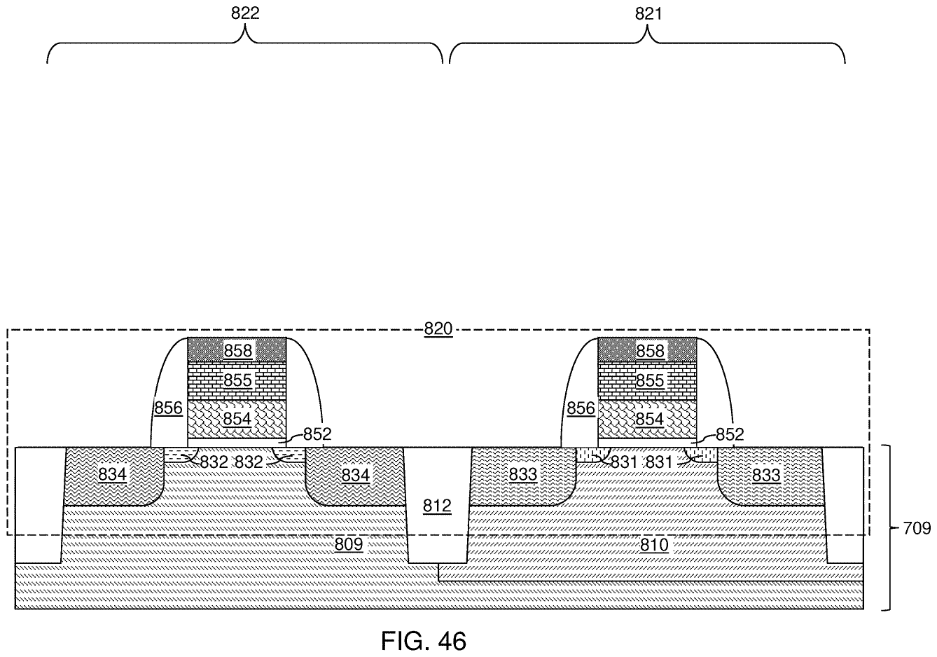

Referring to FIG. 46, optional dielectric gate spacers 856 can be formed around the gate stack structures (852, 854, 855, 858) by conformally depositing a dielectric spacer material layer (e.g., silicon oxide, silicon oxynitride and/or silicon nitride), and by anisotropically etching horizontally-extending portions of the dielectric spacer material layer. The dielectric gate spacers 856 comprise remaining vertically-extending portions of the dielectric spacer material layer.

Second ion implantation processes can be performed to form source/drain regions (e.g., deep heavily doped drain and source regions) (833, 834). For example, the source/drain regions (833, 834) may comprise p-doped source/drain regions 833 that are formed in the first device region 821 in an upper portion of the n-doped single crystalline semiconductor material portion 810, and n-doped source/drain regions 834 that are formed in the second device region 822 in an upper portion of the p-doped single crystalline semiconductor material portion 809. The gate stack structures (852, 854, 855, 858) and the dielectric gate spacers 856 may be employed as implantation masks during the second ion implantation processes. Thus, the edges of the source/drain regions (833, 834) can be self-aligned to the outer sidewalls of the dielectric gate spacers 856. The electrical dopants in the source/drain regions (833, 834) as implanted are not electrically activated. The source/drain regions (833, 834) may have a higher dopant concentration than the respective extension regions (831, 832). In other words, the electrical dopants in the source/drain regions (833, 834) can be located predominantly at interstitial sites of the single crystalline structure of the source/drain regions (833, 834). A p-type field effect transistor can be formed in the first device region 821, and an n-type field effect transistor can be formed in the second device region 822. The p-type field effect transistor and the n-type field effect transistor may be electrically connected to each other in a CMOS configuration and are collectively referred to as at least one semiconductor device (e.g., a CMOS semiconductor device) 820.

Generally, at least one semiconductor device 820 can be formed such that the at least one semiconductor device 820 comprises at least one doped semiconductor region (831, 832, 833, 834) formed by implantation of electrical dopants therein. In one embodiment, the at least one semiconductor device 820 comprises at least one field effect transistor. In one embodiment, the at least one doped semiconductor region (831, 832, 833, 834) comprises source and drain regions (833, 834). In one embodiment, the at least one field effect transistor comprises at least one gate stack structure (852, 854, 855, 858) including a respective gate dielectric 852 and a respective gate electrode (854, 855).

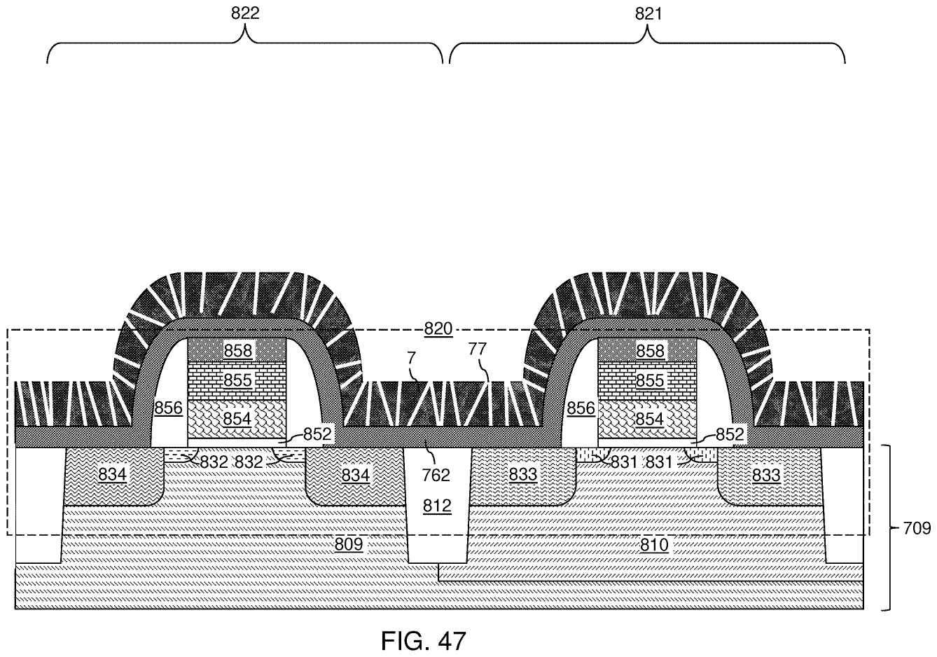

Referring to FIG. 47, a matrix material layer (e.g., heat sink layer) 762 can be deposited over the at least one semiconductor device 820. For example, the matrix dielectric layer 762 may be deposited over the top surfaces of the source/drain regions (833, 834) and the at least one gate stack structure (852, 854, 855, 858) of at least one field effect transistor (821, 822). Thus, the matrix material layer 762 can be formed over at least one semiconductor device 820 including at least one doped semiconductor region (831, 832, 833, 834) including an unactivated semiconductor material. In other words, the at least one semiconductor device 820 comprises at least one doped semiconductor region (e.g., source and drain regions and optionally their extensions (831, 832, 833, 834)) formed by implantation of electrical dopants therein.

The matrix material layer 762 comprises a sacrificial material that can be subsequently removed selective to the at least one semiconductor device. In case the matrix material layer 762 is formed directly on the at least one doped semiconductor region (831, 832, 833, 834) including an unactivated semiconductor material, the matrix material layer 762 comprises a material that can be subsequently removed selective to the material of the at least one doped semiconductor region (831, 832, 833, 834). In one embodiment, the matrix material layer 762 comprises a dielectric material. In one embodiment, the matrix material layer 762 comprises undoped silicate glass, a doped silicate glass, organosilicate glass, silicon oxynitride or silicon nitride. The thickness of the matrix material layer 762 may be less than the peak wavelength of a laser beam to be subsequently employed to electrically activate electrical dopants in the at least one doped semiconductor region (831, 832, 833, 834). For example, if the peak wavelength of the laser beam to be subsequently employed in a laser anneal process is about 500 nm, the thickness of the matrix material layer 762 may be in a range from 50 nm to 500 nm, such as from 150 nm to 400 nm, although lesser and greater thicknesses may also be employed.

The above described carbon-based material layer 7 can be formed upon the matrix material layer 762. The carbon-based material layer 7 may be formed with a random pattern of laterally-extending cracks 77 during deposition.

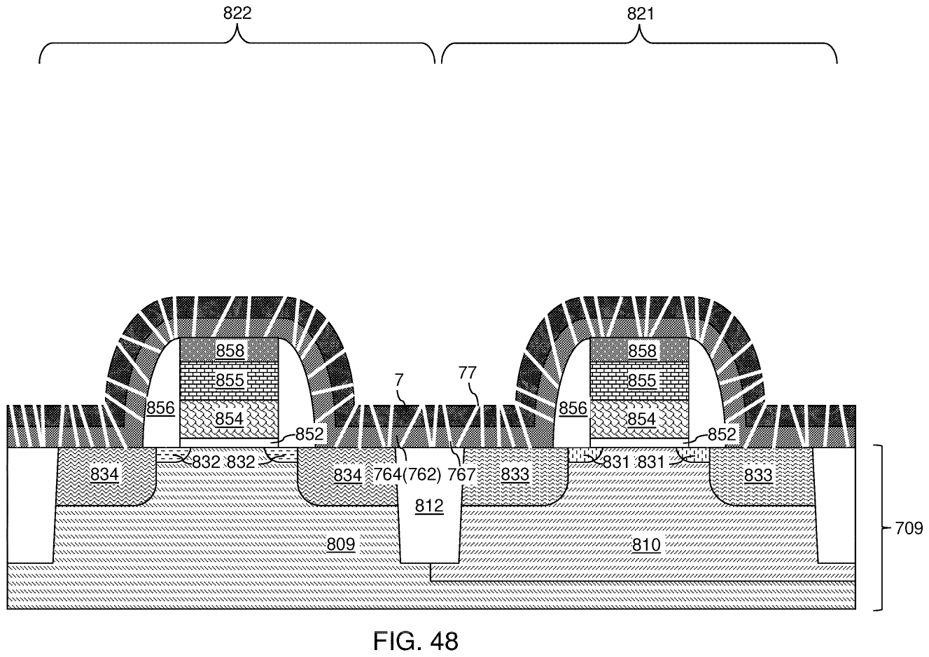

Referring to FIG. 48, the pattern of the laterally-extending cracks 77 in the carbon-based material layer 7 can be transferred through the matrix material layer 762 by performing the above described selective etch process. The etch process transfers a random pattern of laterally-extending cracks 77 in the carbon-based material layer 7 into the matrix material layer 762. Random cracks 767 extending from a top surface of the matrix material layer 762 toward the substrate are formed in the matrix material layer 762 such that the matrix material layer 762 comprises a textured pattern. The pattern of the laterally-extending cracks 77 in the carbon-based material layer 7 is replicated as random cracks 767 in the matrix material layer 762. The matrix material layer 762 including the pattern of the random cracks 767 constitutes a textured-pattern structure 764, i.e., a structure including a textured pattern. The random cracks 767 extend from a physically-exposed surface of the textured-pattern structure 764 toward the semiconductor substrate (809, 810).

In one embodiment, the etch process may have an etch chemistry that amplifies the lateral dimensions of the random cracks 767 relative to the lateral dimensions of the laterally-extending cracks 77 in the carbon-based material layer 7. In one embodiment, the selective etch process etches the material of the matrix material layer 762 at an etch rate that is at least twice an etch rate of the carbon-based material layer 7. In one embodiment, an average lateral dimension (such as an average width) of the random cracks 767 in the textured pattern of the a textured-pattern structure 764 may be greater than an average lateral dimension of the laterally-extending cracks 77 in the carbon-based material layer 7.

Thus, a textured pattern comprising the random cracks 767 is formed within the matrix material layer 762 to provide the textured-pattern structure 764. In one embodiment, the textured pattern may be formed throughout the entirety of the lateral dimension of the matrix material layer 762. The textured pattern includes gaps between neighboring pairs of portions of the matrix material layer 762 with a respective gap width in a range from 5 nm to 500 nm. Specifically, the random cracks 767 may have a respective gap width in a range from 5 nm to 500 nm, and typically in a range from 20 nm to 200 nm.

The random cracks 767 may extend through the entire thickness of the textured-pattern structure 764, or may extend thorough a distal portion of the textured-pattern structure 764 (i.e., a portion that is distal from the semiconductor substrate (809, 810)). Generally, each of the random cracks 767 may have a respective vertical gap depth that is in a range from 30% to 100% of a thickness of the textured-pattern structure 764. In one embodiment, at least 10% of all random cracks 767 are not connected to any other random cracks 767, i.e., are formed as isolated random cracks that do not form a network. In one embodiment, the selective etch process has an etch chemistry that etches a material of the matrix material layer 762 selective to underlying portions of the at least one semiconductor device. For example, the selective etch process has an etch chemistry that etches a material of the matrix material layer 762 selective to the at least one doped semiconductor region (831, 832, 833, 834).

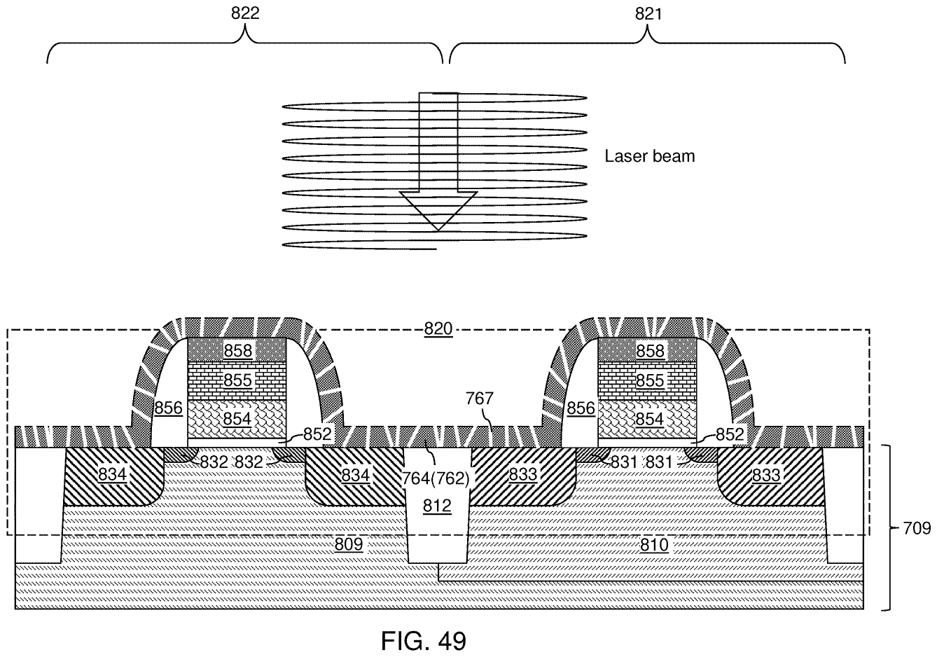

Referring to FIG. 49, the carbon-based material layer 7 may be removed selective to the textured-pattern structure 764, for example, by performing an ashing process.

Subsequently, a laser anneal process can be performed by irradiating a laser beam on the textured-pattern structure 764. The peak wavelength of the laser beam may be in a range from 400 nm to 1,000 nm, such as about 500 nm. In one embodiment, the lateral dimension of gaps, as defined by the widths of the random cracks 767, between neighboring pairs of material portions in the textured-pattern structure 764 is less than the wavelength of the laser beam. The at least one doped semiconductor region (831, 832, 833, 834) can be heated indirectly from the heat absorbed by the textured-pattern structure 764 and directly from the heat absorbed by the at least one doped semiconductor region (831, 832, 833, 834). The laser anneal process converts the at least one doped semiconductor region (831, 832, 833, 834) into at least one activated doped semiconductor material, which may comprise electrically activated source/drain extension regions (831, 832) and electrically activated source/drain regions (833, 834).

The textured pattern enhances an absorption efficiency of the laser beam by the matrix material layer 762 through optical effects, and heat generated at the at least one doped semiconductor region and the matrix material layer 762 activates the electrical dopants within the at least one doped semiconductor region (831, 832, 833, 834).

As described above, the textured pattern in textured-pattern structure 764 enhances the absorption efficiency of the laser beam through optical effects. The thickness of the textured-pattern structure 764 may be in a range from 50 nm to 500 nm, such as from 150 nm to 400 nm, for enhancement of heat absorption.

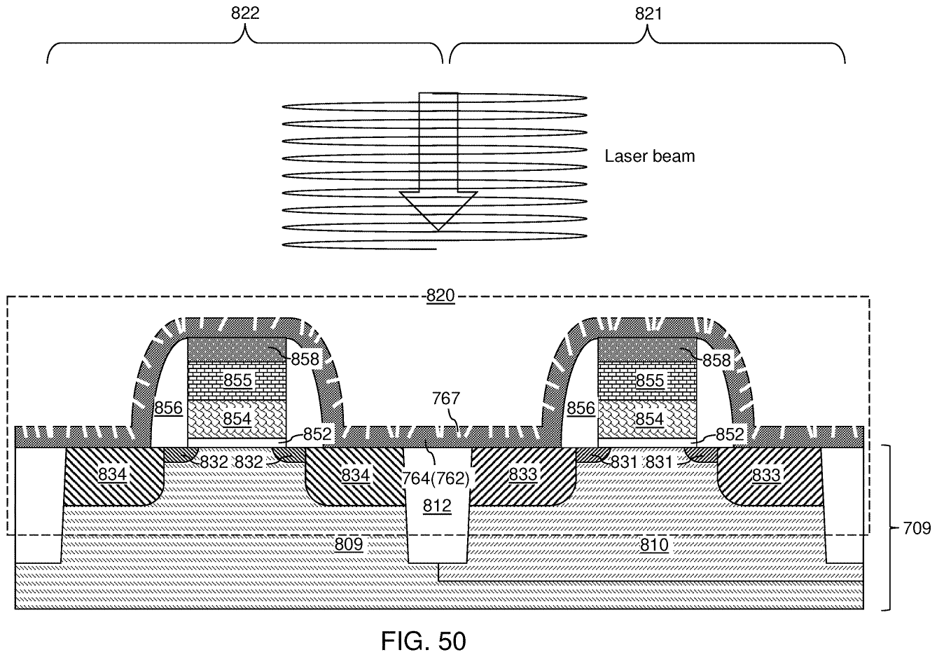

Referring to FIG. 50, an alternative configuration of the fifth exemplary structure is illustrated, in which the vertical extent of the random cracks 767 in the textured-pattern structure 764 is less than the thickness of the textured-pattern structure 764.

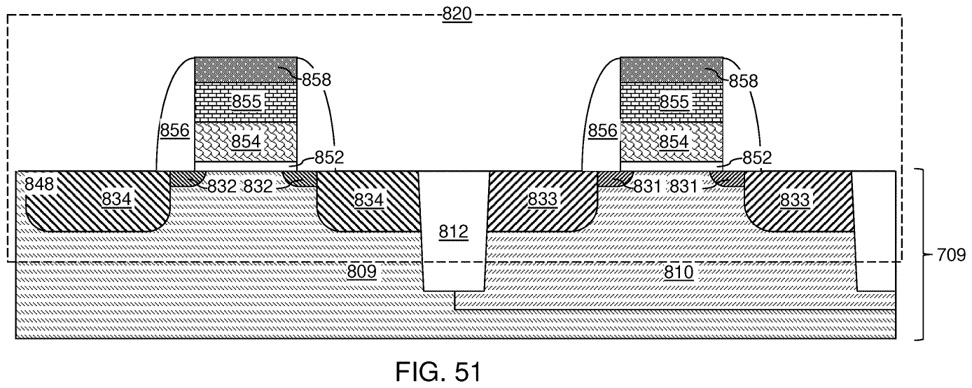

Referring to FIG. 51, the textured-pattern structure 764 can be removed selective to the material of the semiconductor substrate 709 by performing a selective etch process. For example, if the textured-pattern structure 764 comprises undoped silicate glass, a doped silicate glass, or organosilicate glass, a wet etch process using dilute hydrofluoric acid can be performed to remove the textured-pattern structure 764. Generally, the matrix material layer 762 can be removed selective to the at least one semiconductor device 820.

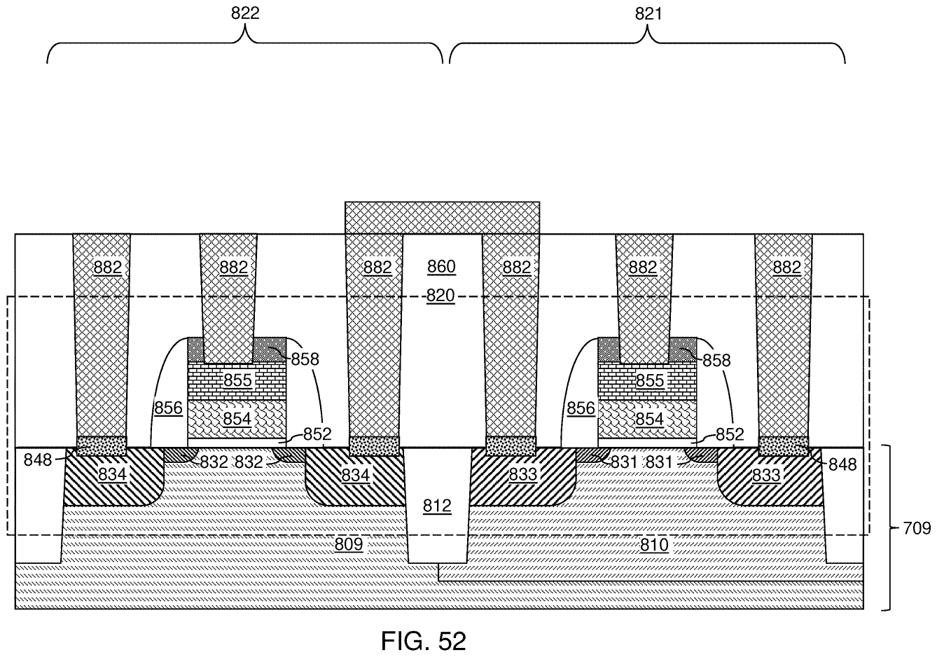

Referring to FIG. 52, a contact-level dielectric layer 860 can be formed over the at least one semiconductor device 820 after removal of the matrix material layer 762. Contact via structures 882 can be formed through the contact-level dielectric layer 860 on the at least one semiconductor device 820. For example, the contact via structures 882 can be formed on the source/drain regions (833, 834) and on the gate electrodes (854, 855). In some embodiments, metal-semiconductor alloy regions 848 (such as metal silicide regions) may be formed between the source/drain regions (833, 834) and the contact via structures 882.

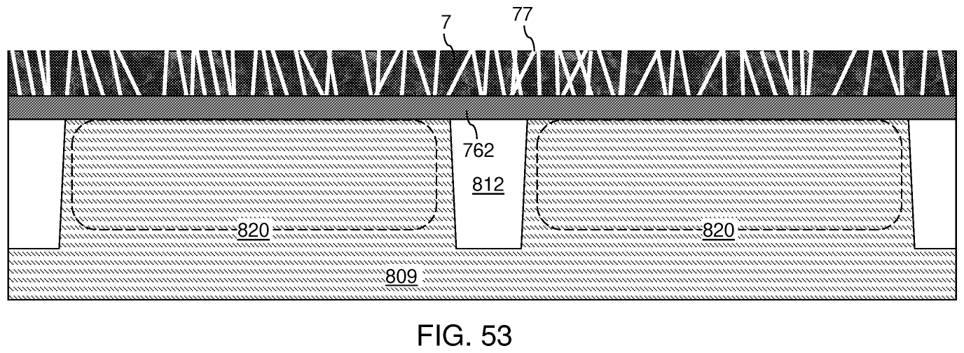

Referring to FIG. 53, a sixth exemplary structure according to a sixth embodiment of the present disclosure can be derived by depositing a matrix material layer 762 and a carbon-based material layer 7 over at least one semiconductor device 820 of any type that includes at least one doped semiconductor region including unactivated doped semiconductor material. The at least one semiconductor device 820 may comprise any type of transistor (such as a field effect transistor or a bipolar transistor), a diode, a resistor, or any other type of semiconductor device known in the art as long as at least one doped semiconductor region including unactivated doped semiconductor material is present therein.

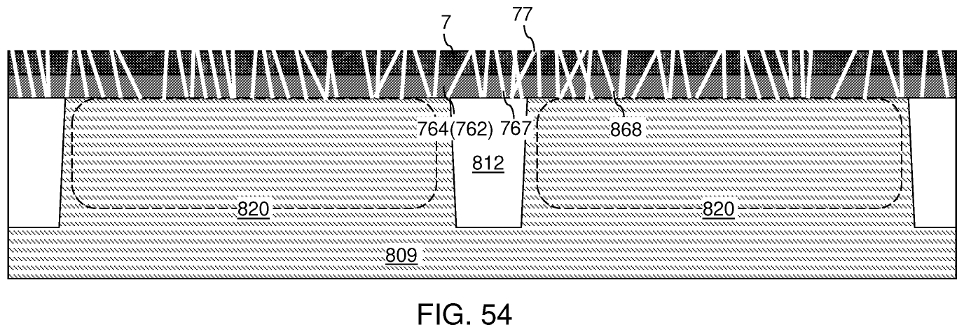

Referring to FIG. 54, the processing steps described with reference to FIG. 48 can be performed to form a textured-pattern structure 764.

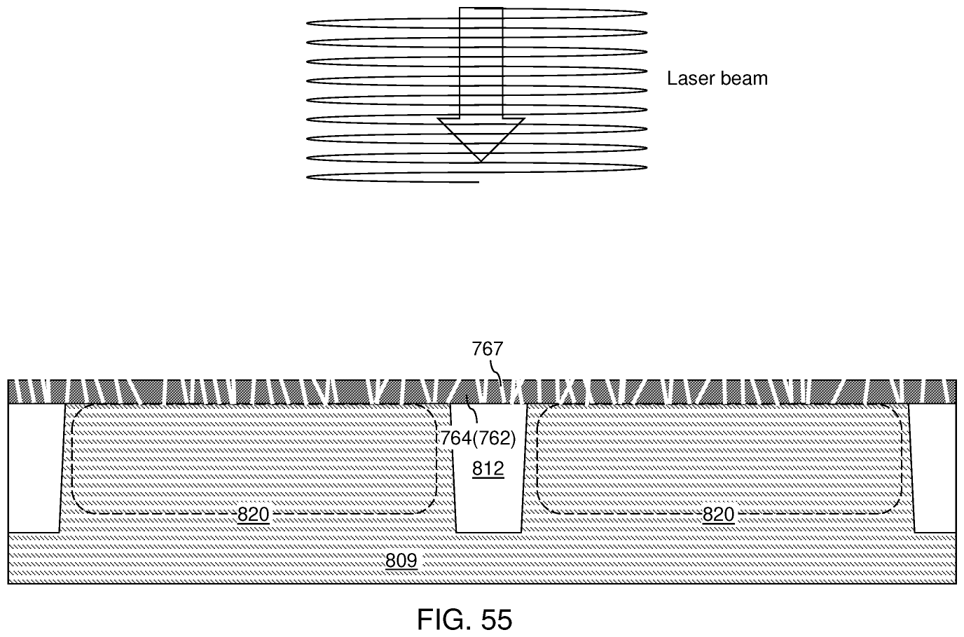

Referring to FIG. 55, the processing steps described with reference to FIG. 49 can be performed to remove the carbon-based material layer 7 and to perform a laser anneal process that activates the electrical dopants within the at least one doped semiconductor region in the at least one semiconductor device 820.

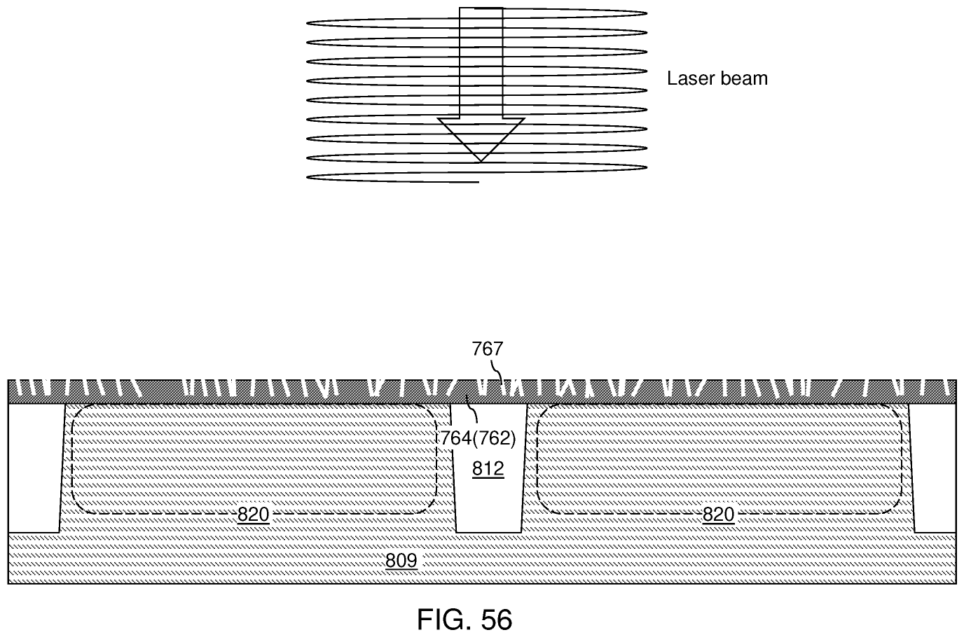

Referring to FIG. 56, an alternative configuration of the sixth exemplary structure is illustrated, in which the vertical extent of the random cracks 767 in the textured-pattern structure 764 is less than the thickness of the textured-pattern structure 764.

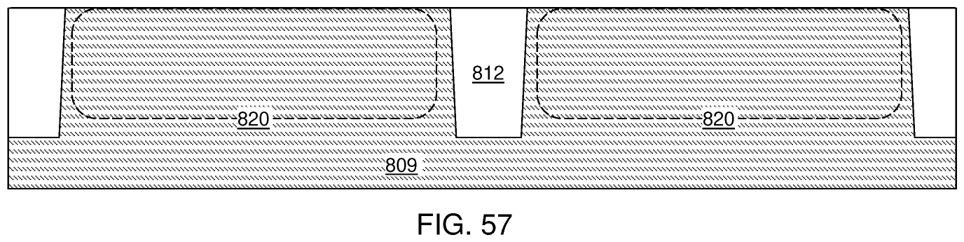

Referring to FIG. 57, the textured-pattern structure 764 can be removed selective to the material of the at least one semiconductor device 820 by performing a selective etch process. For example, if the textured-pattern structure 764 comprises undoped silicate glass, a doped silicate glass, or organosilicate glass, a wet etch process using dilute hydrofluoric acid can be performed to remove the textured-pattern structure 764.

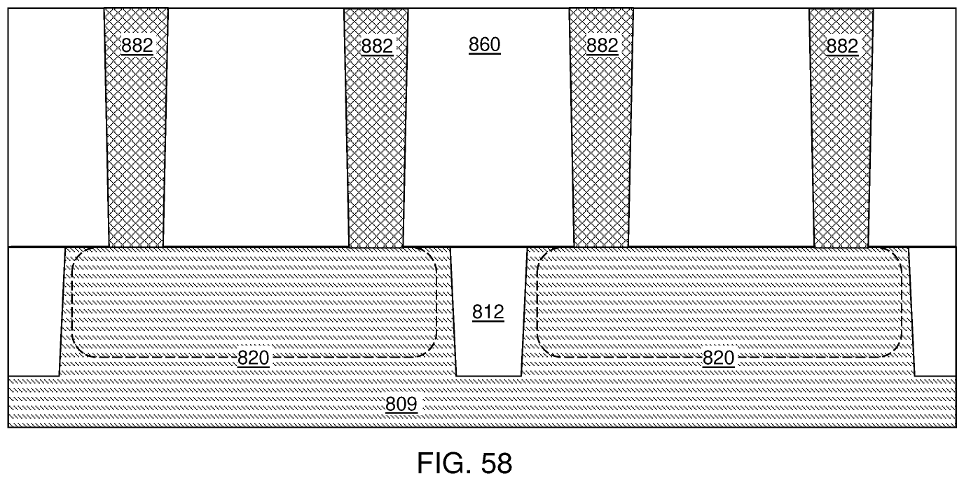

Referring to FIG. 58, a contact-level dielectric layer 860 can be formed over the at least one semiconductor device 820 after removal of the matrix material layer 762. Contact via structures 882 can be formed through the contact-level dielectric layer 860 on the at least one semiconductor device 820.

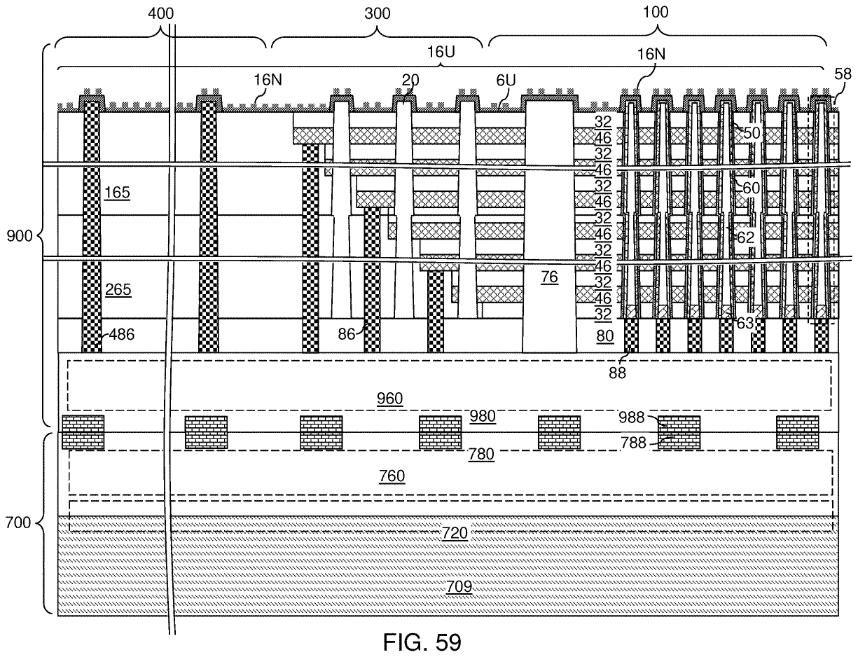

Referring to FIG. 59, the seventh exemplary structure can be derived from the configuration of the first exemplary structure shown in FIG. 19E by replacing the nanopillar textured-pattern structure 16P with a nanoparticle textured-pattern structure 16N. In the seventh embodiment, the nanoparticles 16N are located on the entire top surface of the unactivated semiconductor layer 6U. The nanoparticles 16N form the above described semiconductor textured-pattern structure 16U. The lateral dimensions of the nanoparticle textured pattern, and specifically the pitch and/or the spacing between the nanoparticles of the nanoparticle textured pattern, is preferably less than the peak wavelength of the incident laser radiation. The spacing between the nanoparticles 16N may be less than 1000 nm, such as between 5 nm and 500 nm. For example, if the peak wavelength of the incident laser radiation is 500 nm, then the spacing between the nanoparticles 16N is less than 500 nm, such as 20 to 400 nm. The width or diameter of the nanoparticles 16N may range from 1 to 500 nm, such as 10 to 100 nm.

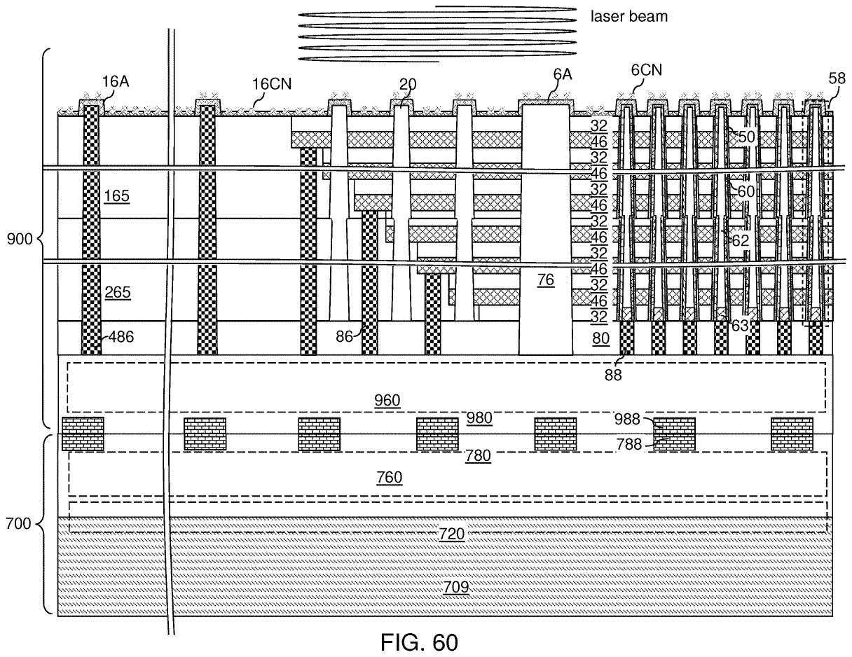

Referring to FIG. 60, the above described laser anneal process can be performed by irradiating a laser beam on the unactivated semiconductor layer 6U. The peak wavelength of the laser beam may be in a range from 400 nm to 1,000 nm, such as about 500 nm. As discussed above, in one embodiment, the lateral dimension of gaps between neighboring nanoparticles 16N of in the semiconductor textured-pattern structure 16U is less than the peak wavelength of the laser beam. The laser anneal process converts the unactivated semiconductor layer 6U into a semiconductor source layer 6A comprising an activated doped semiconductor material. The laser anneal process converts the portion of the unactivated semiconductor layer 6U in the peripheral region 400 semiconductor textured-pattern structure 16U into a polycrystalline activated doped semiconductor material (e.g., doped polysilicon layer) 16A. Furthermore, if the as deposited nanoparticles 16N comprise amorphous semiconductor material nanoparticles, such as silicon, germanium, silicon-germanium or silicon core-germanium-containing shell nanoparticles, then the laser anneal also converts the amorphous semiconductor nanoparticles into crystalline (e.g., polycrystalline or single crystalline) nanoparticles 6CN and 16NC located over the memory array region 100 and the peripheral region 400, respectively. The polycrystalline activated doped semiconductor material and the crystalline semiconductor nanoparticles 16CN together form an activated semiconductor textured-pattern structure (16A, 16CN).

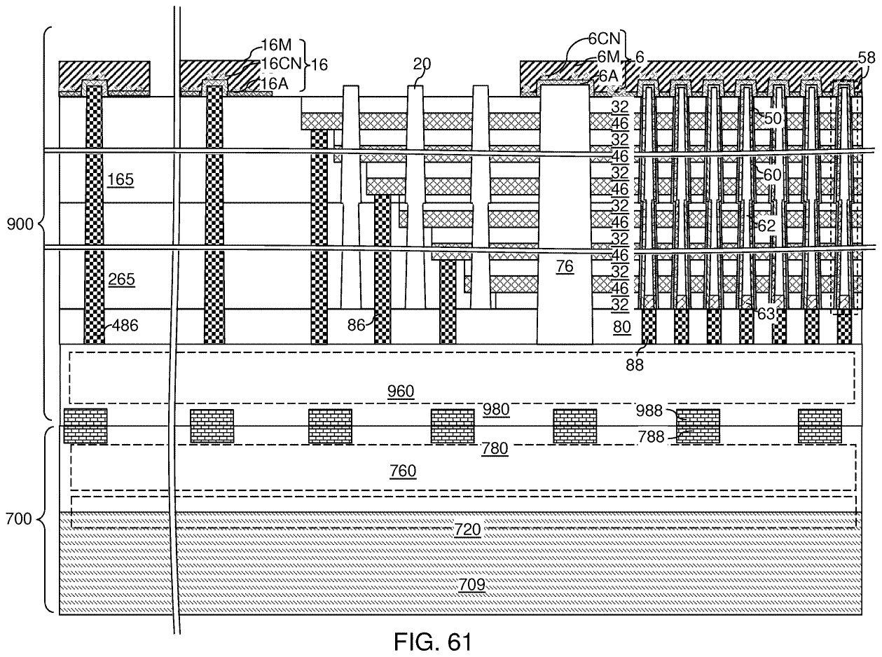

Referring to FIG. 61, the above described metallic source layer is deposited over backside of the semiconductor source layer 6A covered with the crystalline semiconductor nanoparticles 6CN and over the activated semiconductor textured-pattern structure (16A, 16CN). The metallic source layer may include the optional metallic barrier liner (6B, shown in FIGS. 21 and 22) comprising a conductive metallic nitride material (such as TiN, TaN, WN, and/or MoN), and a metal layer 6M located on the metallic barrier liner and comprising a metal (such as W, Al, Cu, Co, Mo, Ru, etc.) having a higher electrical conductivity than the conductive metallic nitride material.

The metallic source layer 6M, the semiconductor source layer 6A, the crystalline semiconductor nanoparticles 6CN and the activated semiconductor textured-pattern structure (16A, 16CN) is then patterned by performing an anisotropic etch process, as described above with respect to FIG. 22. Each patterned portion of the metallic source layer 6M, crystalline semiconductor nanoparticles 6CN and the semiconductor source layer 6A comprises a source layer 6 that contacts end portions of a respective group of vertical semiconductor channels 60 (e.g., the doped source regions 61 in the end portions of the vertical semiconductor channels 60). Thus, the semiconductor nanoparticles 6CN may be incorporated into the source layer 6 of the completed memory device. Specifically, the semiconductor nanoparticles 6CN are located between the semiconductor source layer 6A and the metallic source layer 6M.

Patterned portions of the metallic source layer 6M and the activated semiconductor textured-pattern structure (16CN, 16A) comprise conductive pad structures 16 that contact an end surface of a respective one of the connection via structures 488. Each conductive pad structure 16 may comprise a stack of an activated semiconductor textured-pattern structure 16A, the crystalline semiconductor nanoparticles 16CN, an optional textured metallic barrier liner extending into the gaps within the activated semiconductor textured-pattern structure 16A, and a metal plate 16M. Thus, the crystalline semiconductor nanoparticles 16CN are also incorporated into the conductive pad structures 16 in the seventh embodiment.

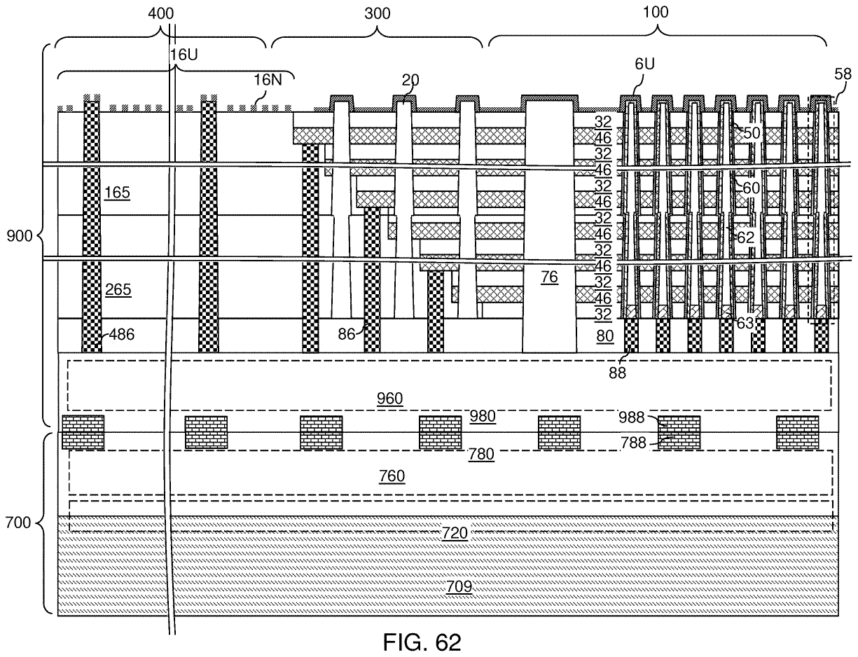

Referring to FIG. 62, the eighth exemplary structure can be derived from the configuration of the seventh exemplary structure shown in FIG. 59 by forming the nanoparticle textured-pattern structure 16N only in the peripheral region, similar to the firs exemplary structure shown in FIG. 19A.

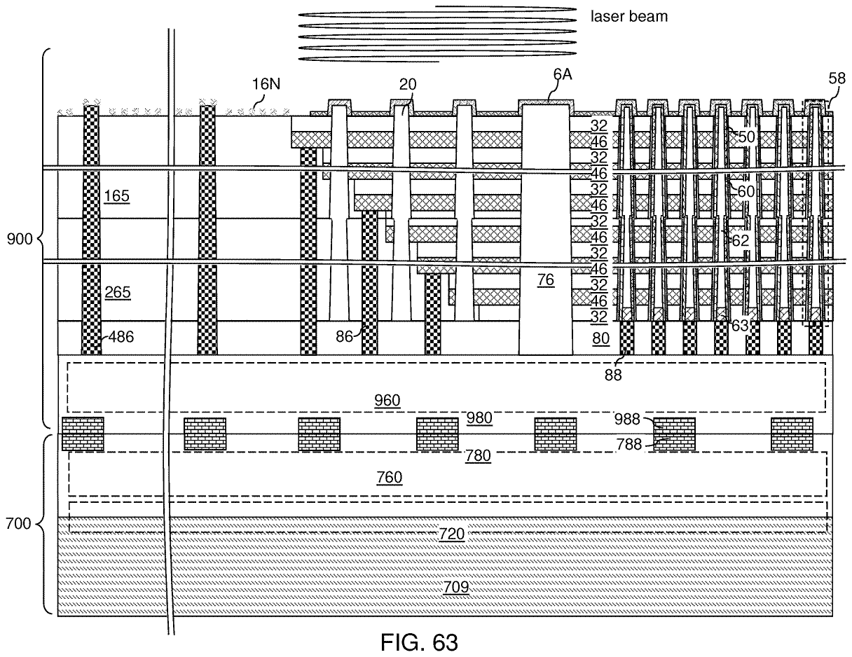

Referring to FIG. 63, the above described laser anneal process can be performed, similar to the step described above with respect to FIG. 60. The laser anneal forms the semiconductor source layer 6A and the activated semiconductor textured-pattern structure (16A, 16CN), as described above.

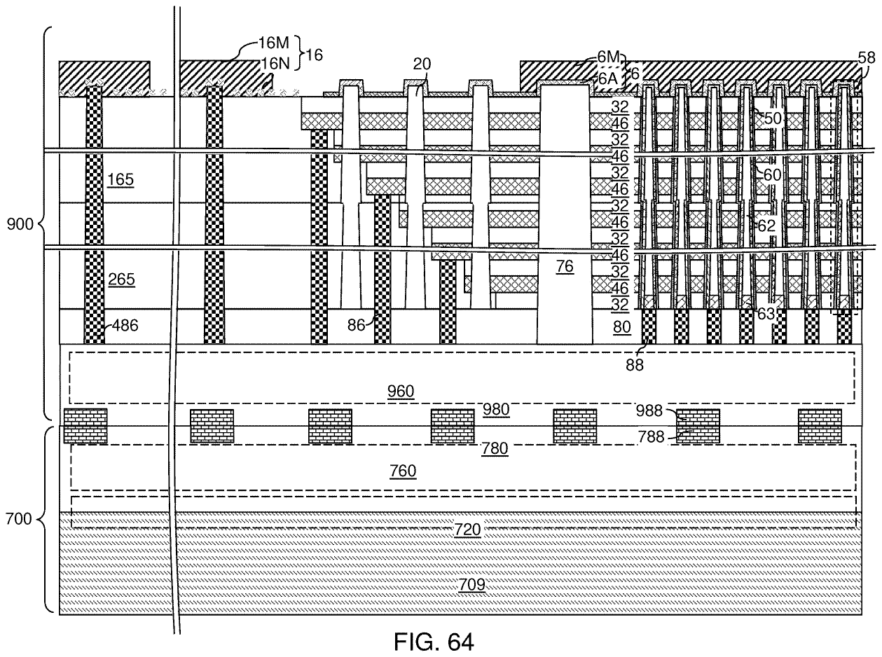

Referring to FIG. 64, the above described metallic source layer is deposited over backside of the semiconductor source layer 6A and over the activated semiconductor textured-pattern structure (16A, 16CN).

The metallic source layer 6M, the semiconductor source layer 6A, and the activated semiconductor textured-pattern structure (16A, 16CN) is then patterned by performing an anisotropic etch process, as described above with respect to FIG. 22. Each patterned portion of the metallic source layer 6M and the semiconductor source layer 6A comprises a source layer 6 that contacts end portions of a respective group of vertical semiconductor channels 60 (e.g., the doped source regions 61 in the end portions of the vertical semiconductor channels 60). Thus, the semiconductor nanoparticles 6CN are not incorporated into the source layer 6 of the completed memory device in the eighth embodiment.

Patterned portions of the metallic source layer 6M and the activated semiconductor textured-pattern structure (16CN, 16A) comprise conductive pad structures 16 that contact an end surface of a respective one of the connection via structures 488. Each conductive pad structure 16 may comprise a stack of an activated semiconductor textured-pattern structure 16A, the crystalline semiconductor nanoparticles 16CN, an optional textured metallic barrier liner extending into the gaps within the activated semiconductor textured-pattern structure 16A, and a metal plate 16M. Thus, the crystalline semiconductor nanoparticles 16CN are incorporated into the conductive pad structures 16 in the eight embodiment.

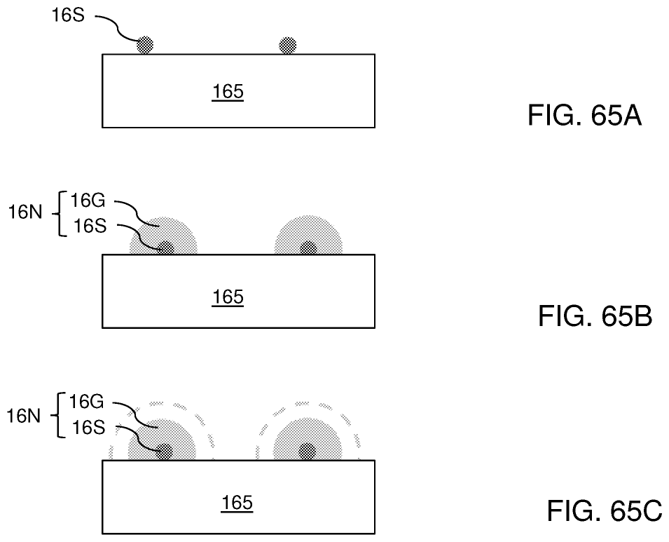

FIGS. 65A-65C illustrate a process for forming silicon core-germanium-containing shell nanoparticles 16N. Referring to FIG. 65A, amorphous silicon cores 16S are formed over the underlying device layer or layers, such as the first stepped dielectric material portion 165. The first stepped dielectric material portion 165 may comprise silicon oxide, and amorphous silicon nanoparticles have a good adhesion to silicon oxide. Amorphous silicon core 16S nucleation density and grain growth can be controlled independently by controlling the growth conditions. The core size can be adjusted by the gas conditions and process time.

For example, an amorphous silicon layer with a rough surface having peaks and valleys may be grown on the over the underlying device layer or layers at a temperature less than 400° C., such as by a low temperature chemical vapor deposition process. The amorphous silicon layer may then be subjected to a timed selective wet etch which etches away the entire thickness of the amorphous silicon layer at the thinner valley portions without etching away the entire thickness of the amorphous silicon layer at the peak portions. The amorphous silicon cores 16S comprise the remaining peak portions of the amorphous silicon layer. Other suitable methods of forming the amorphous silicon cores 16S may also be used.

Referring to FIG. 65B, amorphous germanium-containing shells 16G are grown around the amorphous silicon cores 16S. The amorphous silicon cores 16S act as nucleation seeds for the amorphous germanium-containing shells 16G. While germanium nanoparticles typically do not adhere well to silicon oxide surfaces, the use of the amorphous silicon cores 16S as nucleation seeds permit deposition of amorphous germanium-containing shells 16G at precise locations on the silicon oxide first stepped dielectric material portion 165. The amorphous germanium-containing shells 16G may be deposited by chemical vapor deposition (e.g., using a germane source gas) at a relatively low temperature (e.g., between 275 C and 350 C). The low temperature does not damage the underlying copper bonding pads (788, 988).

Referring to FIG. 65C, the amorphous germanium-containing shell 16G growth may be continued until the spacing between the adjacent amorphous germanium-containing shells 16G reaches a desired value that is less than the peak wavelength of the laser radiation, such as a spacing less than 1000 nm, such as 5 nm to 500 nm, including less than 500 nm, for example 20 nm to 400 nm.

In one embodiment, amorphous germanium-containing shell 16G includes only germanium and unavoidable impurities. During the growth of the amorphous germanium-containing shells 16G on the amorphous silicon cores 16S, the silicon and germanium may interdiffuse, and form a silicon-germanium compound semiconductor region between the amorphous germanium shells 16G and the amorphous silicon cores 16S.

In an alternative embodiment, the amorphous germanium-containing shell 16G may include some silicon in addition to germanium. In the alternative embodiment, both silane and germane are used during the chemical vapor deposition process to form the amorphous germanium-containing shell 16G containing 1 to 40, such as 20 to 40 atomic percent silicon (e.g., silicon germanium compound semiconductor material having a formula SiₓGe₁₋ₓ, where 0.01≤x≤0.4, such as 0.2≤x≤0.4).

The various embodiments of the present disclosure can be employed to enhance energy absorption from a laser beam during a laser anneal process, and to facilitate activation of electrical dopants in a doped semiconductor material region including inactivated electrical dopants. The laser anneal process can locally increase the temperature of the doped semiconductor material region to provide effective electrical activation of dopants and can minimize collateral heating of components of a semiconductor structure that need to be protected from excessive heat.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device, comprising:
an alternating stack of insulating layers and electrically conductive layers that alternate along a vertical direction;
memory openings vertically extending through the alternating stack;
memory opening fill structures located in the memory openings and comprising a respective vertical stack of memory elements and a respective vertical semiconductor channel;
a dielectric material portion located adjacent to the alternating stack;
a semiconductor source layer comprising a polycrystalline doped semiconductor material, underlying a bottommost surface of the alternating stack, and contacting a bottom end of the vertical semiconductor channels; and
a textured nanopattern including gaps having a respective gap width in a range from 5 nm to 500 nm.

2. The three-dimensional memory device of claim 1, wherein the semiconductor source layer contacts doped source layers located in the bottom ends of the vertical semiconductor channels.

3. The three-dimensional memory device of claim 1, wherein the textured nanopattern comprises semiconductor nanoparticles having the respective gap width in the range from 5 nm to 500 nm between adjacent semiconductor nanoparticles.

4. The three-dimensional memory device of claim 3, wherein the semiconductor nanoparticles comprise a two-dimensional periodic array of discrete semiconductor nanoparticles each having a diameter in a range from 1 nm to 500 nm.

5. The three-dimensional memory device of claim 3, wherein the semiconductor nanoparticles are also located on the semiconductor source layer to provide the textured nanopattern on the semiconductor source layer.

6. The three-dimensional memory device of claim 5, further comprising a metallic source layer, wherein the semiconductor nanoparticles are located between the semiconductor source layer and the metallic source layer.

7. The three-dimensional memory device of claim 3, further comprising:
a conductive pad structure comprising the semiconductor nanoparticles and a metal plate; and
a connection via structure extending through the dielectric material portion and contacting the conductive pad structure.

8. The three-dimensional memory device of claim 3, wherein the semiconductor nanoparticles comprise crystalline semiconductor nanoparticles.

9. The three-dimensional memory device of claim 8, wherein each of the crystalline semiconductor nanoparticles comprises a silicon core embedded in a germanium-containing shell.

10. The three-dimensional memory device of claim 8, wherein the germanium-containing shell consists essentially of germanium.

11. The three-dimensional memory device of claim 8, wherein the germanium-containing shell comprises a silicon-germanium compound semiconductor material.

12. The three-dimensional memory device of claim 1, further comprising a logic die bonded to memory die comprising the three-dimensional memory device.

13. A method of forming a three-dimensional memory device, comprising:
forming an alternating stack of insulating layers and spacer material layers over a carrier substrate, wherein the spacer material layers are formed as, or are subsequently replaced with, electrically conductive layers;
forming a dielectric material portion adjacent to the alternating stack;
forming memory openings through the alternating stack;
forming memory opening fill structures in the memory openings, wherein each of the memory opening fill structures comprises a respective vertical stack of memory elements and a respective vertical semiconductor channel;
removing the carrier substrate;
forming an unactivated semiconductor layer underneath the bottommost surface of the alternating stack and on bottom surfaces of the vertical semiconductor channels;
forming a textured nanopattern including gaps having a respective gap width after forming the unactivated semiconductor layer; and
irradiating a laser beam having a peak wavelength greater than the gap width on the unactivated semiconductor layer to convert the unactivated semiconductor into a semiconductor source layer, wherein the textured nanopattern enhances an absorption efficiency of the laser beam through at least one optical effect.

14. The method of claim 13, further comprising bonding a logic die to a memory die comprising the three-dimensional memory die using copper bonding pads, wherein the textured nanopattern absorbs the laser beam and prevents the laser beam from melting the copper bonding pads.

15. The method of claim 13, wherein the textured nanopattern is located over the dielectric material portion.

16. The method of claim 15, wherein the textured nanopattern is also located over the semiconductor source layer.

17. The method of claim 16, further comprising forming a metallic source layer over the textured nanopattern.

18. The method of claim 13, wherein the textured nanopattern comprises semiconductor nanoparticles having the respective gap width in the range from 5 nm to 500 nm between the adjacent semiconductor nanoparticles.

19. The method of claim 18, wherein the step of forming the textured nanopattern comprises forming amorphous silicon cores at least over the dielectric material portion, and growing germanium-containing shells on the amorphous silicon cores to form the semiconductor nanoparticles.

20. The method of claim 19, wherein the germanium-containing shells consist essentially of germanium or comprise a silicon-germanium compound semiconductor material.
